(19) United States
(12) Patent Application Publication
(10) Pub. No.: US 2026/0247790 A1
(43) Pub. Date: Aug. 20, 2026

(54) ORGANIC LIGHT EMITTING ELEMENT

(71) Applicant: CANON KABUSHIKI KAISHA, Tokyo (JP)

(72) Inventors: YOSUKE NISHIDE, Kanagawa (JP); TAKAYOSHI KIKUCHI, Kanagawa (JP); TAKAYUKI HORIUCHI, Kanagawa (JP); HIROKI OHRUI, Tokyo (JP); NAOKI YAMADA, Tokyo (JP)

(21) Appl. No.: 19/532,941

(22) Filed: Feb. 6, 2026

(30) Foreign Application Priority Data
Feb. 18, 2025 (JP) 2025-024000
Jan. 26, 2026 (JP) 2026-010607

(51) Int. Cl. H10K 50/12; H10K 85/30; H10K 85/40; H10K 85/60; H10K 101/10

(52) U.S. Cl. CPC H10K 50/12; H10K 85/324; H10K 85/342; H10K 85/40; H10K 85/622; H10K 85/623; H10K 85/624; H10K 85/626; H10K 85/633; H10K 85/636; H10K 85/654; H10K 85/656; H10K 85/6572; H10K 85/6574; H10K 85/6576; H10K 85/658; H10K 2101/10

(57) ABSTRACT

An organic light emitting element includes a first electrode, a second electrode, and an organic compound layer disposed between the first electrode and the second electrode. The organic compound layer includes a light emitting layer containing an organic compound and a light emitting material. When a permanent dipole moment of the organic compound is defined as μₕ and a permanent dipole moment of the light emitting material is defined as μ_{d}, μₕ/μ_{d} is 0.6 or more and 1.9 or less.

### BACKGROUND

### Field of the Technology

The present disclosure relates to an organic light emitting element.

### Description of the Related Art

An organic light emitting element (hereafter may also be referred to as an “organic electroluminescence element” or an “organic EL element”) is an electronic element having a pair of electrodes and an organic compound layer disposed between the electrodes. By injecting electrons and holes from the pair of electrodes, excitons of a light emitting organic compound in the organic compound layer are generated, and when the excitons return to the ground state, the organic light emitting element emits light.

Recent advancements in organic light emitting elements are remarkable; examples include low driving voltage, a variety of emission wavelengths, high-speed response, and the possibility of thinning and weight reduction of light emitting devices.

Chinese Patent Application Publication No. 114478588 (PTL1) describes an organic light emitting element in which a compound 1-a and a compound 1-b are used in a light emitting layer.

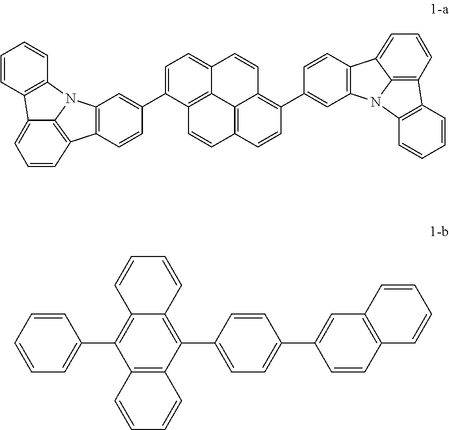

### SUMMARY

An organic light emitting element according to the present disclosure includes a first electrode, a second electrode, and an organic compound layer disposed between the first electrode and the second electrode, wherein the organic compound layer includes a light emitting layer containing an organic compound and a light emitting material; in a case that a permanent dipole moment of the organic compound is defined as uh and a permanent dipole moment of the light emitting material is defined as μ_{d}, μₕ/μ_{d} is 0.6 or more and 1.9 or less.

Features of the present disclosure will become apparent from the following description of embodiments with reference to the attached drawings. The following description of embodiments is described by way of example.

### BRIEF DESCRIPTION OF THE DRAWINGS

FIG. 1A is a schematic sectional view illustrating an example of a pixel of a display apparatus according to an embodiment of the present disclosure. FIG. 1B is a schematic sectional view illustrating an example of a display apparatus using an organic EL element according to an embodiment of the present disclosure.

FIG. 2 is a schematic view illustrating an example of a display apparatus according to an embodiment of the present disclosure.

FIG. 3A is a schematic view illustrating an example of an image pickup apparatus according to an embodiment of the present disclosure. FIG. 3B is a schematic view illustrating an example of an electronic apparatus according to an embodiment of the present disclosure.

FIG. 4A is a schematic view illustrating an example of a display apparatus according to an embodiment of the present disclosure. FIG. 4B is a schematic view illustrating an example of a foldable display apparatus.

FIG. 5A is a schematic view illustrating an example of a lighting apparatus according to an embodiment of the present disclosure. FIG. 5B is a schematic view illustrating an example of an automobile including a vehicular lighting device according to an embodiment of the present disclosure. FIG. 5C is a schematic view illustrating an example of the interior of an automobile including a vehicular lighting device according to an embodiment of the present disclosure.

FIG. 6A is a schematic view illustrating an example of a wearable device according to an embodiment of the present disclosure. FIG. 6B is a schematic view illustrating an example of a wearable device according to an embodiment of the present disclosure, the wearable device including an image pickup device.

FIG. 7A is a schematic view illustrating an example of an image forming apparatus according to an embodiment of the present disclosure.

FIG. 7B is a schematic view illustrating an example of an exposure light source of an image forming apparatus according to an embodiment of the present disclosure. FIG. 7C is a schematic view illustrating an example of an exposure light source of an image forming apparatus according to an embodiment of the present disclosure.

FIG. 8 illustrates the relationships of conceptual diagrams of interactions between an organic compound and a light emitting material and ratios of permanent dipole moments.

FIG. 9 illustrates legends in FIG. 8.

FIG. 10 illustrates schematic views of quenching with charges in light emitting elements using an exemplary compound A9 and the compound 1-a.

### DESCRIPTION OF THE EMBODIMENTS

However, in the organic light emitting element described in PTL 1, the compound 1-a serving as a light emitting material and the compound 1-b serving as a host material differ greatly in permanent dipole moment and hence there has been room for improvement in luminous efficiency.

Accordingly, the present disclosure is directed to providing an organic light emitting element excellent in luminous efficiency.

In this specification, examples of the halogen atom include fluorine, chlorine, bromine, iodine, astatine, and tennessine, but are not limited thereto.

The alkyl group may be an alkyl group having 1 or more and 20 or less carbon atoms, and may be an alkyl group having 1 or more and 10 or less carbon atoms. Specific examples include a methyl group, an ethyl group, a normal propyl group, an isopropyl group, a normal butyl group, a tertiary butyl group, a secondary butyl group, an octyl group, a cyclohexyl group, a tertiary pentyl group, a 3-methylpentan-3-yl group, a 1-adamantyl group, and a 2-adamantyl group, but are not limited thereto.

The alkoxy group may be an alkoxy group having 1 or more and 20 or less carbon atoms, and may be an alkoxy group having 1 or more and 10 or less carbon atoms. Specific examples include a methoxy group, an ethoxy group, a propoxy group, an isopropoxy group, a tertiary butoxy group, a 2-ethyl-octyloxy group, and a benzyloxy group, but are not limited thereto.

The silyl group is a group in which a silicon atom has a substituent. The substituent may be a substituted or unsubstituted alkyl group, or a substituted or unsubstituted aryl group. The substituted or unsubstituted alkyl group that the silicon atom has may be a substituted or unsubstituted alkyl group having 1 or more and 4 or less carbon atoms. The substituted or unsubstituted aryl group that the silicon atom has may be a substituted or unsubstituted aryl group having 6 or more and 10 or less carbon atoms. The silyl group may be a trialkylsilyl group, or may be a triarylsilyl group. Specific examples include a trimethylsilyl group and a triphenylsilyl group, but are not limited thereto.

The aryl group may be an aryl group having 6 or more and 20 or less carbon atoms, may be an aryl group having 6 or more and 18 or less carbon atoms, and may be an aryl group having 6 or more and 12 or less carbon atoms. Specific examples include a phenyl group, a biphenyl group, a naphthyl group, a phenanthrenyl group, a triphenylenyl group, an indenyl group, a terphenyl group, a fluorenyl group, a pyrenyl group, an anthracenyl group, a perylenyl group, a chrysenyl group, and a fluoranthenyl group, but are not limited thereto.

The heteroaryl group may be a heteroaryl group having 3 or more and 24 or less carbon atoms, may be a heteroaryl group having 3 or more and 18 or less carbon atoms, and may be a heteroaryl group having 3 or more and 12 or less carbon atoms. Specific examples include a pyridyl group, a pyrimidyl group, a pyrazyl group, a triazyl group, a benzofuranyl group, a benzothiophenyl group, a dibenzofuranyl group, a dibenzothiophenyl group, an oxazolyl group, an oxadiazolyl group, a thiazolyl group, a thiadiazolyl group, a carbazolyl group, an acridinyl group, and a phenanthrolinyl group, but are not limited thereto.

The amino group may be a substituted amino group substituted with an alkyl group or an aryl group, and may be a substituted amino group substituted with an alkyl group having 1 or more and 4 or less carbon atoms or an aryl group having 6 or more and 12 or less carbon atoms. Specific examples include an N-methylamino group, an N-ethylamino group, an N,N-dimethylamino group, an N,N-diethylamino group, an N-methyl-N-ethylamino group, an N-benzylamino group, an N-methyl-N-benzylamino group, an N,N-dibenzylamino group, an anilino group, an N,N-diphenylamino group, an N,N-dinaphthylamino group, an N,N-difluorenylamino group, an N-phenyl-N-tolylamino group, an N,N-ditolylamino group, an N-methyl-N-phenylamino group, an N,N-dianisylamino group, an N-mesityl-N-phenylamino group, an N,N-dimesitylamino group, an N-phenyl-N-(4-tert-butylphenyl)amino group, an N-phenyl-N-(4-trifluoromethylphenyl)amino group, and an N-piperidyl group, but are not limited thereto.

The aryloxy group may be specifically a phenoxy group or the like, but is not limited thereto.

The heteroaryloxy group may be specifically a thienyloxy group or the like, but is not limited thereto.

Examples of substituents that the above alkyl group, alkoxy group, amino group, aryloxy group, silyl group, aryl group, heteroaryl group, and heteroaryloxy group may further have include, for example, deuterium, alkyl groups such as a methyl group, an ethyl group, a normal propyl group, an isopropyl group, a normal butyl group, and a tertiary butyl group, aralkyl groups such as a benzyl group, aryl groups such as a phenyl group and a biphenyl group, heterocyclic groups such as a pyridyl group and a pyrrolyl group, amino groups such as a dimethylamino group, a diethylamino group, a dibenzylamino group, a diphenylamino group, and a ditolylamino group, alkoxy groups such as a methoxy group, an ethoxy group, and a propoxy group, aryloxy groups such as a phenoxy group, halogen atoms such as fluorine, chlorine, bromine, and iodine, and a cyano group, but are not limited thereto.

### (1) Organic Light Emitting Element

An organic light emitting element according to the present disclosure will be described. The organic light emitting element according to the present disclosure includes a first electrode, a second electrode, and an organic compound layer disposed between the electrodes. One of the first electrode and the second electrode is an anode and the other is a cathode. The organic compound layer includes a light emitting layer, and the light emitting layer contains an organic compound and a light emitting material. In an organic light emitting element according to an embodiment of the present disclosure, the light emitting layer may be a layer containing an organic compound, a light emitting material, and a compound other than the foregoing. In the organic light emitting element according to the present embodiment, the organic compound layer may be a single layer or may be a laminate including a plurality of layers as long as it has the light emitting layer.

In the organic light emitting element according to the present disclosure, the organic compound may be used as a host material of the light emitting layer, or may be used as an assist material. The light emitting material may be used as a guest material or may be used as an assist material, but is preferably used as the guest material. When the light emitting layer contains a material other than the organic compound and the light emitting material, the material may be used as an assist material.

Here, the host material is also referred to as a “host” or a “first compound” and is a compound having the highest mass ratio among the compounds constituting the light emitting layer. The guest material is also referred to as a “guest”, a “dopant material”, a “dopant”, or a “third compound” and is a compound whose mass ratio among the compounds constituting the light emitting layer is lower than that of the host and that is mainly responsible for light emission. Therefore, the guest material may also be referred to as a light emitting material. The assist material is also referred to as an “assist” or a “second compound” and is a compound whose mass ratio among the compounds constituting the light emitting layer is lower than that of the host material and that assists the light emission of the guest material. Note that the assist material is also called a second host.

Let S1(H) denote the lowest singlet excitation energy of the host material, S1(D) denote the lowest singlet excitation energy of the guest material, and S1(A) denote the lowest singlet excitation energy of the assist material.

In this case, the organic light emitting element according to the present embodiment preferably satisfies S1(H)>S1(D) or S1(H)>S1(A)>S1(D). When the lowest singlet excitation energies of the compounds contained in the organic light emitting element according to the present embodiment satisfy the above relationship, excitons can be efficiently transferred to the guest material, so that the organic light emitting element has more excellent luminous efficiency.

The concentration of the host material may be, relative to the entire light emitting layer, 50 mass % or more and less than 99 mass %, is preferably 50 mass % or more and 98 mass % or less, is more preferably 50 mass % or more and 95 mass % or less, and is still more preferably 50 mass % or more and 90 mass % or less.

The concentration of the guest material may be, relative to the entire light emitting layer, 0.1 mass % or more and 30 mass % or less, may be 0.1 mass % or more and 20 mass % or less, and may be 0.1 mass % or more and 10.0 mass % or less.

When the light emitting layer further contains an assist material, the concentration of the assist material may be, relative to the entire light emitting layer, 1 mass % or more and less than 50 mass %, and is preferably 10 mass % or more and less than 50 mass %. The concentration of the guest may be 0.01 mass % or more and 20 mass % or less, and is preferably 0.01 mass % or more and 5 mass % or less.

Here, when the organic compound layer is a laminate including a plurality of layers, the organic compound layer may further include, in addition to the light emitting layer, a hole injection layer, a hole transport layer, an electron blocking layer, a hole-exciton blocking layer, an electron transport layer, an electron injection layer, and the like. The light emitting layer may be a single layer or may be a laminate including a plurality of layers. When the light emitting layer includes a plurality of layers, a charge generation layer may be provided between the light emitting layers. The charge generation layer may be formed of a compound whose LUMO (Lowest Unoccupied Molecular Orbital) energy level is lower than the HOMO energy level of the hole transport layer, and the LUMO energy level of the charge generation layer may be lower than the HOMO energy level of the hole transport layer. Here, the HOMO energy level and the LUMO energy level of the organic compound layer may be the HOMO energy level and the LUMO energy level of an organic compound having the highest weight ratio in the organic compound layer.

Specific examples of element configurations of the organic light emitting element according to the present embodiment include the following (1) to (6) multilayer element configurations in which electrode layers and organic compound layers are sequentially stacked on a substrate.
(1) anode/light emitting layer/cathode
(2) anode/hole transport layer/light emitting layer/electron transport layer/cathode
(3) anode/hole transport layer/light emitting layer/electron transport layer/electron injection layer/cathode
(4) anode/hole injection layer/hole transport layer/light emitting layer/electron transport layer/cathode
(5) anode/hole injection layer/hole transport layer/light emitting layer/electron transport layer/electron injection layer/cathode
(6) anode/hole transport layer/electron blocking layer/light emitting layer/hole blocking layer/electron transport layer/cathode

However, these element configuration examples are merely very basic element configurations and are non-limiting examples. For example, various layer configurations can be employed: an insulating layer, an adhesive layer, or an interference layer is disposed at the interface between an electrode and an organic compound layer; an electron transport layer or a hole transport layer is constituted by two layers having different ionization potentials; and a light emitting layer is constituted by two layers formed of different light emitting materials.

In the above-described element configurations (1) to (6), the configuration of (6) is preferable because it has both an electron blocking layer and a hole blocking layer. Specifically, in the configuration (6) having the electron blocking layer and the hole blocking layer, both carriers of holes and electrons can be reliably confined within the light emitting layer, to thereby provide an organic light emitting element having no carrier leakage and having high luminous efficiency.

The extraction mode of light output from the light emitting layer (element form) may be, what is called, the bottom emission mode in which light is extracted from the electrode on the substrate side or, what is called, the top emission mode in which light is extracted from a side opposite to the substrate. Alternatively, a both-side extraction mode in which light is extracted from the substrate side and the side opposite to the substrate can also be employed.

Here, the HOMO energy level and the LUMO energy level are referred to as “high” when they are closer to the vacuum level. That the LUMO energy level of the charge generation layer is lower than the HOMO energy level of the hole transport layer indicates that the LUMO energy level of the charge generation layer is farther from the vacuum level than the HOMO energy level of the hole transport layer.

In this specification, the HOMO energy level and the LUMO energy level can be calculated using molecular orbital calculations.

In this specification, the HOMO energy level and the LUMO energy level can also be calculated using the ionization potential and the band gap. The HOMO energy level can be estimated by measuring the ionization potential. The ionization potential can be measured by dissolving a compound to be measured in a solvent such as toluene or forming a vapor-deposited film of the compound to be measured on a substrate formed of glass or the like and then performing measurement with a measurement apparatus such as AC-3. The band gap can be measured by dissolving a compound to be measured in a solvent such as toluene and subjected to measurement by irradiation with excitation light. The band gap can be measured by measuring the absorption edge of an absorption spectrum of the excitation light. Alternatively, the band gap can be measured by vapor-depositing the compound to be measured on a substrate formed of glass or the like, and irradiating the vapor-deposited film with excitation light. The band gap can be measured by measuring the absorption edge of an absorption spectrum in which the vapor-deposited film absorbs the excitation light.

The LUMO energy level can be calculated using values of the band gap and the ionization potential. By subtracting the value of the ionization potential from the band gap, the LUMO energy level can be estimated.

The LUMO energy level can also be estimated from a reduction potential. For example, a one-electron reduction potential is estimated using CV (cyclic voltammetry) measurement. The CV measurement can be performed, for example, in a DMF solution of 0.1 M tetrabutylammonium perchlorate, using a reference electrode of Ag/Ag⁺, a counter electrode of Pt, and a working electrode of glassy carbon.

For the determined reduction potential of the compound, a difference from the reduction potential of ferrocene is added to −4.8 eV, to thereby estimate the LUMO energy level.

The light emitting layer may be a single layer or a plurality of layers; when a light emitting material having another emission color is contained, white, an intermediate color, or the like can be provided. The plurality of layers mean a state in which a light emitting layer and another light emitting layer are laminated. In this case, the emission color of the organic light emitting element is not limited to blue. These films are formed by vapor deposition or coating.

Hereinafter, the organic light emitting element according to the present disclosure will be described in detail.

The organic light emitting element according to the present disclosure has the following features and therefore has excellent durability.

### (1-1) Ratio of Permanent Dipole Moments of Organic Compound and Light Emitting Material is 0.6 or More and 1.9 or Less

Hereinafter, this feature will be described.

### (1-1) Ratio of Permanent Dipole Moments of Organic Compound and Light Emitting Material is 0.6 or More and 1.9 or Less

In the organic light emitting element according to the present disclosure, when the permanent dipole moment of the organic compound is defined as μₕ and the permanent dipole moment of the light emitting material is defined as μ_{d}, μₕ/μ_{d} is 0.6 or more and 1.9 or less.

Because of this feature, energy transfer between the organic compound and the light emitting material is promoted, to thereby provide an organic light emitting element excellent in luminous efficiency. In this case, the value of μₕ is not particularly limited, and μₕ may be 0.10 or more, and may be 0.12 or more. Un may be 3.0 or less, may be 2.67 or less, may be 1.67 or less, may be 1.0 or less, may be 0.89 or less, may be 0.60 or less, and may be 0.53 or less. μₕ/μ_{d} may be 0.6 or more and 1.8 or less, and may be 0.6 or more and 1.2 or less.

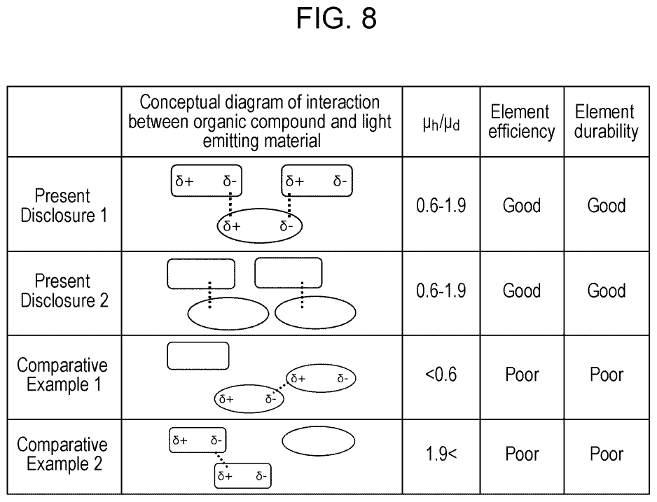

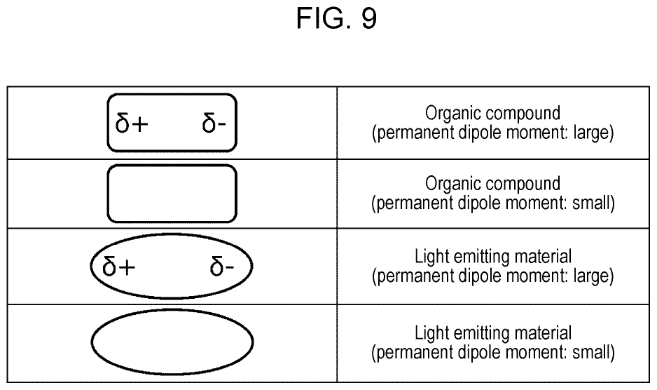

The present inventors focused on a relationship between permanent dipole moments of an organic compound and a light emitting material as a measure to promote energy transfer in a light emitting layer of an organic light emitting element. FIG. 8 illustrates the relationships of conceptual diagrams of interactions between an organic compound and a light emitting material and ratios of permanent dipole moments, and FIG. 9 illustrates legends in FIG. 8.

In FIG. 8, the organic light emitting elements according to Present Disclosures 1 and 2 have configurations in which the ratio of the permanent dipole moments of the organic compound and the light emitting material is 0.6 or more and 1.9 or less. In other words, the organic light emitting elements according to Present Disclosures 1 and 2 have configurations in which the values of the permanent dipole moments of the organic compound and the light emitting material are close. Here, the organic compound having a large permanent dipole moment refers to an organic compound in which a charge bias (δ+ or δ−) occurs in the molecule, and the organic compound having a small permanent dipole moment refers to an organic compound in which a charge bias is less likely to occur in the molecule.

In Present Disclosure 1, both the organic compound and the light emitting material are compounds having large permanent dipole moments, and a charge bias occurs in the molecules. Interactions between δ− of the organic compound and δ+ of the light emitting material and between δ+ of the organic compound and δ− of the light emitting material tend to occur, to thereby improve compatibility between the organic compound and the light emitting material. As a result, the intermolecular distance between the organic compound and the light emitting material becomes short, so that, in the present embodiment, energy transfer from the organic compound to the light emitting material is promoted, and luminous efficiency is improved. In Present Disclosure 2, both the organic compound and the light emitting material are compounds having small permanent dipole moments, and a charge bias is less likely to occur in the molecules. Therefore, the organic compound and the light emitting material are likely to interact with each other, to thereby improve compatibility between the organic compound and the light emitting material.

As a result, the intermolecular distance between the organic compound and the light emitting material becomes short, energy transfer from the organic compound to the light emitting material is promoted, and luminous efficiency is improved.

On the other hand, when the intermolecular distance between the organic compound and the light emitting material becomes long, energy transfer from the organic compound to the light emitting material decreases. As a result, the exciton of the organic compound deactivates before moving to the light emitting material, so that luminous efficiency decreases. The organic light emitting element according to Comparative Example 1 has a configuration in which the permanent dipole moment of the organic compound is small and the permanent dipole moment of the light emitting material is large. The organic light emitting element according to Comparative Example 2 has a configuration in which the permanent dipole moment of the organic compound is large and the permanent dipole moment of the light emitting material is small. These organic light emitting elements have configurations in which one of the permanent dipole moments of the organic compound and the light emitting material is large; thus, when the compounds interact with each other, δ+ and δ− of the compounds having large permanent dipole moments interact with each other. In other words, in the configuration of Comparative Example 1, interaction between the light emitting materials is large, and in the configuration of Comparative Example 2, interaction between the organic compounds is large, so that compatibility between the organic compound and the light emitting material decreases. Therefore, the intermolecular distance between the organic compound and the light emitting material increases, and efficiency of energy transfer decreases. As a result, the exciton of the organic compound deactivates before moving to the light emitting material, so that luminous efficiency decreases.

For the reasons described above, the organic light emitting element according to the present disclosure in which values of the permanent dipole moments of the organic compound and the light emitting material are close is an organic light emitting element excellent in luminous efficiency.

In addition, the organic light emitting element according to the present disclosure is an organic light emitting element also excellent in element durability. The values of the permanent dipole moments of the organic compound and the light emitting material are close, so that the organic compound and the light emitting material are likely to interact with each other. In the organic light emitting element according to the present disclosure, compared with the organic light emitting elements according to Comparative Examples, interaction between organic compounds can be reduced, so that localized charge accumulation is eliminated, and generation of quenchers can be inferentially suppressed. As a result, the organic light emitting element according to the present embodiment is also excellent in element durability.

Table 1 describes element efficiency ratios and element durability ratios of organic light emitting elements according to the present disclosure and organic light emitting elements according to Comparative Examples. The organic light emitting elements according to Comparative Examples are the organic light emitting elements described in PTL1.

The element efficiency ratio is a ratio relative to the luminous efficiency of the organic light emitting element according to Comparative Example 1; and the element durability ratio is a ratio relative to the time at which the luminance of the organic light emitting element according to Comparative Example 1 decreases to 95% of the initial luminance, and is a value indicating durability.

TABLE 1

| | Organic compound | Light emitting | | | |
|---|---|---|---|---|---|
| | (permanent dipole | material (permanent | | Element | Element |
| | moment μₕ) | dipole moment μ_{d}) | μₕ/μ_{d} | efficiency | durability |
| Present Disclosure 1 | 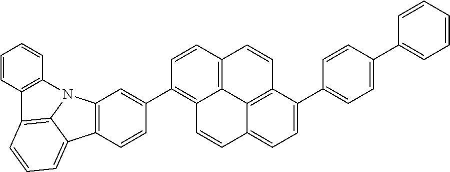 [SMILES: c1ccc(-c2ccc(-c3ccc4ccc5c(-c6ccc7c8cccc9c%10ccccc%10n(c7c6)c98)ccc6ccc3c4c65)cc2)cc1] | 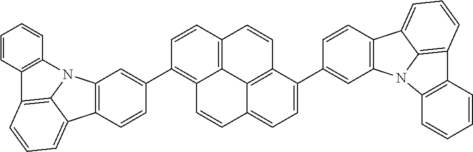 [SMILES: c1ccc2c(c1)c1cccc3c4ccc(-c5ccc6ccc7c(-c8ccc9c%10cccc%11c%12ccccc%12n(c9c8)c%11%10)ccc8ccc5c6c87)cc4n2c13] | 1.8 | 1.2 | 1.2 |
| | A9(0.53) | 1-a(0.30) | | | |
| Present Disclosure 2 | 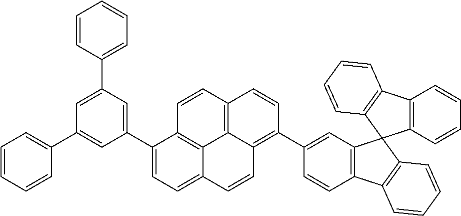 [SMILES: c1ccc(-c2cc(-c3ccccc3)cc(-c3ccc4ccc5c(-c6ccc7c(c6)C6(c8ccccc8-c8ccccc86)c6ccccc6-7)ccc6ccc3c4c65)c2)cc1] | 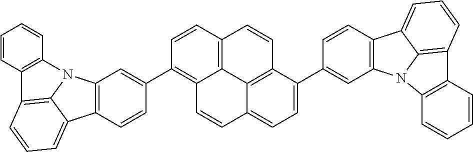 [SMILES: c1ccc2c(c1)c1cccc3c4ccc(-c5ccc6ccc7c(-c8ccc9c%10cccc%11c%12ccccc%12n(c9c8)c%11%10)ccc8ccc5c6c87)cc4n2c13] | 0.8 | 1.1 | 1.2 |
| | EM41(0.24) | 1-a(0.30) | | | |
| Present Disclosure 3 | 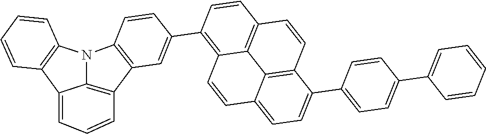 [SMILES: c1ccc(-c2ccc(-c3ccc4ccc5c(-c6ccc7c(c6)c6cccc8c9ccccc9n7c86)ccc6ccc3c4c65)cc2)cc1] | 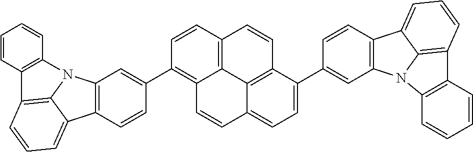 [SMILES: c1ccc2c(c1)c1cccc3c4ccc(-c5ccc6ccc7c(-c8ccc9c%10cccc%11c%12ccccc%12n(c9c8)c%11%10)ccc8ccc5c6c87)cc4n2c13] | 1.5 | 1.1 | 1.1 |
| | 2-a(0.44) | 1-a(0.30) | | | |
| Comparative Example 1 | 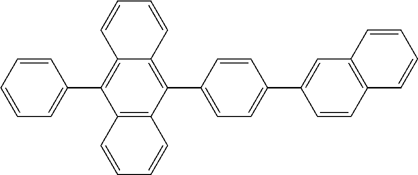 [SMILES: c1ccc(-c2c3ccccc3c(-c3ccc(-c4ccc5ccccc5c4)cc3)c3ccccc23)cc1] | 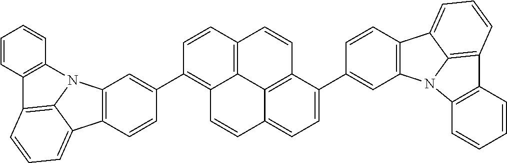 [SMILES: c1ccc2c(c1)c1cccc3c4ccc(-c5ccc6ccc7c(-c8ccc9c%10cccc%11c%12ccccc%12n(c9c8)c%11%10)ccc8ccc5c6c87)cc4n2c13] | 0.1 | 1.0 | 1.0 |
| | 1-b(0.03) | 1-a(0.30) | | | |
| Comparative Example 2 | 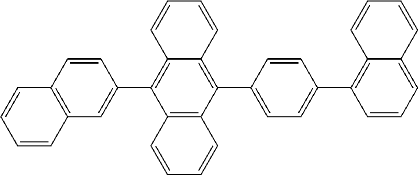 [SMILES: c1ccc2cc(-c3c4ccccc4c(-c4ccc(-c5cccc6ccccc56)cc4)c4ccccc34)ccc2c1] | 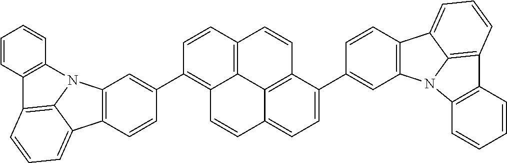 [SMILES: c1ccc2c(c1)c1cccc3c4ccc(-c5ccc6ccc7c(-c8ccc9c%10cccc%11c%12ccccc%12n(c9c8)c%11%10)ccc8ccc5c6c87)cc4n2c13] | 0.5 | 1.0 | 1.0 |
| | EM42(0.15) | 1-a(0.30) | | | |

The organic light emitting elements according to the present disclosure are organic light emitting elements in which μₕ/μ_{d} is 0.6 or more and 1.9 or less; and the organic light emitting elements according to Comparative Examples are organic light emitting elements in which μₕ/μ_{d} is less than 0.6 or more than 1.9 and in which the permanent dipole moment of the light emitting material is larger than the permanent dipole moment of the organic compound. Table 1 has demonstrated that the organic light emitting elements according to the present disclosure have configurations excellent in element efficiency. This is inferentially because, as described above, the values of the permanent dipole moments of the organic compound and the light emitting material are close, so that these are likely to be dispersed in the film, to promote energy transfer from the organic compound to the light emitting material.

As has been described, the organic light emitting elements according to the present disclosure are organic light emitting elements excellent in luminous efficiency. In addition, the organic light emitting elements according to the present embodiment are organic light emitting elements excellent also in durability.

Note that the permanent dipole moment was calculated using molecular orbital calculation. As the calculation technique of the molecular orbital calculation method, density functional theory (DFT), which is currently widely used, was used. The functional was B3LYP and the basis set was 6-31G*. Note that the molecular orbital calculation method was implemented using Gaussian09, which is currently widely used (Gaussian09, Revision C. 01, M. J. Frisch, G. W. Trucks, H. B. Schlegel, G. E. Scuseria, M. A. Robb, J. R. Cheeseman, G. Scalmani, V. Barone, B. Mennucci, G. A. Petersson, H. Nakatsuji, M. Caricato, X. Li, H. P. Hratchian, A. F. Izmaylov, J. Bloino, G. Zheng, J. L. Sonnenberg, M. Hada, M. Ehara, K. Toyota, R. Fukuda, J. Hasegawa, M. Ishida, T. Nakajima, Y. Honda, O. Kitao, H. Nakai, T. Vreven, J. A. Montgomery, Jr., J. E. Peralta, F. Ogliaro, M. Bearpark, J. J. Heyd, E. Brothers, K. N. Kudin, V. N. Staroverov, T. Keith, R. Kobayashi, J. Normand, K. Raghavachari, A. Rendell, J. C. Burant, S. S. Iyengar, J. Tomasi, M. Cossi, N. Rega, J. M. Millam, M. Klene, J. E. Knox, J. B. Cross, V. Bakken, C. Adamo, J. Jaramillo, R. Gomperts, R. E. Stratmann, O. Yazyev, A. J. Austin, R. Cammi, C. Pomelli, J. W. Ochterski, R. L. Martin, K. Morokuma, V. G. Zakrzewski, G. A. Voth, P. Salvador, J. J. Dannenberg, S. Dapprich, A. D. Daniels, O. Farkas, J. B. Foresman, J. V. Ortiz, J. Cioslowski, and D. J. Fox, Gaussian, Inc., Wallingford CT, 2010). Hereinafter, molecular orbital calculations in this specification are performed by the same technique.

Furthermore, the organic light emitting element of the present embodiment preferably has the following features:
(1-2) Organic compound includes fused polycyclic hydrocarbon ring having 3 rings or more and 4 rings or less;
(1-3) Organic compound includes indolocarbazole skeleton and pyrene skeleton;
(1-4) Organic compound includes indolocarbazole skeleton in which substituent is provided at meta position relative to nitrogen atom; or
(1-5) Light emitting material emits fluorescence.

Hereinafter, these will be described.

### (1-2) Organic Compound Includes Fused Polycyclic Hydrocarbon Ring Having 3 Rings or More and 4 Rings or Less

In the organic light emitting element according to the present embodiment, the organic compound preferably has a fused polycyclic hydrocarbon ring having 3 rings or more and 4 rings or less. Non-limiting specific examples include an anthracene skeleton, a pyrene skeleton, and a tetracene skeleton. These skeletons tend to exhibit a low lowest triplet excitation energy (T1) and the efficiency of converting a triplet excited state into a singlet excited state can be increased, so that more excellent luminous efficiency can be achieved.

The organic compound according to the present embodiment may further include a fused polycyclic hydrocarbon ring having 10 or more and 30 or less carbon atoms. The fused polycyclic hydrocarbon ring having 10 or more and 30 or less carbon atoms is preferably a fused polycyclic hydrocarbon ring having 3 or more and 6 or less rings. Specifically, the ring preferably has an anthracene skeleton, a phenanthrene skeleton, a fluorene skeleton, a pyrene skeleton, a triphenylene skeleton, a fluorene skeleton, a fluoranthene skeleton, a tetracene skeleton, a chrysene skeleton, a perylene skeleton, or a spirofluorene skeleton, more preferably an anthracene skeleton or a pyrene skeleton, and still more preferably a pyrene skeleton.

The compound including an anthracene skeleton or a pyrene skeleton has a low T1 and provides a higher efficiency of converting a triplet excited state into a singlet excited state; therefore, an organic light emitting element using a compound including such a skeleton is more excellent in luminous efficiency and is therefore preferable. In addition, the compound including a pyrene skeleton has excellent oxidation stability; therefore, the organic light emitting element using the compound is more excellent also in durability and is therefore preferable.

### (1-3) Organic Compound Includes Indolocarbazole Skeleton and Pyrene Skeleton

In the organic light emitting element according to the present embodiment, the organic compound preferably includes an indolocarbazole skeleton and a pyrene skeleton. When the organic compound having these skeletons is used, the permanent dipole moment of the molecule becomes large, and therefore the organic light emitting element according to the present embodiment is more excellent in luminous efficiency.

The organic compound in the organic light emitting element according to the present embodiment is preferably represented by any one of general formulas (1) to (3), and the organic compound represented by the general formula (1) is more preferably represented by a general formula (1-2).

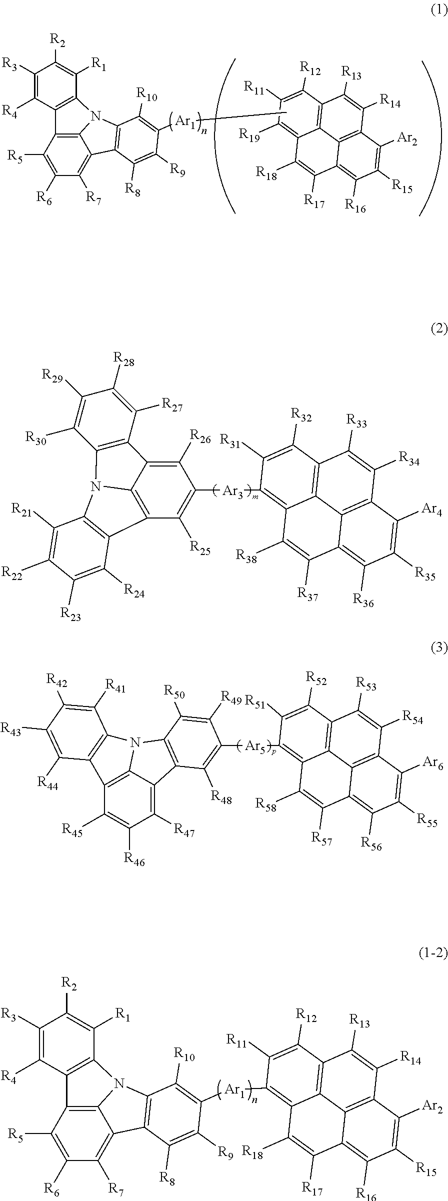

The organic compound according to the present embodiment includes, with respect to the pyrene skeleton, on one side, the indolocarbazole skeleton, which is a heteroaromatic ring, while, on the other side, a hydrogen atom, a deuterium atom, an aromatic hydrocarbon ring, or a combination of aromatic hydrocarbon rings. Thus, the molecule as a whole has, at one of the terminals, the indolocarbazole skeleton, which is a heteroaromatic ring, and, at the other terminal, the hydrocarbon structure. Therefore, in the organic compound according to the present embodiment, polarization occurs in the molecule, so that the permanent dipole moment becomes high and, as a result, excellent luminous efficiency is exhibited.

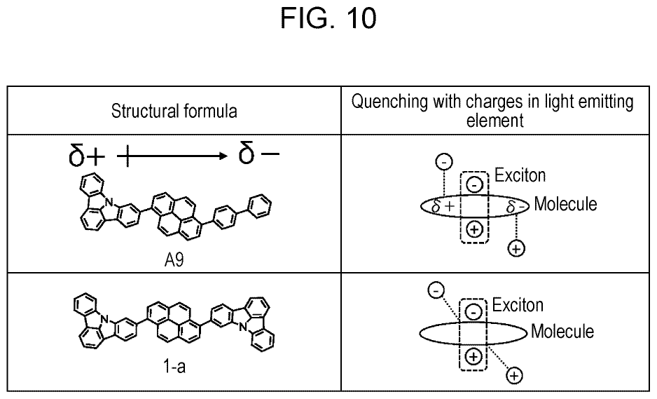

FIG. 10 illustrates schematic views of quenching with charges in light emitting elements using an exemplary compound A9 and the compound 1-a.

In FIG. 10, the compound 1-a is a compound in which polarization in the molecule is small and, when an exciton is generated at the center of the molecule, an electron and a hole easily approach the exciton, and therefore the compound is more likely to be quenched as compared with the organic compound according to the present embodiment.

On the other hand, in the exemplary compound A9, when an exciton is generated at the center of the molecule, an electron (anion) and a hole (cation) approaching the molecule respectively approach the δ+ portion and the δ− portion of the molecule. As a result, the exciton and the electron or hole are located at portions away from each other, so that deactivation (quenching) of the exciton by the electron or hole can be suppressed, to provide an organic light emitting element excellent in luminous efficiency.

Here, the effect of separating the position where an exciton is generated and the position where an electron or a hole approaches is described. Before the exciton transitions to the ground state and when the exciton and an electron or hole approach each other to within a certain distance, the exciton is quenched and luminous efficiency decreases. Therefore, in order to suppress quenching of the exciton, the position where the exciton is generated and the position where the electron or hole approaches the molecule need to be separated. The organic compound according to the present embodiment has large polarization in the molecule, and therefore an electron or hole approaches a position away from the center of the molecule. As a result, the exciton generated at the center of the molecule and the electron or hole are separated, and hence quenching of the exciton can be suppressed.

Therefore, the organic light emitting element according to the present embodiment contains an organic compound represented by any one of the general formulas (1) to (3) and, as a result, is more excellent in luminous efficiency.

The organic compound according to the present embodiment preferably includes a freely rotatable single bond that is a carbon-carbon bond, which has high bond energy. In particular, the organic compounds represented by the general formulas (1) to (3), which include freely rotatable single bonds that are carbon-carbon bonds, which have high bond energy, are more excellent also in durability. Therefore, organic light emitting elements using the organic compounds represented by the general formulas (1) to (3) are more excellent also in durability.

In this specification, the freely rotatable single bond refers to a single bond between a unit A and a unit B, represented as “A-B”, in which the unit A and the unit B are not ring-fused to each other. The units A and B may each be an atom such as a carbon atom or a nitrogen atom, or may each be a molecule such as benzene or carbazole.

Hereinafter, the general formulas (1) to (3) will be described.

R₁ to R₁₇, R₂₁ to R₃₈, and R₄₁ to R₅₈

R₁ to R₁₇, R₂₁ to R₃₈, and R₄₁ to R₅₈ are each independently selected from the group consisting of a hydrogen atom, a deuterium atom, substituted or unsubstituted alkyl groups, substituted or unsubstituted alkoxy groups, substituted or unsubstituted silyl groups, substituted or unsubstituted amino groups, and a cyano group.

R₁ to R₁₇ may each be independently selected from the group consisting of a hydrogen atom, a deuterium atom, substituted or unsubstituted alkyl groups having 1 or more and 6 or less carbon atoms, substituted or unsubstituted alkoxy groups having 1 or more and 4 or less carbon atoms, and a trimethylsilyl group. Specifically, R₁ to R₁₇ may each be independently selected from the group consisting of a hydrogen atom, a deuterium atom, a methyl group, a CD₃ group, an iso-propyl group, a tert-butyl group, a cyclohexyl group, a methoxy group, and a trimethylsilyl group.

R₃ and R₆ may be hydrogen atoms, R₁ to R₁₉ may be hydrogen atoms, or R₁ to R₁₉ may be deuterium atoms.

Here, when at least one of R₁ to R₁₇ is a substituent other than a hydrogen atom, at least one of R₃, R₅, R₆, R₁₂, and R₁₆ may be a substituent, or R₃ and R₅, R₆, or R₁₂ and R₁₆ may be substituents. When at least one of R₂₁ to R₃₈ is a substituent other than a hydrogen atom, at least one of R₂₁, R₂₂, R₂₉, R₃₂, and R₃₆ may be a substituent. When at least one of R₄₁ to R₅₈ is a substituent other than a hydrogen atom, at least one of R₄₃, R₄₅, R₄₆, R₅₂, and R₅₆ may be a substituent.

Ar₁ is bonded to any one of R₁₁ to R₁₉, preferably to any one of R₁₃, R₁₆, and R₁₉, more preferably to R₁₉.

Here, for example, “Ar₁ is bonded to R₁₉” means that Ar₁ is directly bonded to the carbon atom to which R₁₉ is bonded, which specifically means the structure represented by the general formula (1-2).

Ar₁, Ar₃, and Ar₅

Ar₁, Ar₃, and Ar₅ are each independently selected from the group consisting of aromatic hydrocarbon rings, heteroaromatic rings, and combinations thereof. The aromatic hydrocarbon rings may have a substituent.

When the organic compound according to the present disclosure has Ar₁ (n is 1), Ar₁ may be an aromatic hydrocarbon ring having 6 or more and 30 or less carbon atoms, a heteroaromatic ring having 3 or more and 15 or less carbon atoms, or a combination thereof.

Ar₁, Ar₃, and Ar₅ may be an aromatic hydrocarbon ring having 6 or more and 30 or less carbon atoms, a heteroaromatic ring having 3 or more and 15 or less carbon atoms, a combination of an aromatic hydrocarbon ring having 6 or more and 10 or less carbon atoms and a heteroaromatic ring having 3 or more and 9 or less carbon atoms, a combination of an aromatic hydrocarbon ring having 6 or more and 10 or less carbon atoms and an aromatic hydrocarbon ring having 6 or more and 10 or less carbon atoms, or a combination of a heteroaromatic ring having 3 or more and 9 or less carbon atoms and a heteroaromatic ring having 3 or more and 9 or less carbon atoms. Specific examples include a benzene ring, a phenanthrene ring, a triphenylene ring, a chrysene ring, a spirofluorene ring, a fluorene ring, a pyridine ring, a thiophene ring, a furan ring, a dibenzofuran ring, a dibenzothiophene ring, a quinoline ring, a combination of a benzene ring and a benzene ring (a biphenyl group), a combination of a naphthalene ring and a benzene ring, a combination of a thiophene ring and a thiophene ring, a combination of a benzene ring and a pyridine ring, a combination of a benzene ring and an oxazole ring, and a combination of a benzene ring and a thiazole ring.

Ar₁, Ar₃, and Ar₅ may be an aromatic hydrocarbon ring having 6 or more and 25 or less carbon atoms, a heteroaromatic ring having 3 or more and 12 or less carbon atoms, a combination of an aromatic hydrocarbon ring having 6 or more and 10 or less carbon atoms and a heteroaromatic ring having 3 or more and 5 or less carbon atoms, a combination of an aromatic hydrocarbon ring having 6 or more and 10 or less carbon atoms and an aromatic hydrocarbon ring having 6 or more and 10 or less carbon atoms, or a combination of a heteroaromatic ring having 3 or more and 5 or less carbon atoms and a heteroaromatic ring having 3 or more and 5 or less carbon atoms.

Ar₁, Ar₃, and Ar₅ may be an aromatic hydrocarbon ring having 5 or more and 15 or less carbon atoms or a heteroaromatic ring having 3 or more and 12 or less carbon atoms. Specific examples include a benzene ring, a pyridine ring, a dibenzofuran ring, a dibenzothiophene ring, and a fluorene ring, and preferred examples include a benzene ring, a dibenzofuran ring, a dibenzothiophene ring, and a fluorene ring.

When Ar₁, Ar₃, and Ar₅ have a substituent, the substituent may be a deuterium atom, a substituted or unsubstituted alkyl group, a substituted or unsubstituted alkoxy group, a substituted or unsubstituted silyl group, a substituted or unsubstituted amino group, or a cyano group. The substituent is preferably a deuterium atom, a substituted or unsubstituted alkyl group having 1 or more and 4 or less carbon atoms, or an aryl group having 6 or more and 10 or less carbon atoms, and more preferably a substituted or unsubstituted alkyl group having 1 or more and 4 or less carbon atoms or an aryl group having 6 or more and 10 or less carbon atoms. Specifically, the substituent is preferably one or two or more methyl groups or a phenyl group, and more preferably one or two or more methyl groups.

Ar₁, Ar₃, and Ar₅ preferably have a larger number of sp² carbons than sp³ carbons, and more preferably composed only of sp² carbons. Furthermore, when Ar₁ includes a benzene ring, the benzene ring preferably has bonding positions to the indolocarbazole ring and the pyrene ring that are meta or para to each other, and more preferably has bonding positions to the indolocarbazole ring and the pyrene ring that are para to each other.

Ar₂, Ar₄, and Ar₆

Ar₂, Ar₄, and Ar₆ are each independently selected from the group consisting of a hydrogen atom, a deuterium atom, aromatic hydrocarbon rings, and combinations of aromatic hydrocarbon rings. The aromatic hydrocarbon rings may have a substituent.

Ar₂, Ar₄, and Ar₆ may be an aromatic hydrocarbon ring having 6 or more and 30 or less carbon atoms, may be an aromatic hydrocarbon ring having 6 or more and 18 or less carbon atoms, and may be an aromatic hydrocarbon ring having 6 or more and 15 or less carbon atoms. Specifically, Ar₂, Ar₄, and Ar₆ may be a benzene ring, a naphthalene ring, a spirofluorene ring, a chrysene ring, a triphenylene ring, or a fluorene ring, may be a benzene ring, a triphenylene ring, or a fluorene ring, and may be a benzene ring or a fluorene ring. Ar₂, Ar₄, and Ar₆ may be a benzene ring or a combination of a benzene ring and a benzene ring (a biphenyl group).

When Ar₂, Ar₄, and Ar₆ are an aromatic hydrocarbon ring, the aromatic hydrocarbon ring may have a substituent. The substituent may be a deuterium atom, a substituted or unsubstituted alkyl group having 1 or more and 6 or less carbon atoms, or a substituted or unsubstituted aryl group having 6 or more and 18 or less carbon atoms. Specifically, the substituent may be a deuterium atom, a phenyl group, a phenyl group having a deuterium atom, a naphthyl group, a phenyl group having a tert-butyl group, one or two or more methyl groups, one or two or more iso-propyl groups, a tert-butyl group, a tert-butyl group having a deuterium atom, a triphenylene group, a cyclohexyl group, or a phenyl group having a CD₃ group.

Ar₂, Ar₄, and Ar₆ may be a deuterium atom, a substituted or unsubstituted alkyl group having 1 or more and 4 or less carbon atoms, or a substituted or unsubstituted aryl group having 6 or more and 18 or less carbon atoms. Specifically, Ar₂, Ar₄, and Ar₆ may be a deuterium atom, a phenyl group, a naphthyl group, a phenyl group having an alkyl group having 1 or more and 4 or less carbon atoms, one or two or more methyl groups, a tert-butyl group having a deuterium atom, a triphenylene group, or a triphenylene group having a phenyl group.

Ar₂, Ar₄, and Ar₆ may be a deuterium atom, a substituted or unsubstituted alkyl group having 1 or more and 4 or less carbon atoms, or a substituted or unsubstituted aryl group having 6 or more and 18 or less carbon atoms. Specifically, Ar₂, Ar₄, and Ar₆ may be a deuterium atom, a phenyl group, a phenyl group having a tert-butyl group, one or two or more methyl groups, or a triphenylene group.

Ar₂, Ar₄, and Ar₆ may be a deuterium atom, a substituted or unsubstituted alkyl group having 1 or more and 4 or less carbon atoms, or a phenyl group having an alkyl group having 3 or 4 carbon atoms. Specifically, Ar₂, Ar₄, and Ar₆ may be a deuterium atom, one or two or more methyl groups, or a phenyl group having a tert-butyl group. Ar₂, Ar₄, and Ar₆ may have no substituent.

n, m, and p

n, m, and p are 0 or 1, and n, m, and p are preferably 0. In other words, the indolocarbazole skeleton and the pyrene skeleton are preferably directly bonded to each other.

Specific examples of the organic compound according to the present embodiment will be described below. However, the present embodiment is not limited thereto.

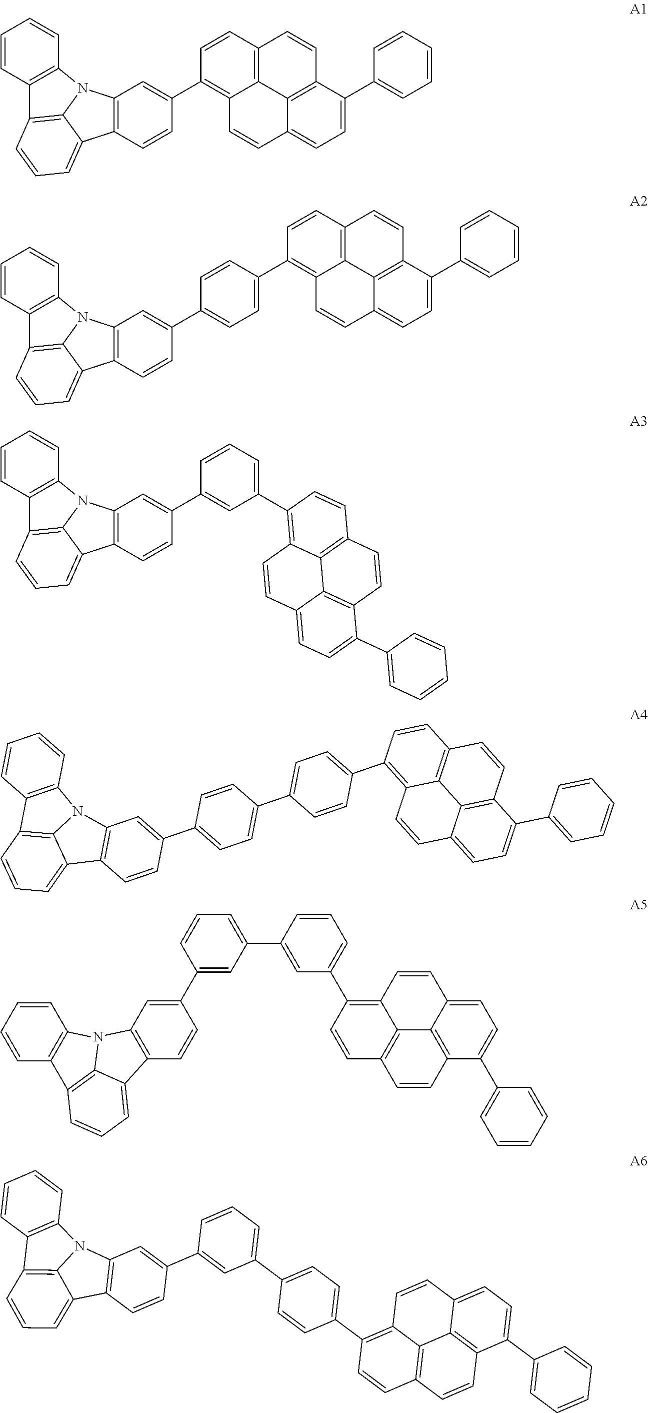

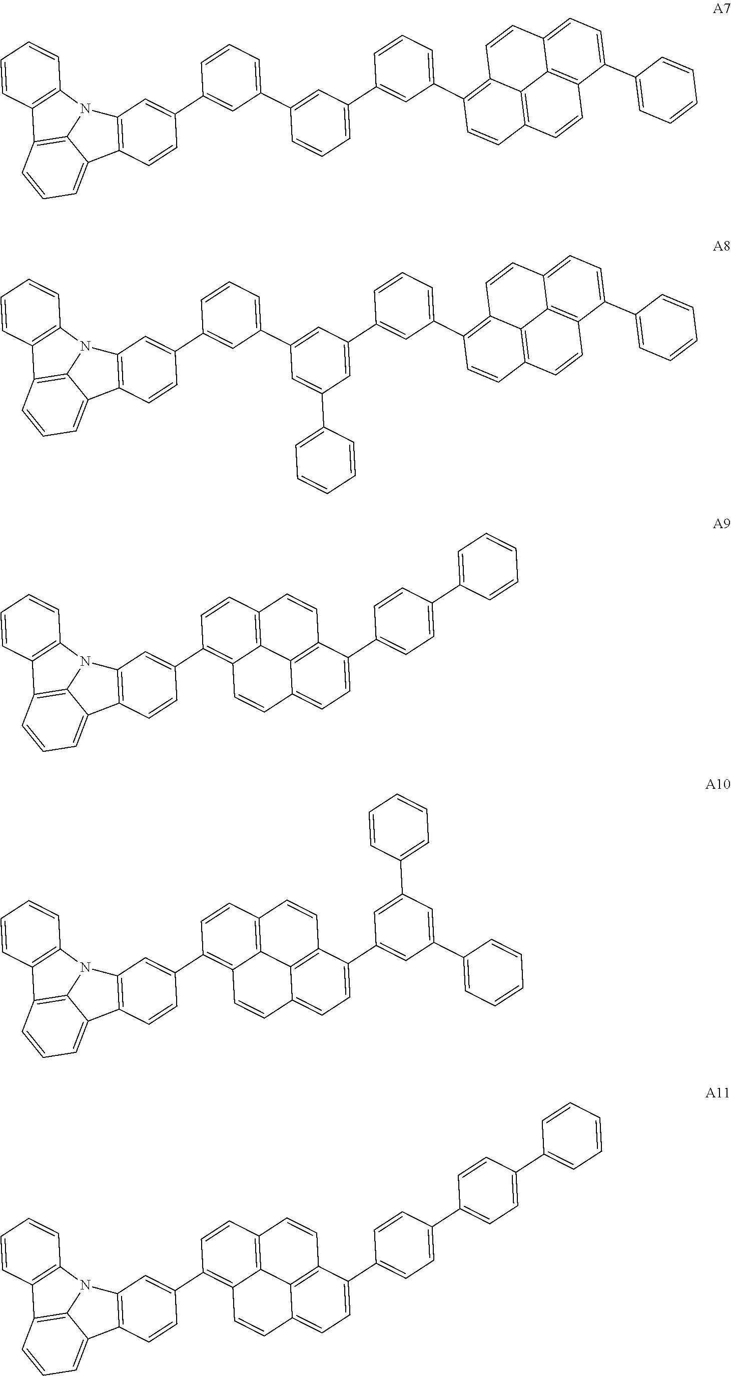

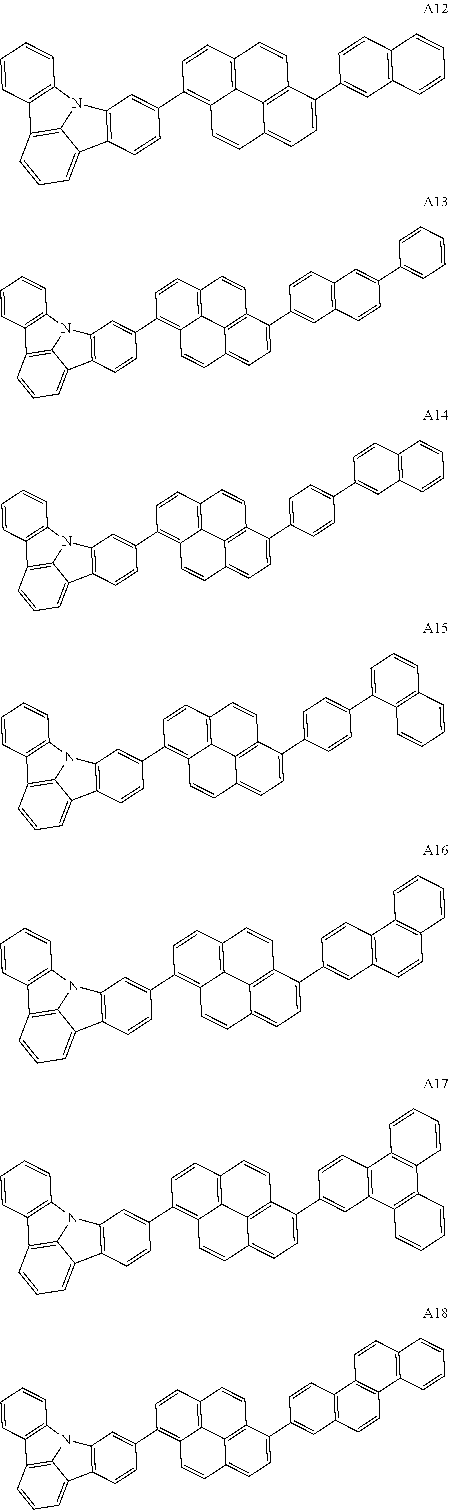

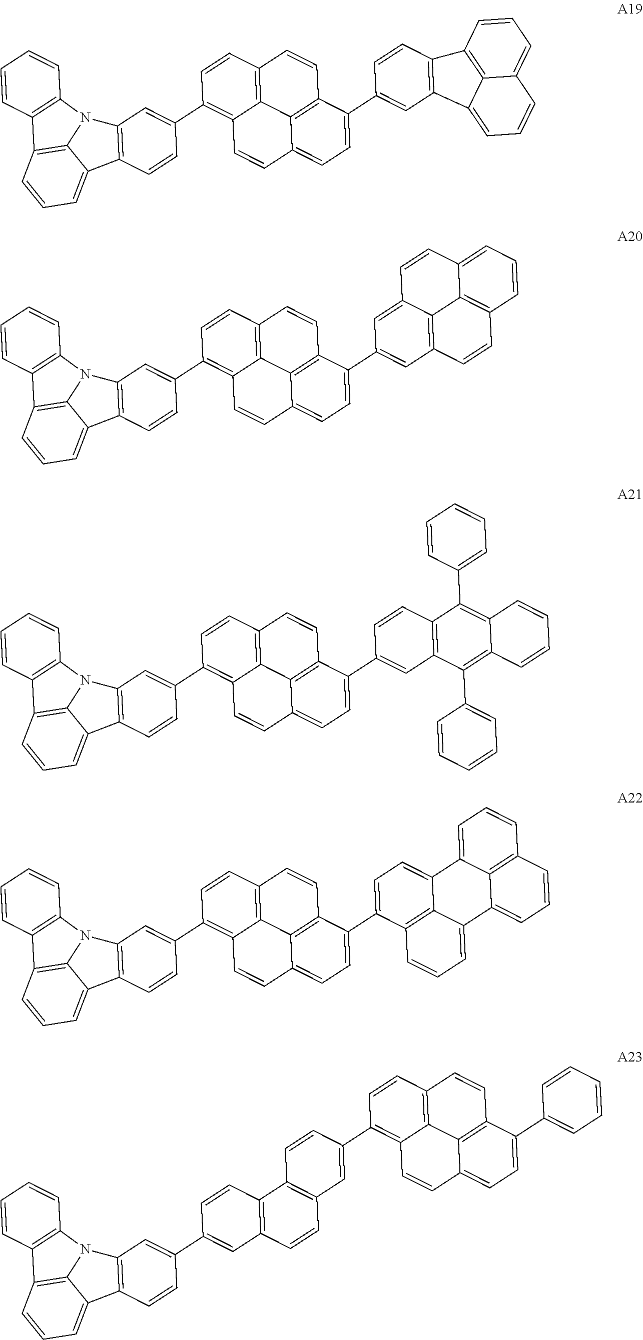

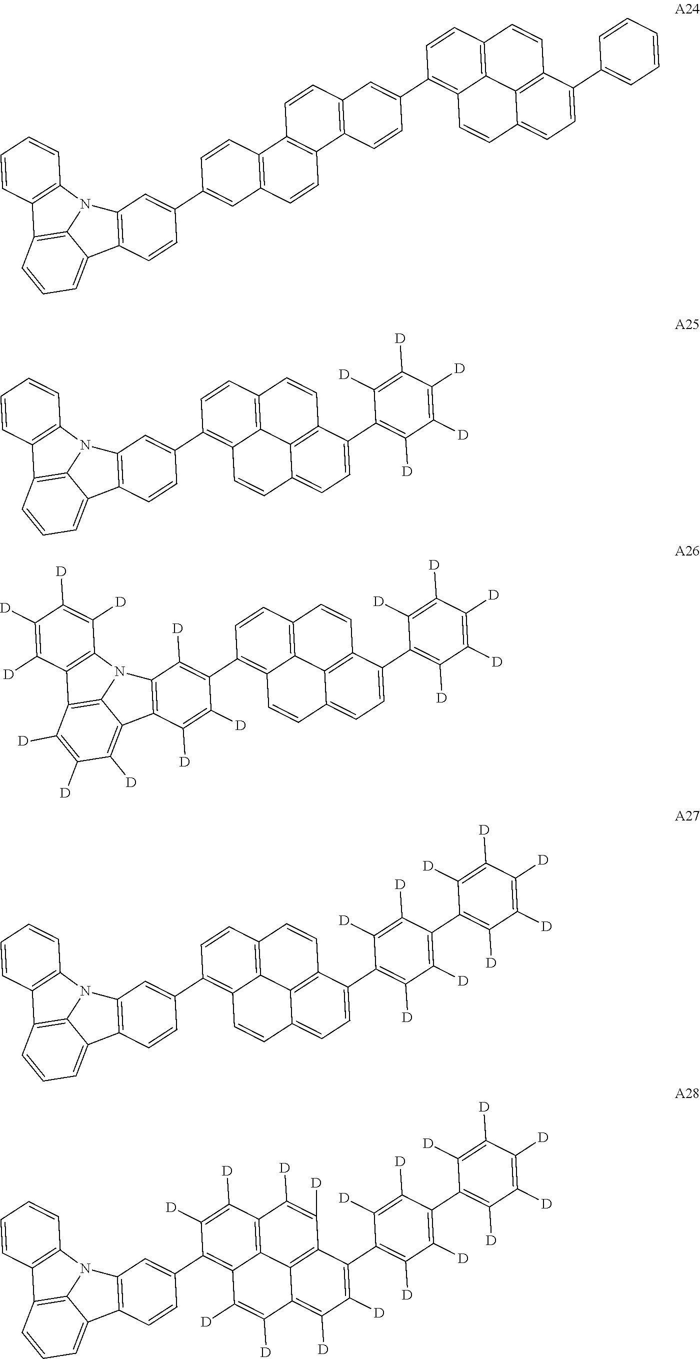

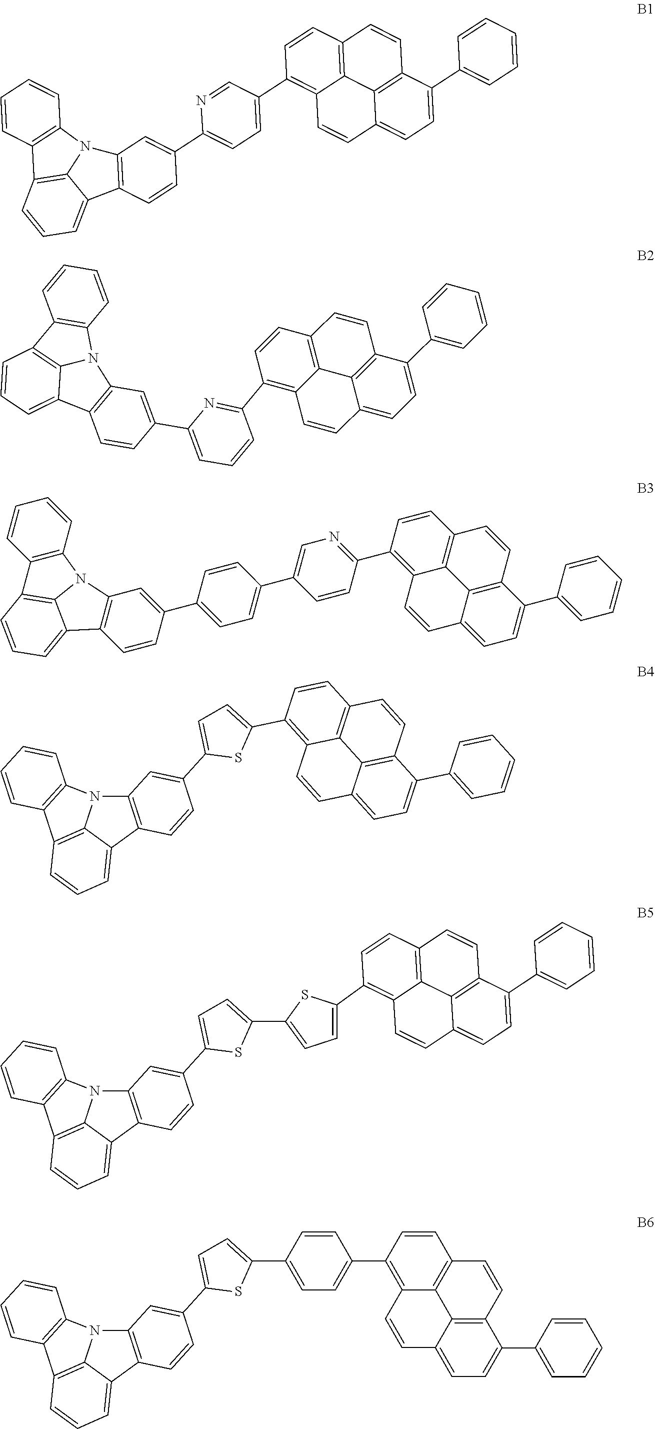

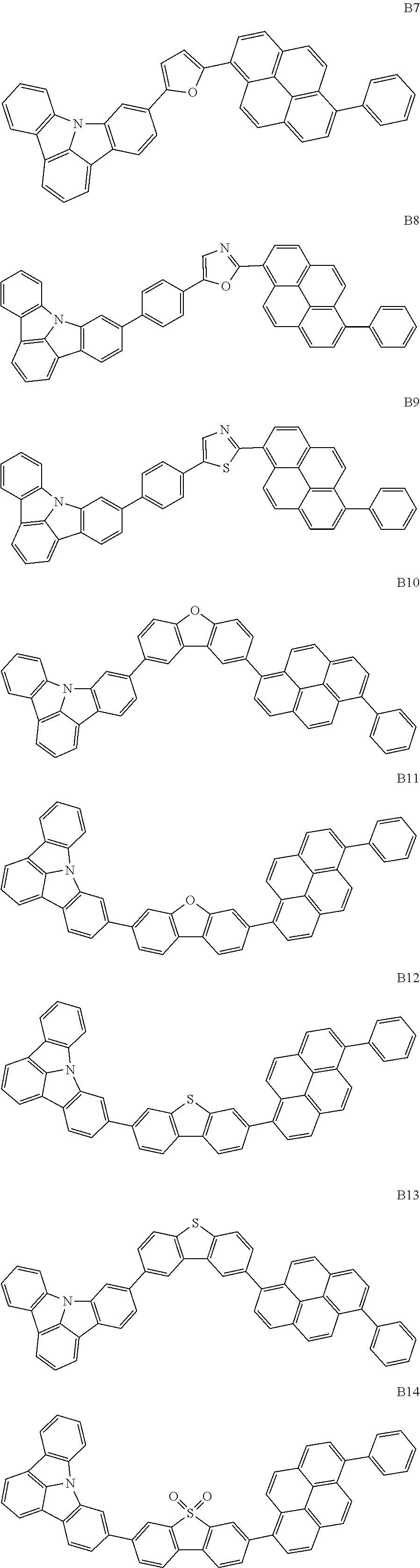

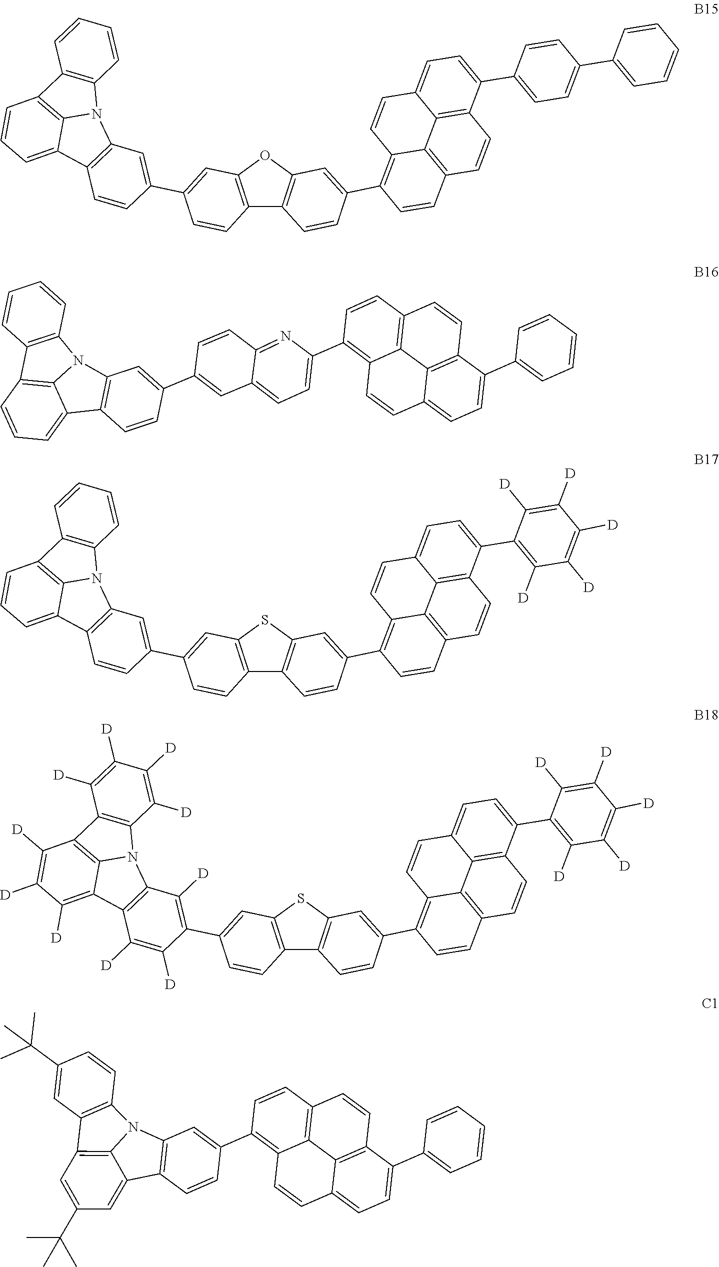

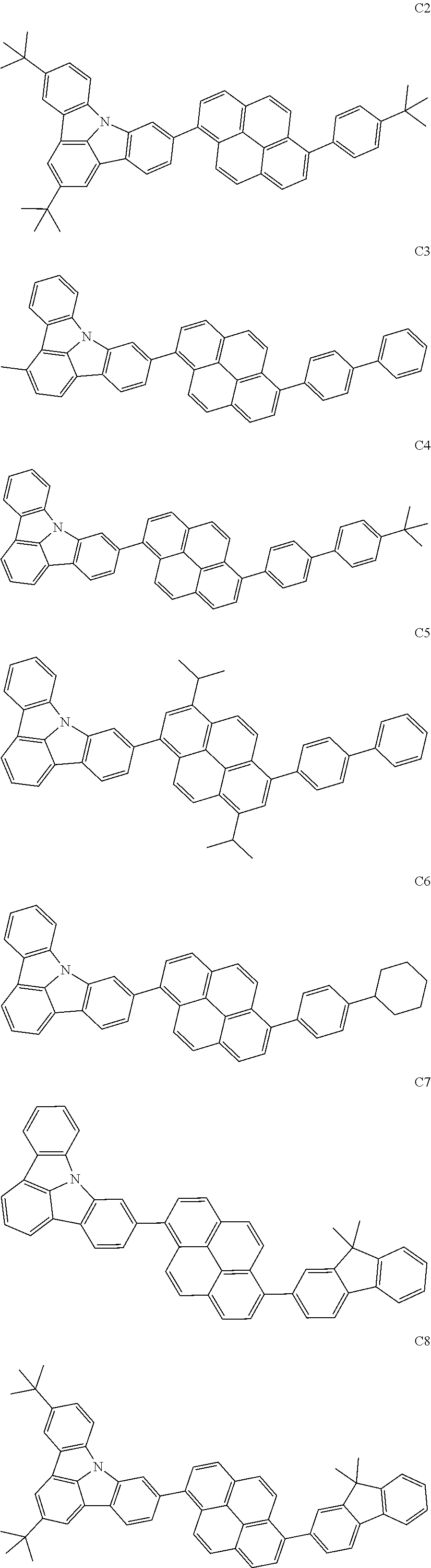

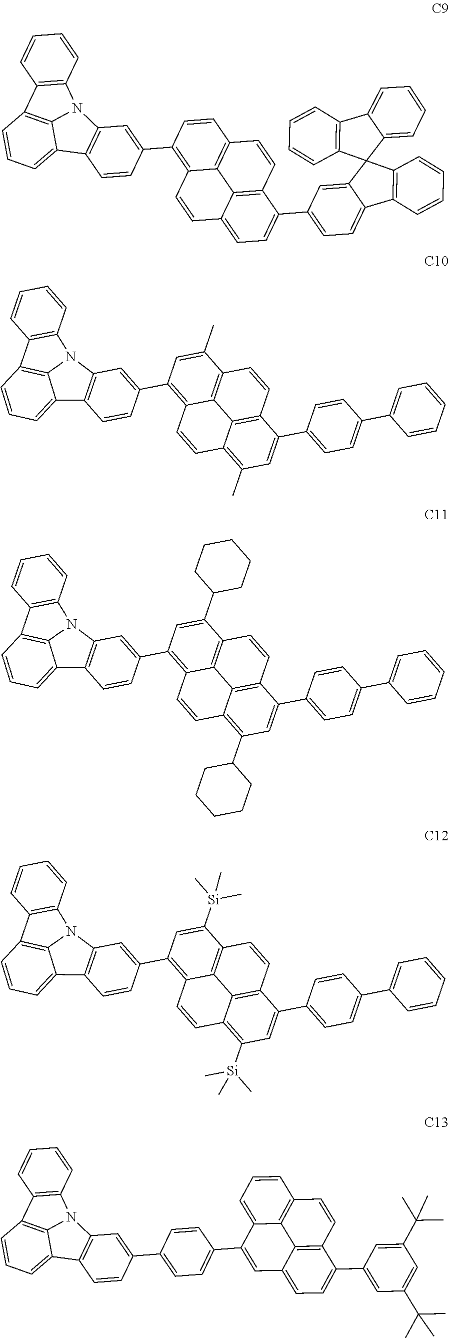

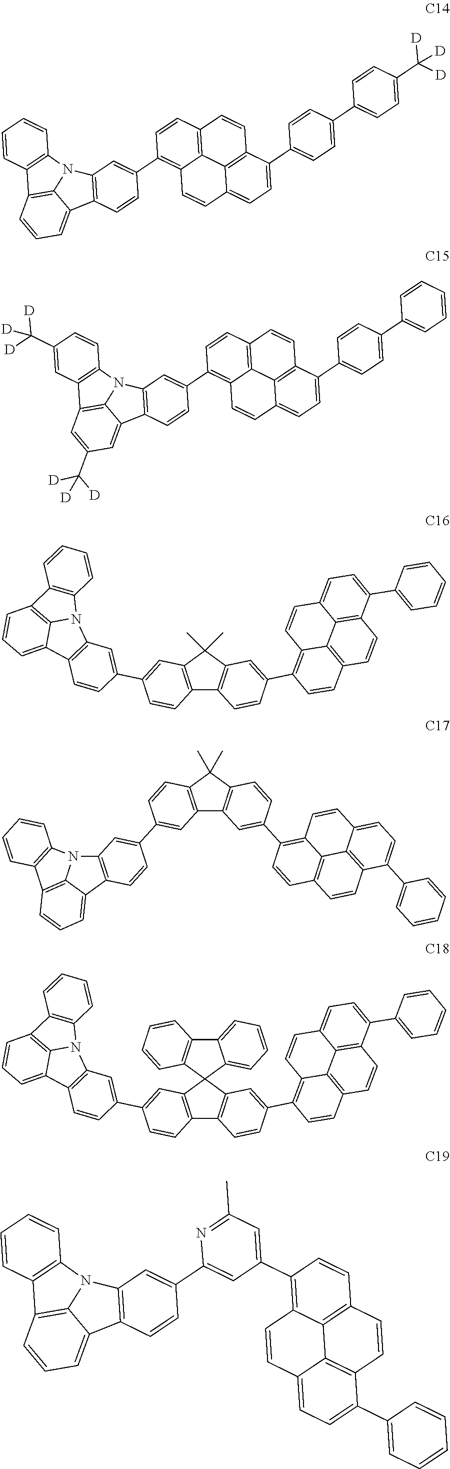

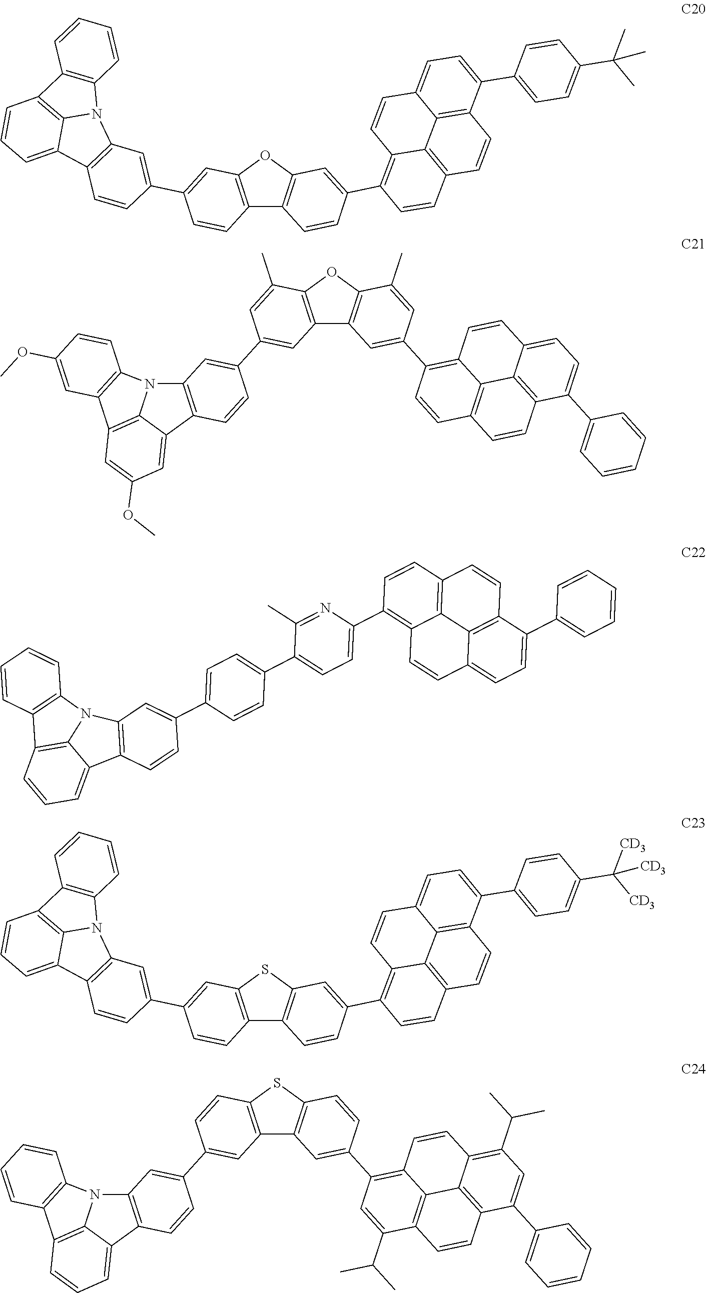

The exemplary compounds belonging to Group A are compounds in which the entire molecule is composed of sp² carbon atoms. Therefore, the compounds are particularly organic compounds having excellent durability among the organic compounds according to the present embodiment.

The exemplary compounds belonging to Group B are compounds in which Ar₁, Ar₃, and Ar₅ have a heteroaromatic ring. Therefore, charge transportability is improved to provide particularly low-voltage organic light emitting elements.

The exemplary compounds belonging to Group C are compounds having an alkyl group, a silyl group, or a spirofluorene ring. Therefore, the organic compounds according to the present embodiment are bulky, and intermolecular stacking can be reduced; accordingly, the compounds are particularly organic compounds having excellent luminous efficiency.

(1-4) Organic Compound Includes Indolocarbazole Skeleton in which Substituent is Provided at Meta Position Relative to Nitrogen Atom

The organic compound according to the present embodiment is preferably an organic compound that includes an indolocarbazole skeleton in which a substituent is provided at a meta position relative to the nitrogen atom of the indolocarbazole skeleton.

Because of this feature, the HOMO of the organic compound according to the present embodiment becomes lower (farther from the vacuum level), so that the organic compound has more excellent durability. Among the general formulas (1) to (3), the organic compound according to the present embodiment is more preferably the organic compound represented by the general formula (1).

Here, in a benzene ring having a carbon-nitrogen bond, electron donating ability at the meta position relative to the nitrogen atom is smaller than that at the para position. Therefore, when the substituent is provided at the meta position relative to the nitrogen atom, the HOMO becomes lower as compared with the case where the substituent is provided at the para position. As a result, the organic compound according to the present embodiment has excellent oxidation stability and therefore excellent durability.

Table 2 describes the HOMO of the exemplary compound A9 and compounds 2-a and 2-b.

TABLE 2

| | HOMO/ |
|---|---|
| Molecular structure | eV |
| 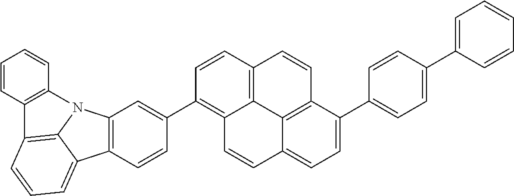 [SMILES: c1ccc(-c2ccc(-c3ccc4ccc5c(-c6ccc7c8cccc9c%10ccccc%10n(c7c6)c98)ccc6ccc3c4c65)cc2)cc1] | −5.15 |
| A 9 | |
| 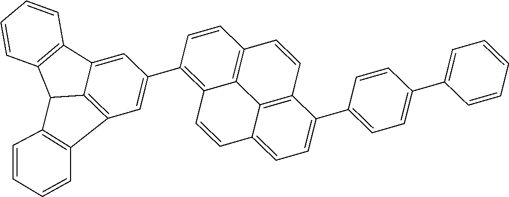 [SMILES: c1ccc(-c2ccc(-c3ccc4ccc5c(-c6cc7c8c(c6)-c6ccccc6C8c6ccccc6-7)ccc6ccc3c4c65)cc2)cc1] | −5.08 |
| 2-a | |
| 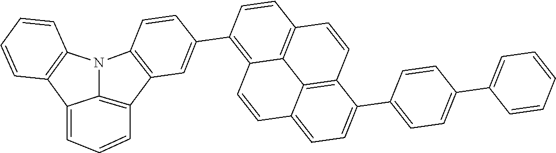 [SMILES: c1ccc(-c2ccc(-c3ccc4ccc5c(-c6ccc7c(c6)c6cccc8c9ccccc9n7c86)ccc6ccc3c4c65)cc2)cc1] | −5.09 |
| 2-b | |

In Table 2, the HOMO of the exemplary compound A9 is a value lower than the HOMO of the compounds 2-a and 2-b. This is because the exemplary compound A9 has pyrene bonded at the meta position relative to the nitrogen atom of indolocarbazole, and therefore the HOMO is a low value.

Thus, the organic compound according to the present embodiment has a low HOMO and hence is an organic compound having excellent oxidation stability. Therefore, the organic light emitting element using the organic compound according to the present embodiment has more excellent durability.

### (1-5) Light Emitting Material Emits Fluorescence

The light emitting material of the organic light emitting element according to the present embodiment is preferably a compound that emits fluorescence.

The organic light emitting element according to the present embodiment has a configuration in which triplet-state excitons in the organic compound are converted into singlet-state excitons and subsequently energy can be efficiently transferred to the light emitting material. Therefore, when the light emitting material is a compound that emits fluorescence, the generated excitons can be efficiently used for light emission, which is preferable from the viewpoint of luminous efficiency.

In addition, fluorescent emission has a shorter emission lifetime than phosphorescent emission. Thus, degradation of the light emitting layer due to excitons can be reduced. As a result, the organic light emitting element according to the present embodiment also has more excellent durability.

Note that the material that emits fluorescence refers to an organic compound and does not encompass organometallic complexes.

Hereinafter, specific examples of the light emitting material that can be used in the organic light emitting element according to the present embodiment will be described.

However, the present disclosure is not limited thereto.

The light emitting material of the organic light emitting element according to the present embodiment can be represented by a general formula (4).

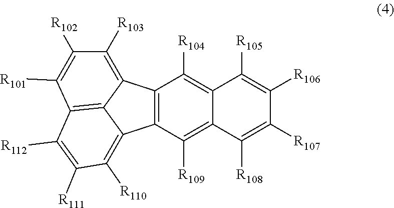

In the general formula (4), R₁₀₁ to R₁₁₂ are each independently selected from the group consisting of a hydrogen atom, a deuterium atom, substituted or unsubstituted alkyl groups, substituted or unsubstituted alkoxy groups, substituted or unsubstituted aryl groups, substituted or unsubstituted aryloxy groups, substituted or unsubstituted heteroaryl groups, substituted or unsubstituted heteroaryloxy groups, substituted or unsubstituted amino groups, and a cyano group. R₁₀₁ to R₁₁₂ may be bonded together to form a ring.

R₁₀₁ to R₁₁₂ may each be independently selected from the group consisting of a hydrogen atom, a deuterium atom, substituted or unsubstituted alkyl groups, substituted or unsubstituted aryl groups, substituted or unsubstituted heteroaryl groups, and a cyano group. R₁₀₁ to R₁₁₂ may each be independently selected from the group consisting of a hydrogen atom, a deuterium atom, substituted or unsubstituted alkyl groups having 1 or more and 6 or less carbon atoms, substituted or unsubstituted aryl groups having 6 or more and 18 or less carbon atoms, substituted or unsubstituted heteroaryl groups having 5 or more and 12 or less carbon atoms, and a cyano group.

The ring formed by bonding together R₁₀₁ to R₁₁₂ may be an aromatic hydrocarbon ring or a heteroaromatic ring, and is preferably an aromatic hydrocarbon ring. Specifically, when R₁₀₁ to R₁₁₂ are bonded together to form a ring, the basic skeleton of the light emitting material is preferably any one of FF7 to FF42, more preferably any one of FF7 to FF16, and still more preferably FF12 or FF14. Here, the basic skeleton refers to, in the organic compound according to the general formula (4), a skeleton in which, among R₁₀₁ to R₁₁₂, all R's that are not bonded together to form a ring are hydrogen atoms.

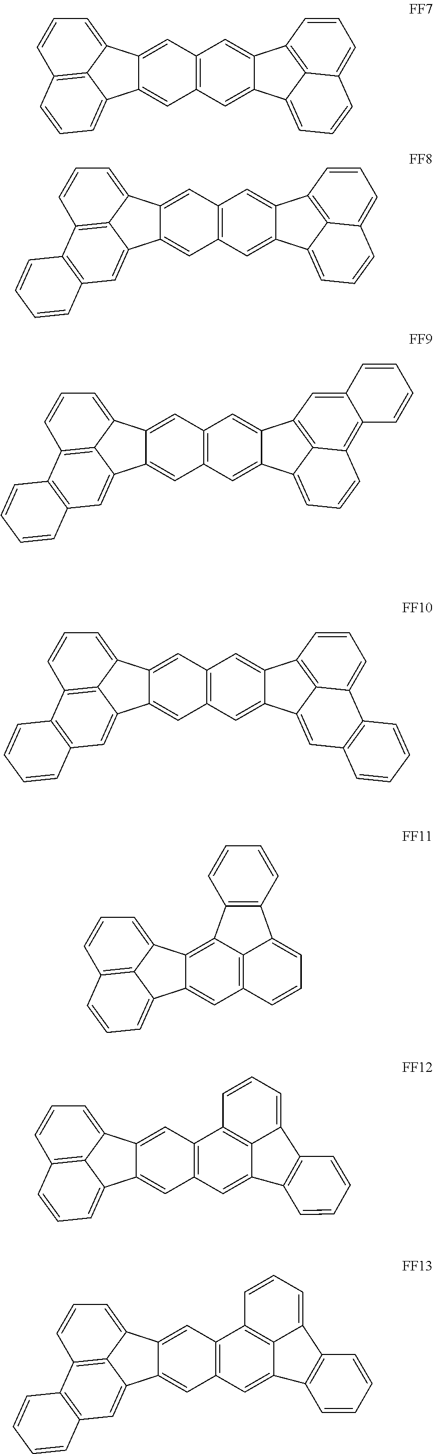

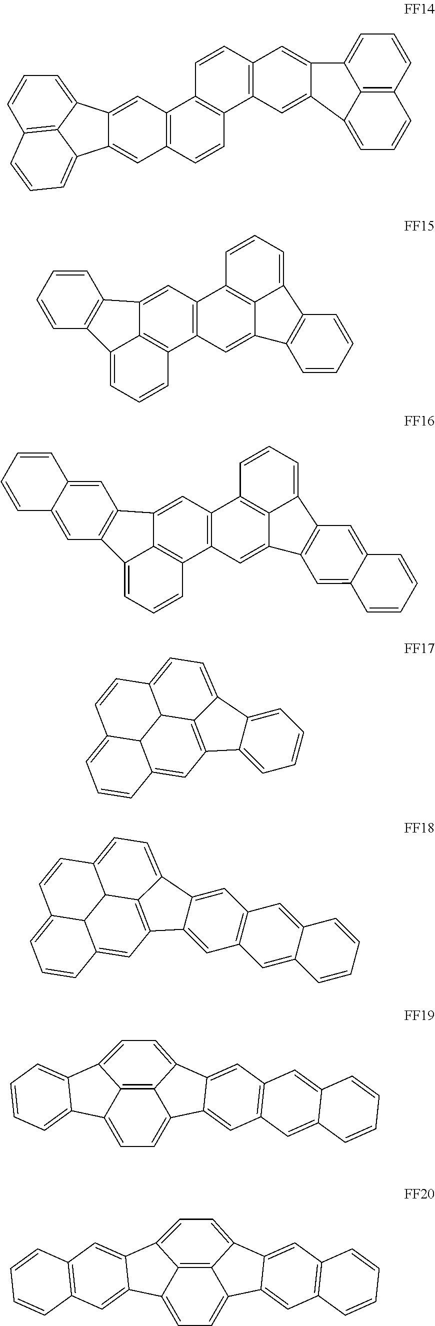

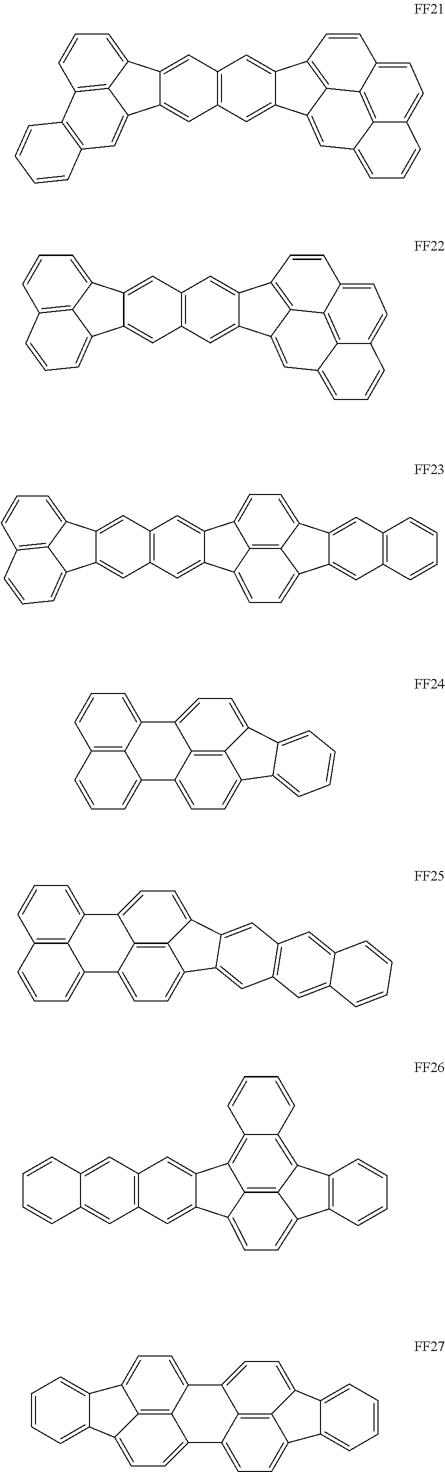

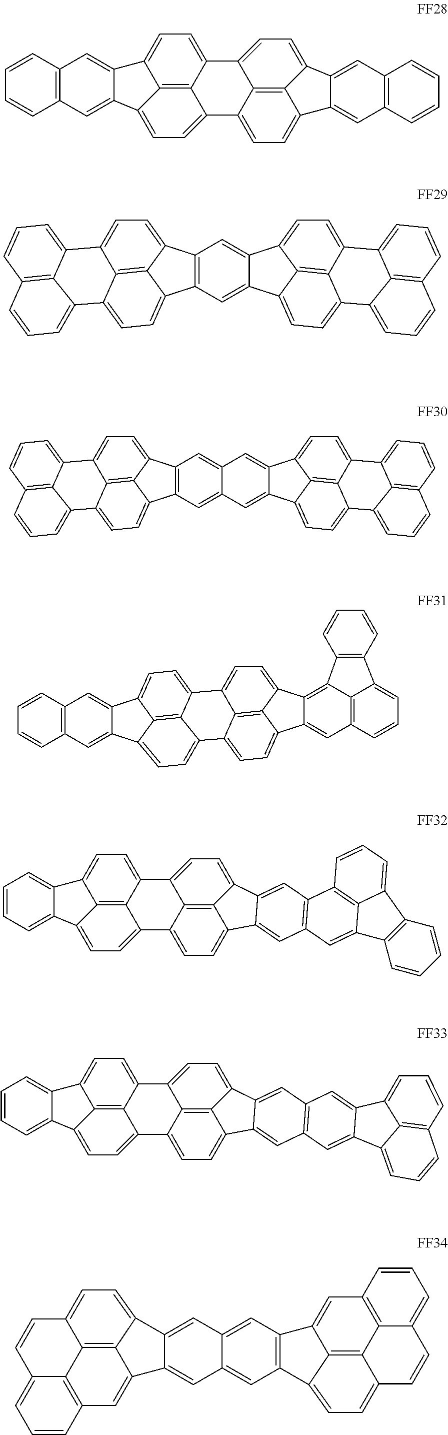

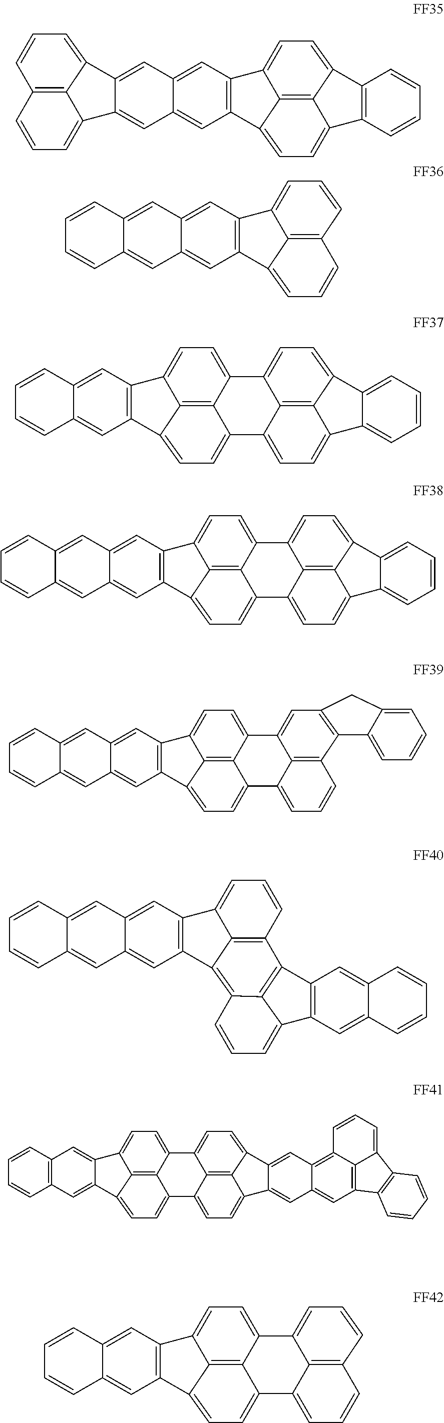

The light emitting material of the organic light emitting element according to the present embodiment can be represented by any one of general formulas (5) to (8).

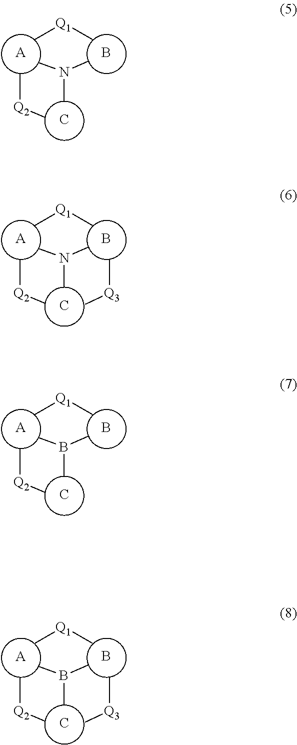

In the general formulas (5) to (8), the cyclic units A to C are each independently selected from substituted or unsubstituted aryl groups or substituted or unsubstituted heteroaryl groups. Q₁ to Q₃ are each independently selected from a direct bond, a boron atom, C(R_{A})(R_{B}), N(R_{C}), an oxygen atom, a sulfur atom, a selenium atom, or a tellurium atom. R_{A} to R_{C} are each independently selected from a hydrogen atom, a deuterium atom, halogen atoms, substituted or unsubstituted alkyl groups, substituted or unsubstituted alkoxy groups, substituted or unsubstituted aryl groups, or substituted or unsubstituted heteroaryl groups. R_{C} and adjacent cyclic units A to C may form rings.

The light emitting material of the organic light emitting element according to the present embodiment can be represented by a general formula (9).

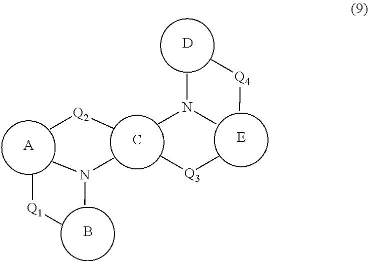

In the general formula (9), the cyclic units A to E are each independently selected from substituted or unsubstituted aryl groups or substituted or unsubstituted heteroaryl groups. The cyclic units A to E may be a substituted or unsubstituted benzene skeleton. Alternatively, the cyclic units A, B, D, and E may be a substituted or unsubstituted benzene skeleton, and the cyclic unit C may be a substituted or unsubstituted benzene skeleton or naphthalene skeleton. Q₁ to Q₃ are each independently selected from a direct bond, C(R_{A})(R_{B}), N(R_{C}), B(R_{D}), an oxygen atom, a sulfur atom, a selenium atom, or a tellurium atom. Q₁ to Q₄ may be a direct bond. R_{A} to R_{D} are each independently selected from a hydrogen atom, a deuterium atom, halogen atoms, substituted or unsubstituted alkyl groups, substituted or unsubstituted alkoxy groups, substituted or unsubstituted aryl groups, or substituted or unsubstituted heteroaryl groups.

### (2) Other Compounds

The organic light emitting element according to the present embodiment may include an organic compound layer other than the light emitting layer constituting the organic light emitting element. As necessary, publicly known low-molecular or polymer hole injection compounds or hole transport compounds, compounds serving as a host, light emitting compounds, electron injection compounds or electron transport compounds, and the like can be additionally used. Hereinafter, examples of these compounds will be described.

Such hole injection/transport materials are preferably materials having high hole mobility in order to facilitate injection of holes from an anode and to transport the injected holes to the light emitting layer. In addition, the materials preferably have a high glass transition temperature in order to reduce deterioration of film quality such as crystallization in the organic light emitting element. Examples of the low-molecular or polymer materials having hole injection/transport performance include triarylamine derivatives, arylcarbazole derivatives, phenylenediamine derivatives, stilbene derivatives, phthalocyanine derivatives, porphyrin derivatives, poly(vinylcarbazole), poly(thiophene), and other conductive polymers. The above-described hole injection/transport materials are also suitably used for an electron blocking layer. Hereinafter, specific examples of the compounds used as the hole injection/transport materials will be described; however, the present disclosure is of course not limited thereto.

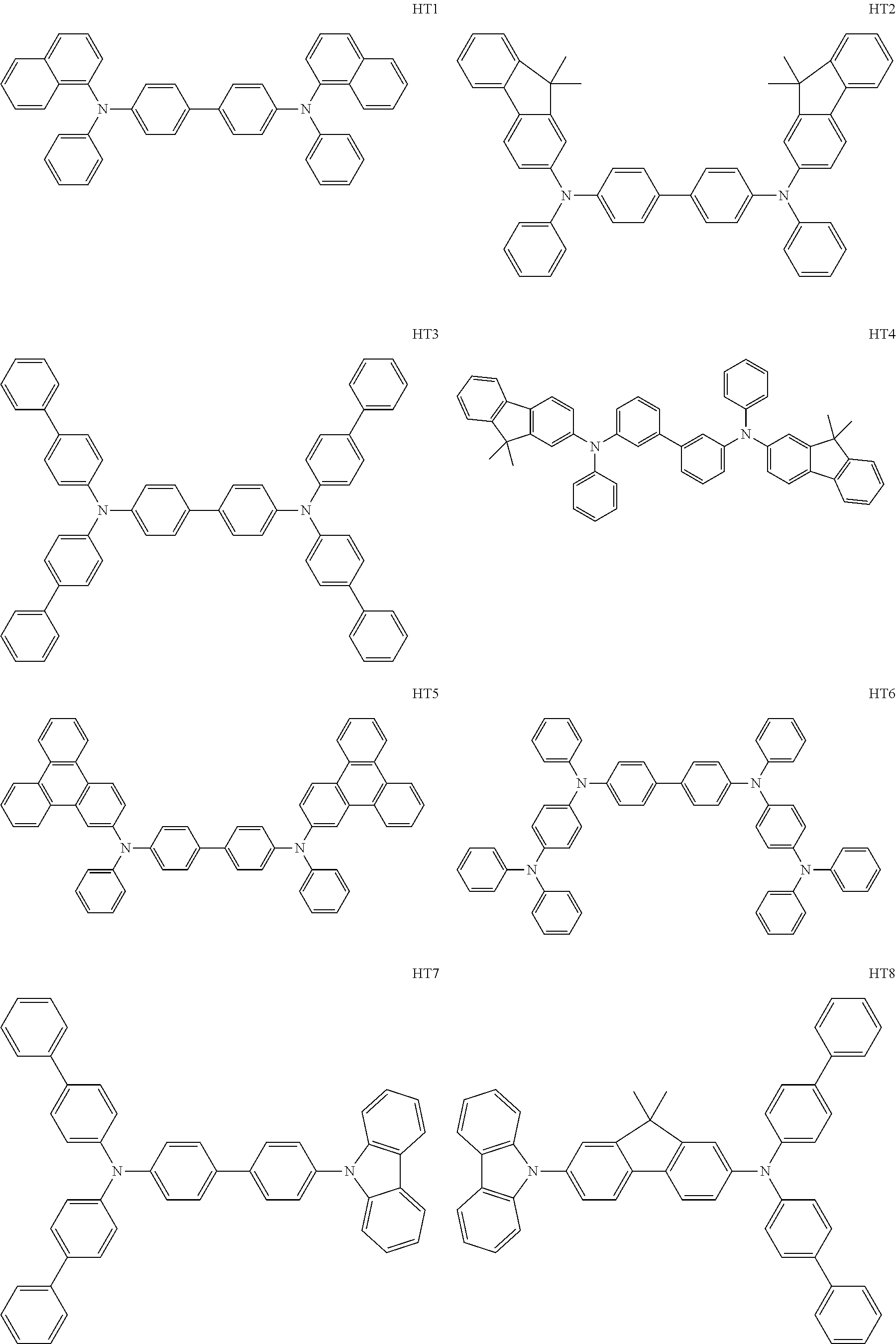

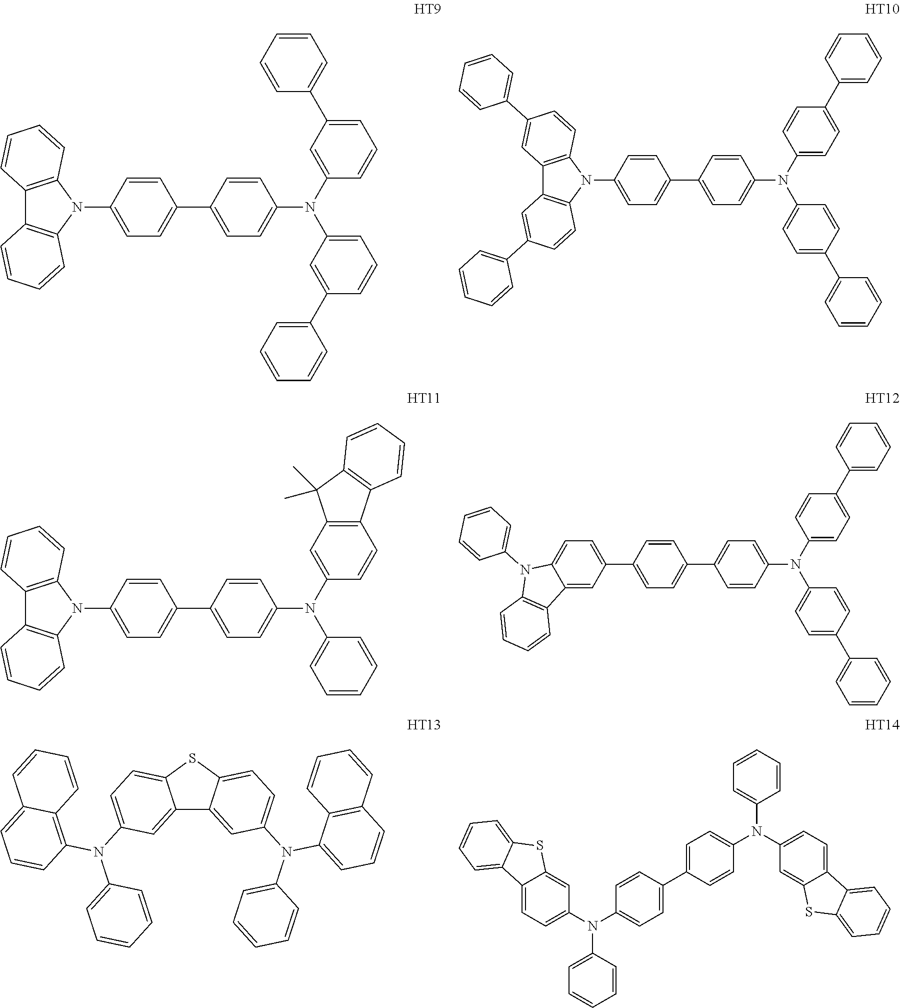

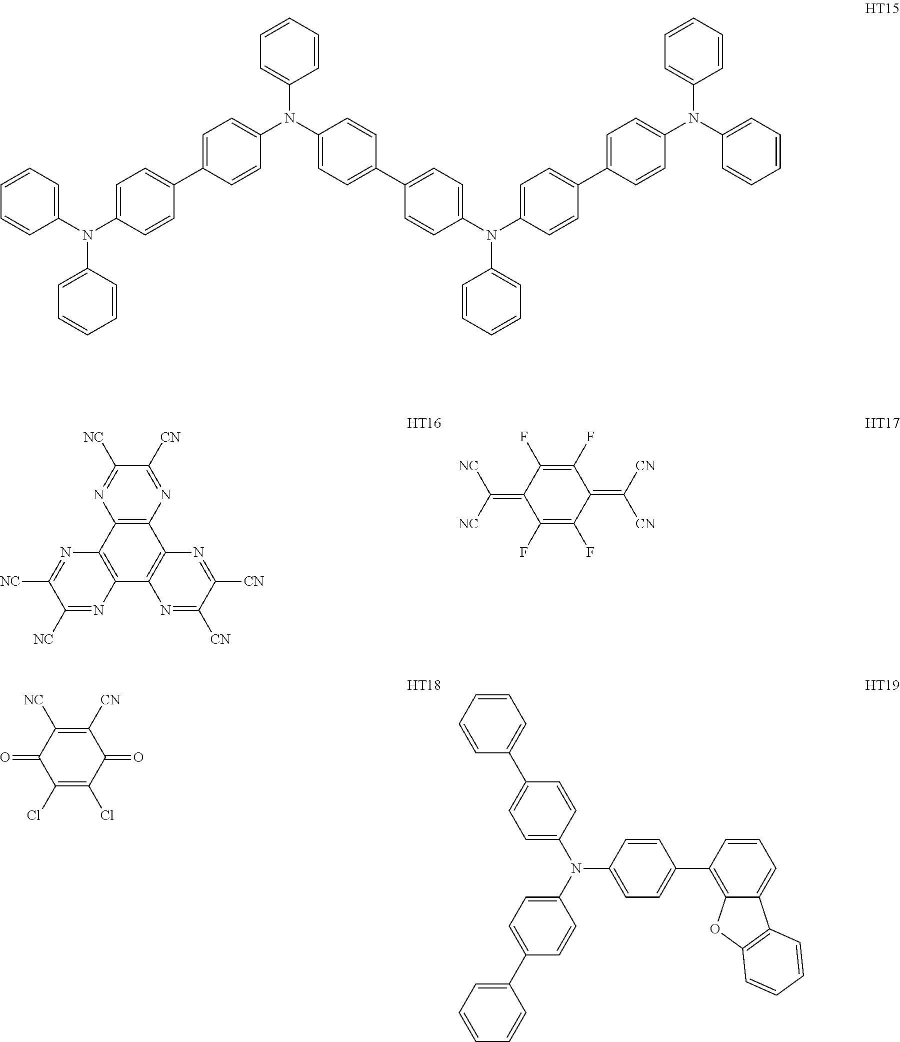 [SMILES: c1ccc(N(c2ccccc2)c2ccc(-c3ccc(N(c4ccccc4)c4ccc(-c5ccc(N(c6ccccc6)c6ccc(-c7ccc(N(c8ccccc8)c8ccccc8)cc7)cc6)cc5)cc4)cc3)cc2)cc1 ; N#Cc1nc2c3nc(C#N)c(C#N)nc3c3nc(C#N)c(C#N)nc3c2nc1C#N ; N#CC(C#N)=c1c(F)c(F)c(=C(C#N)C#N)c(F)c1F ; N#CC1=C(C#N)C(=O)C(Cl)=C(Cl)C1=O ; c1ccc(-c2ccc(N(c3ccc(-c4ccccc4)cc3)c3ccc(-c4cccc5c4oc4ccccc45)cc3)cc2)cc1]

Among the above-described hole transport materials, HT16 to HT18 can reduce a driving voltage when used in a layer in contact with an anode. HT16 is widely used in organic light emitting elements. In an organic compound layer adjacent to HT16, HT2, HT3, HT4, HT5, HT6, HT10, or HT12 may be used. A plurality of materials may be used in a single organic compound layer.

Examples of light emitting materials mainly contributing to light emitting function include fused ring compounds (for example, fluorene derivatives, naphthalene derivatives, pyrene derivatives, perylene derivatives, tetracene derivatives, anthracene derivatives, and rubrene), quinacridone derivatives, coumarin derivatives, stilbene derivatives, organic aluminum complexes such as tris(8-quinolinolato)aluminum, iridium complexes, platinum complexes, rhenium complexes, copper complexes, europium complexes, ruthenium complexes, and polymer derivatives such as poly(phenylene vinylene) derivatives, poly(fluorene) derivatives, and poly(phenylene) derivatives.

Hereinafter, specific examples of compounds used as the light emitting material will be described; however, the present disclosure is of course not limited thereto.

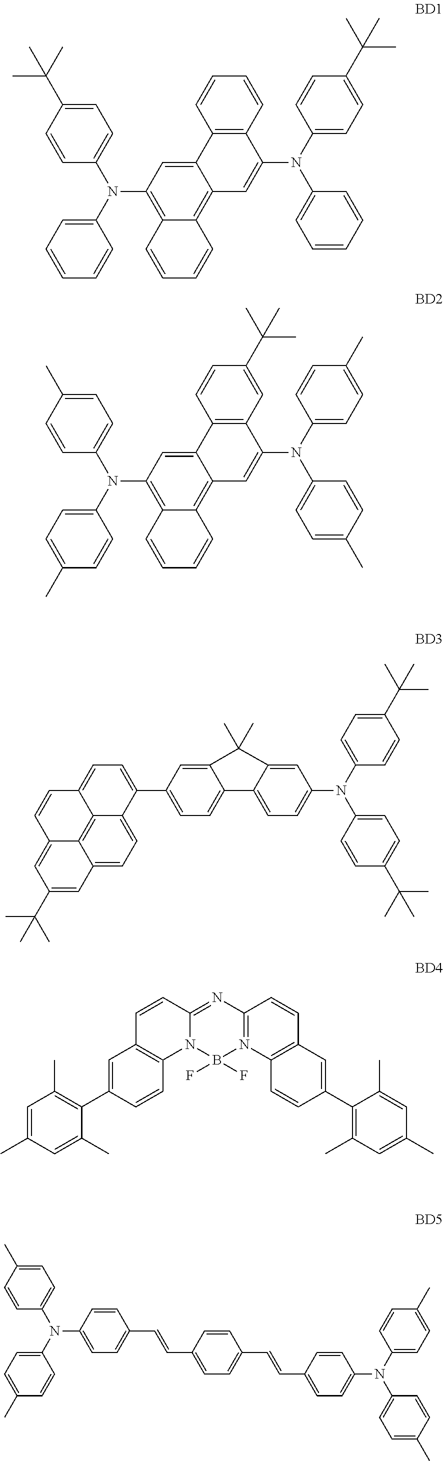

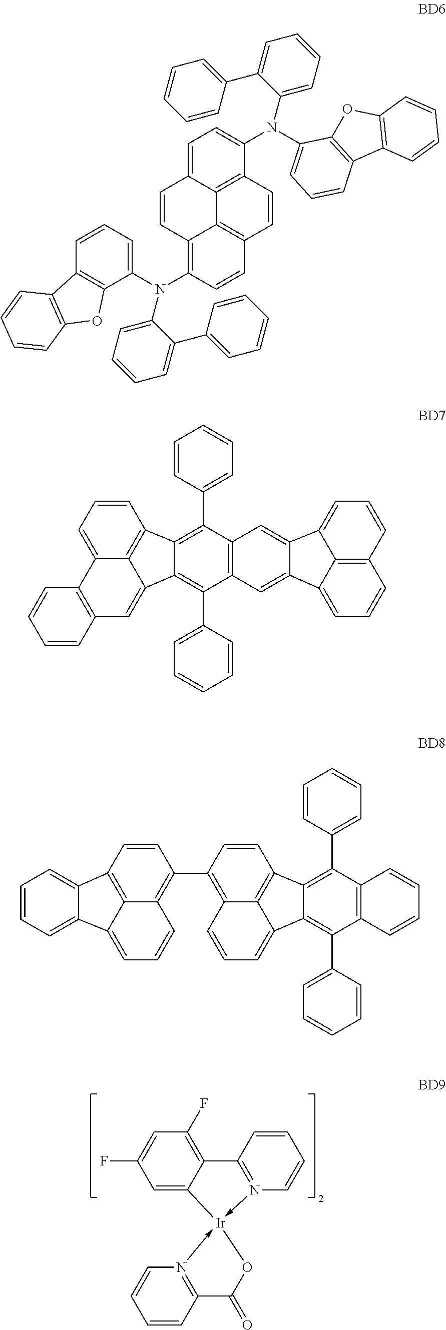

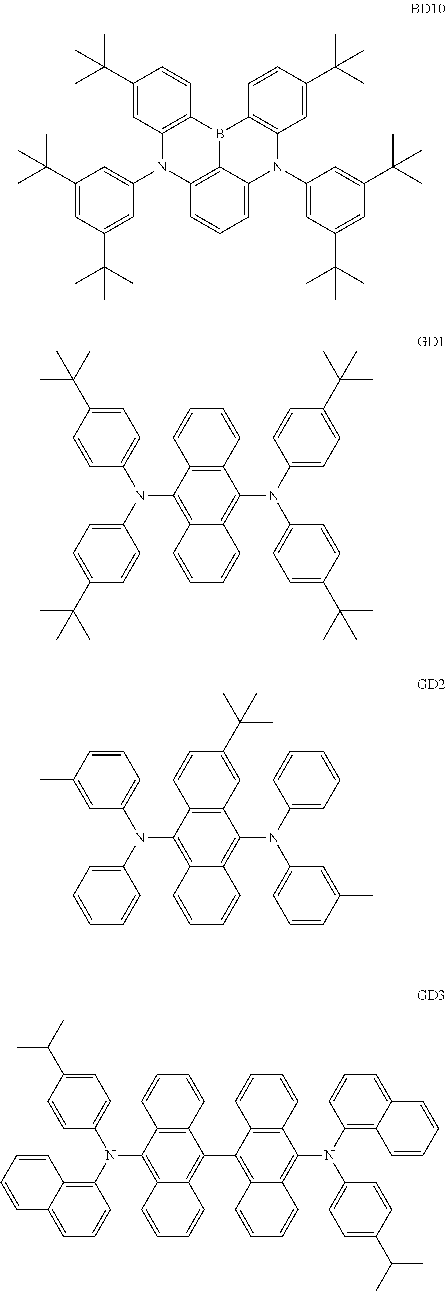

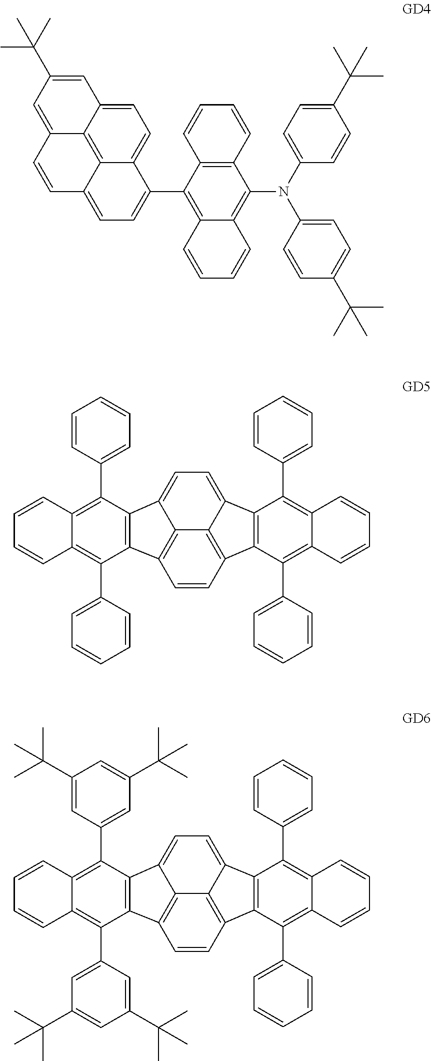

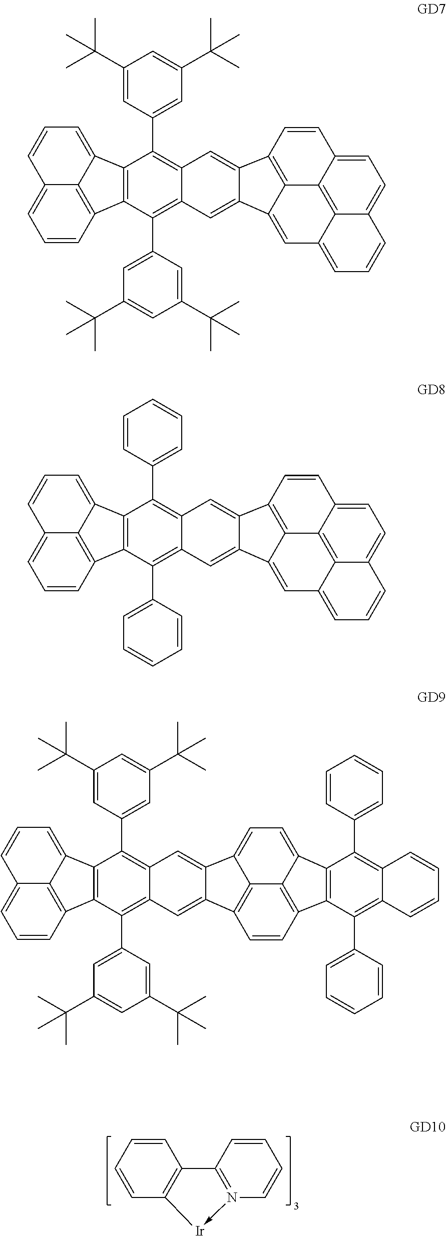

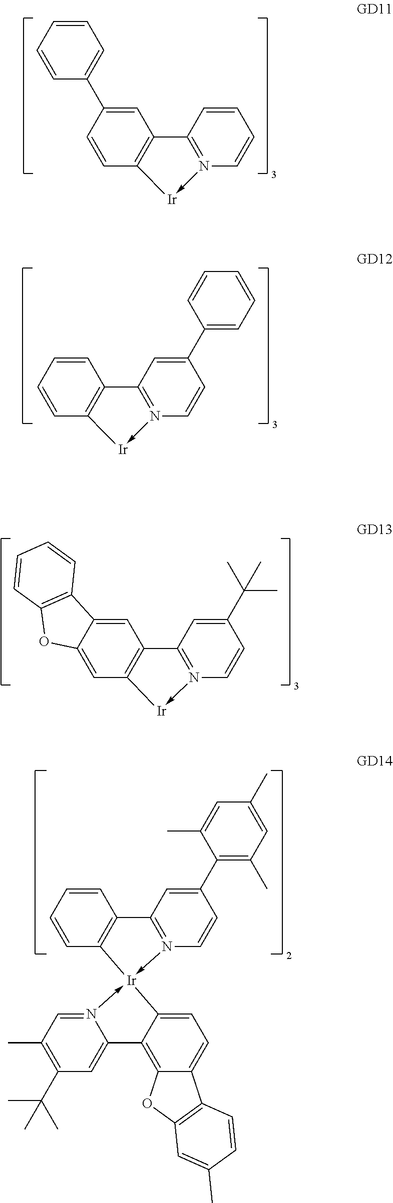

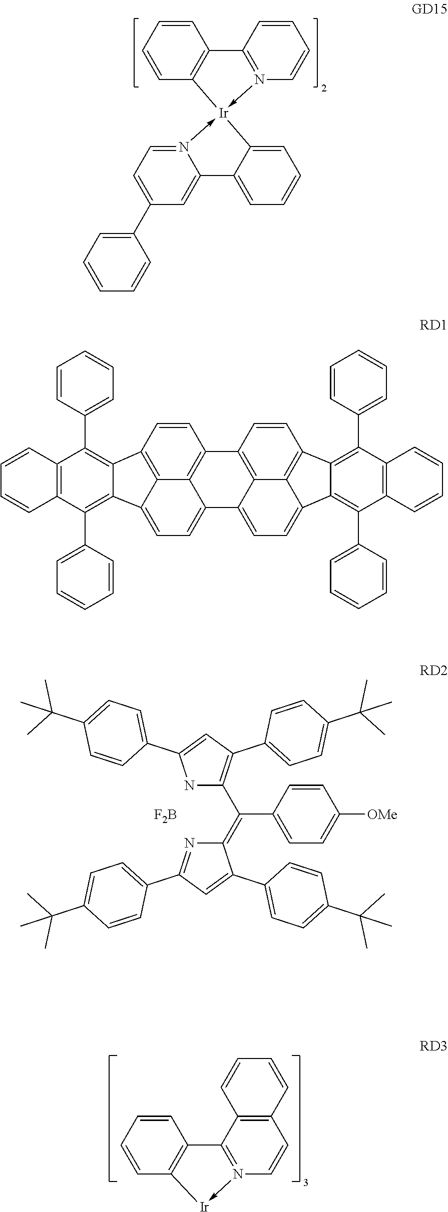

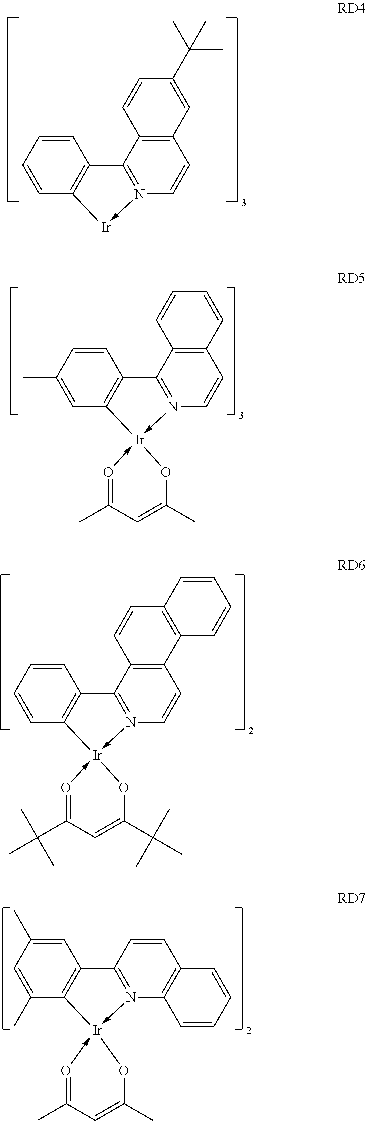

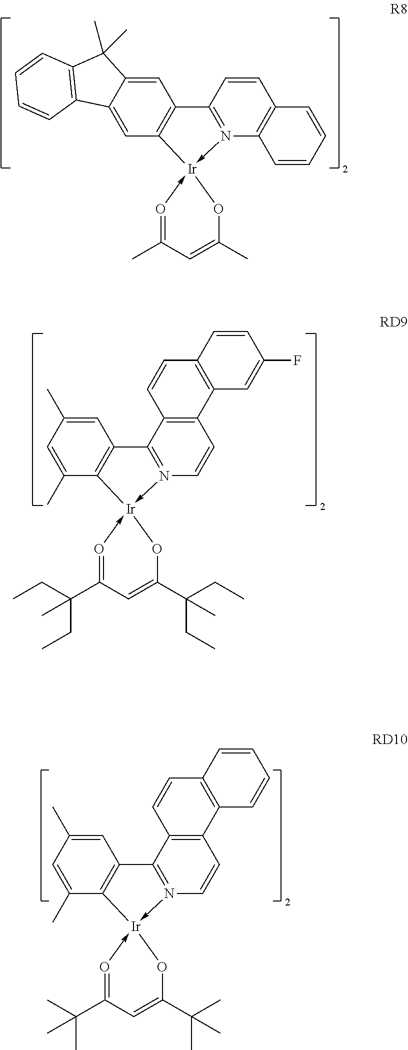

The light emitting material is preferably a hydrocarbon compound because decrease in luminous efficiency due to exciplex formation and decrease in color purity due to change in an emission spectrum of the light emitting material caused by exciplex formation can be reduced.

The hydrocarbon compound is a compound composed only of carbon and hydrogen; the above-described exemplary compounds that are hydrocarbon compounds are BD7, BD8, GD5 to GD9, and RD1.

The light emitting material is preferably a fused polycyclic compound including a five-membered ring because it has a high ionization potential and hence is less likely to be oxidized to provide an element having a highly durable lifetime. The above-described exemplary compounds that fall under this category are BD7, BD8, GD5 to GD9, and RD1.

Examples of the host for the light emitting layer or the emission-assist material contained in the light emitting layer include, in addition to aromatic hydrocarbon compounds or derivatives thereof, carbazole derivatives, dibenzofuran derivatives, dibenzothiophene derivatives, organic aluminum complexes such as tris(8-quinolinolato)aluminum, and organic beryllium complexes.

Hereinafter, specific examples of compounds used as the host for the light emitting layer or as the emission-assist material contained in the light emitting layer will be described; however, the present disclosure is of course not limited thereto.

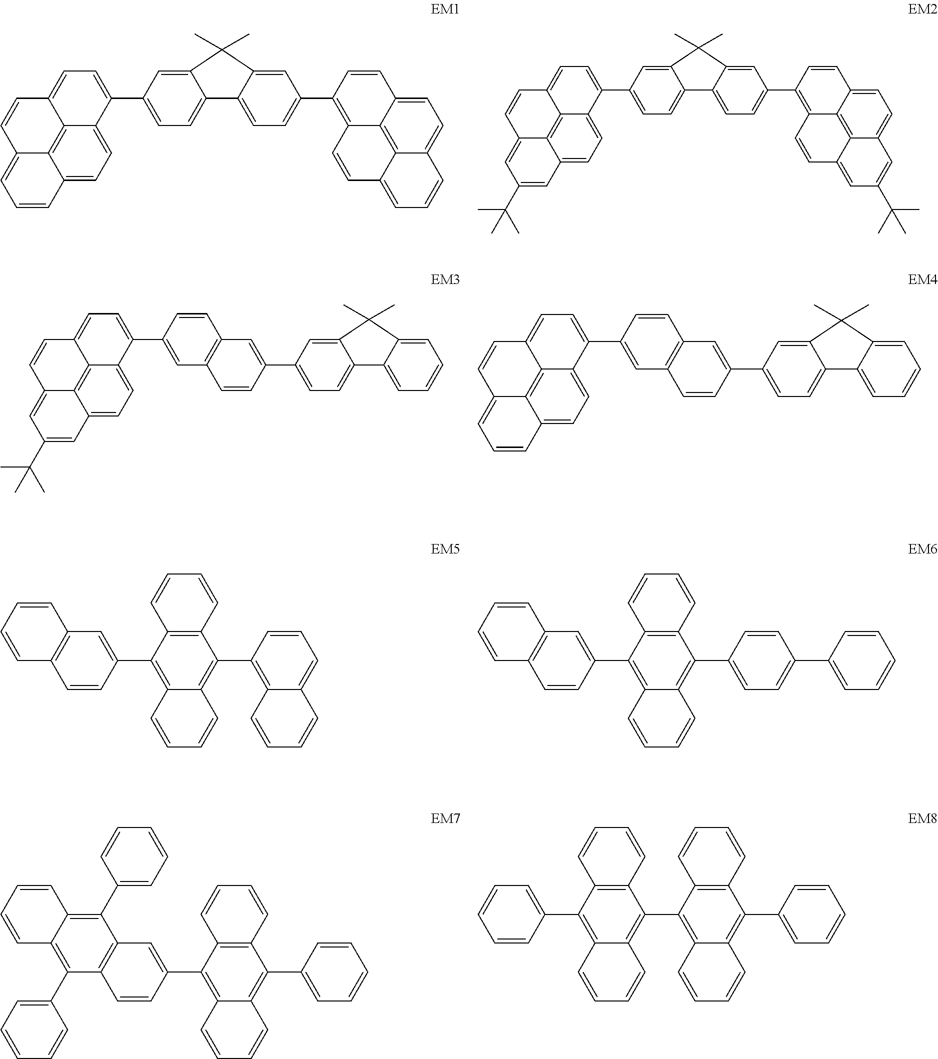

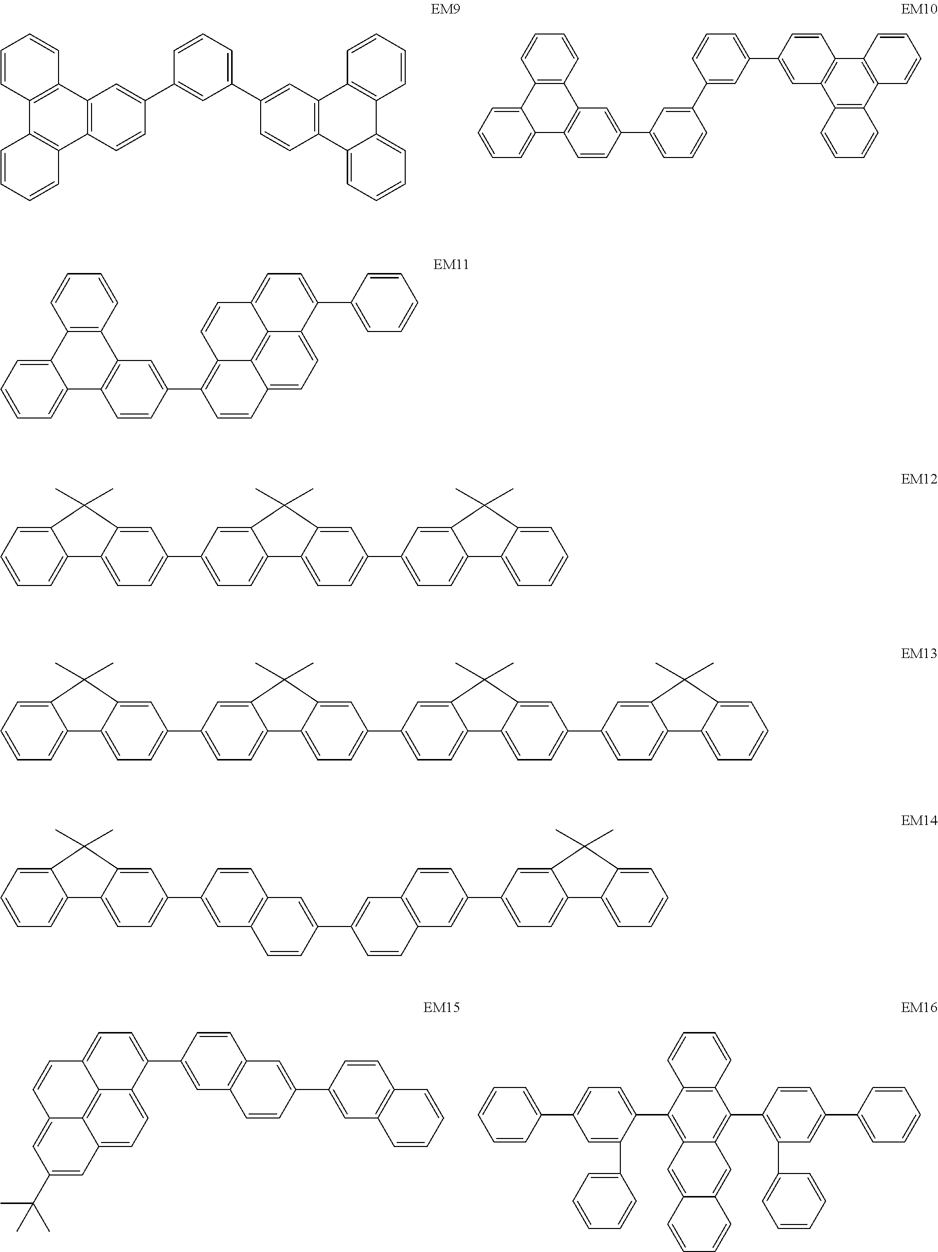

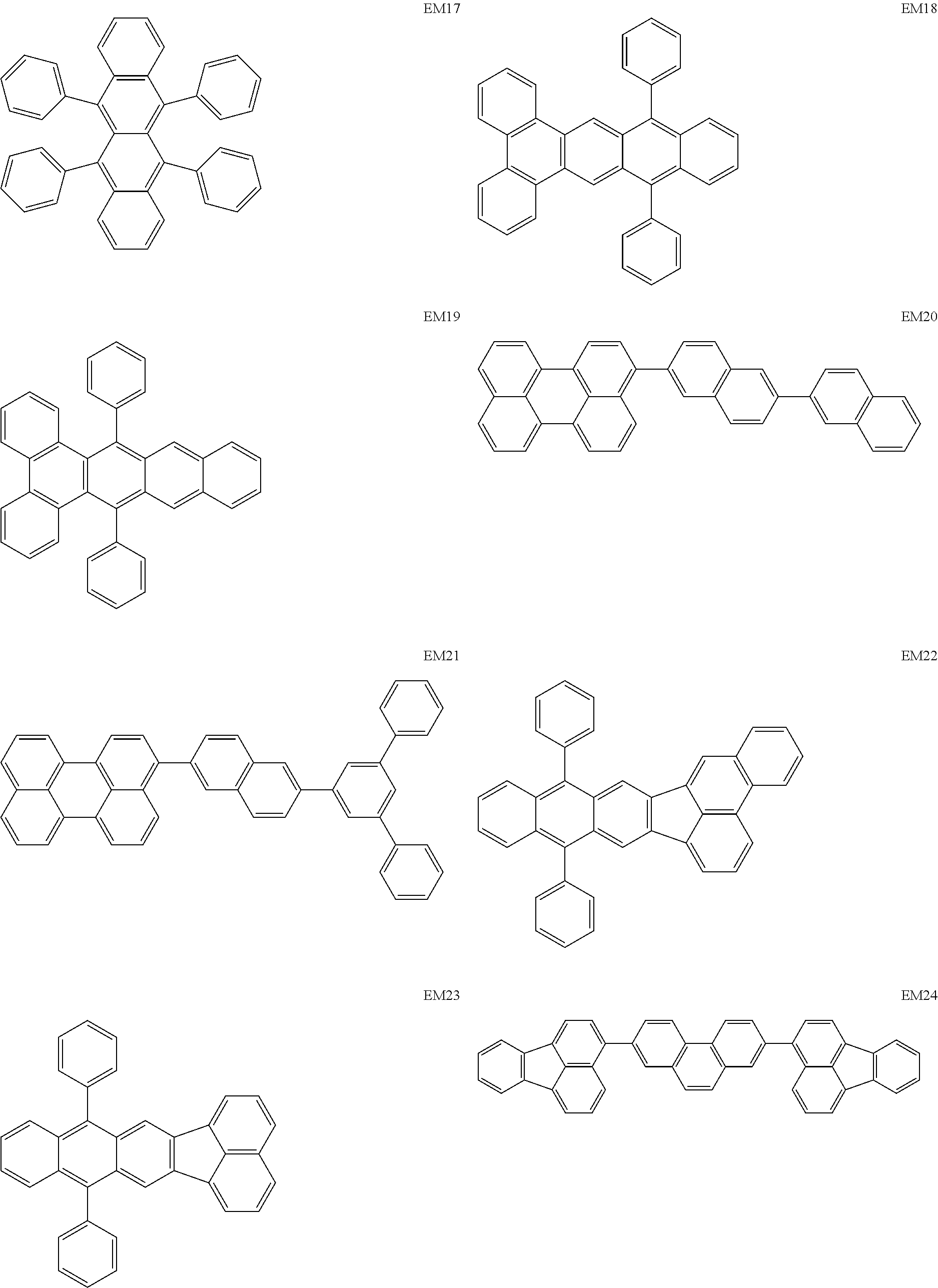

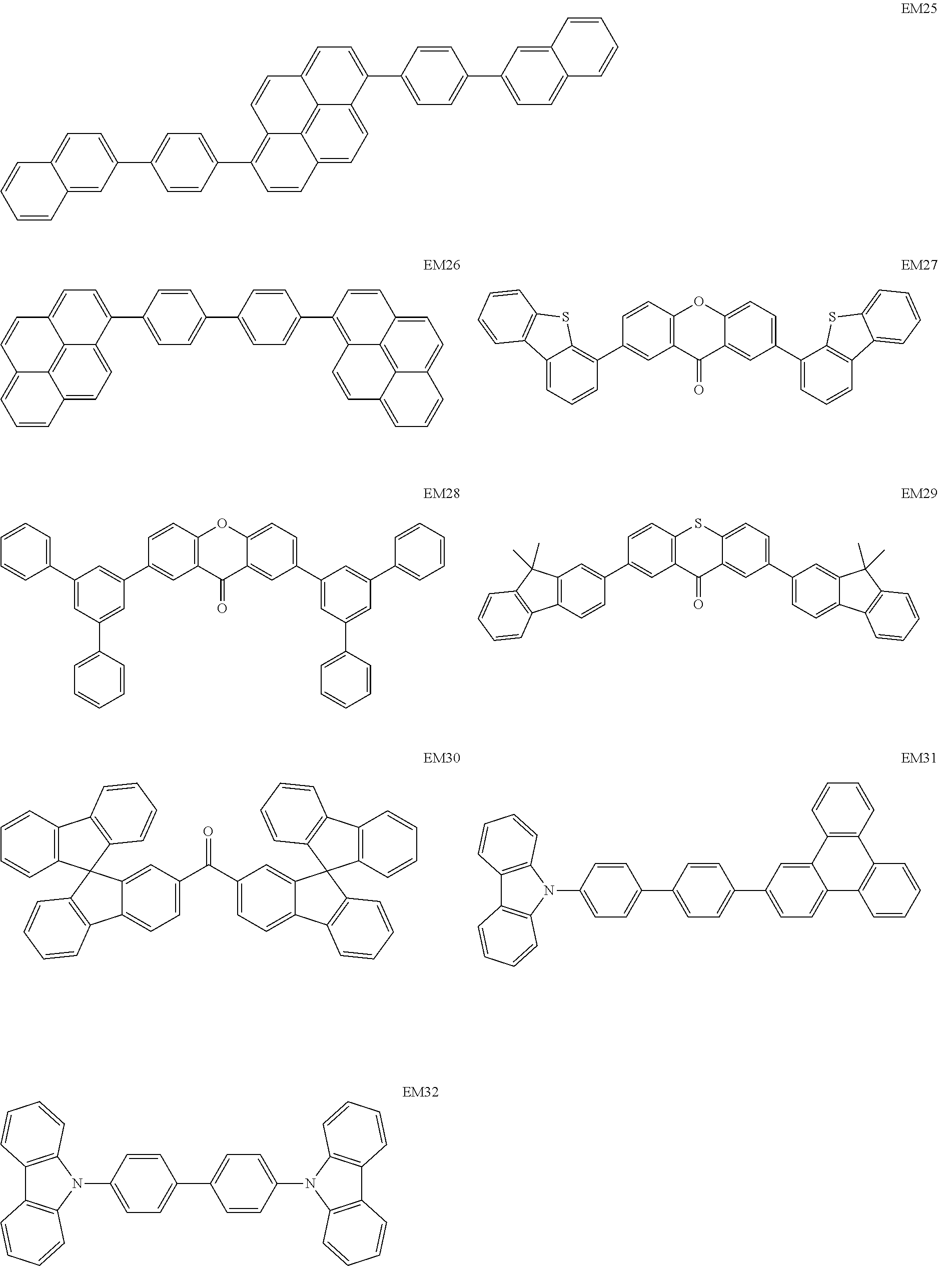

The host material preferably includes a freely rotatable single bond that is a carbon-carbon bond, which has a high bond energy. The host material is preferably a hydrocarbon compound because the compound of the present disclosure more easily traps electrons and holes, to thereby produce a marked improvement in efficiency. The hydrocarbon compound is a compound composed only of carbon and hydrogen; and the above-described exemplary compounds that are hydrocarbon compounds are EM1 to EM12 and EM16 to EM27.

The electron transport material can be appropriately selected from materials that transport electrons injected from the cathode to the light emitting layer and are selected in consideration of, for example, the balance with the hole mobility of the hole transport material. Examples of the material having electron transport ability include oxadiazole derivatives, oxazole derivatives, pyrazine derivatives, triazole derivatives, triazine derivatives, quinoline derivatives, quinoxaline derivatives, phenanthroline derivatives, organic aluminum complexes, and fused ring compounds (for example, fluorene derivatives, naphthalene derivatives, chrysene derivatives, and anthracene derivatives). Such electron transport materials are also suitably used for a hole blocking layer.

Hereinafter, specific examples of compounds used as the electron transport material will be described; however, the present disclosure is of course not limited thereto.

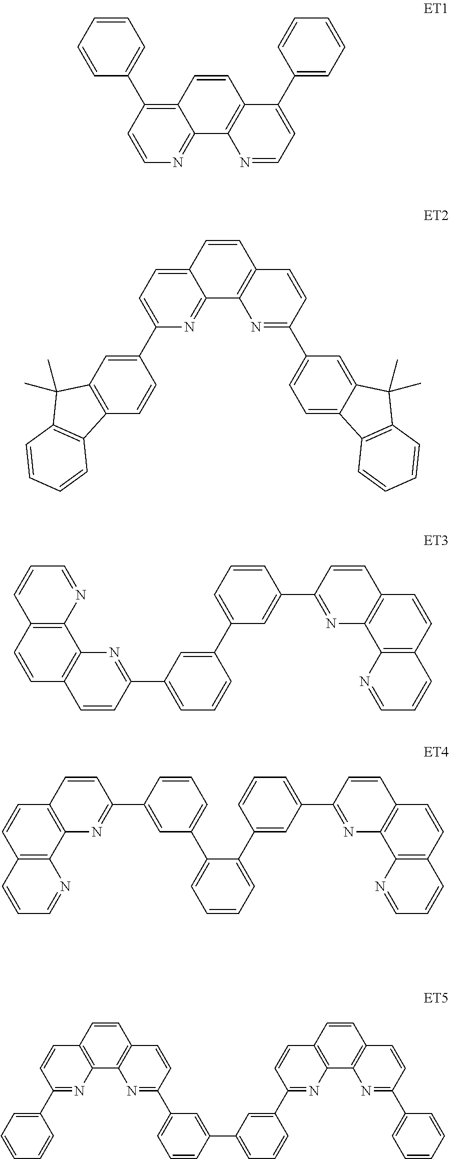

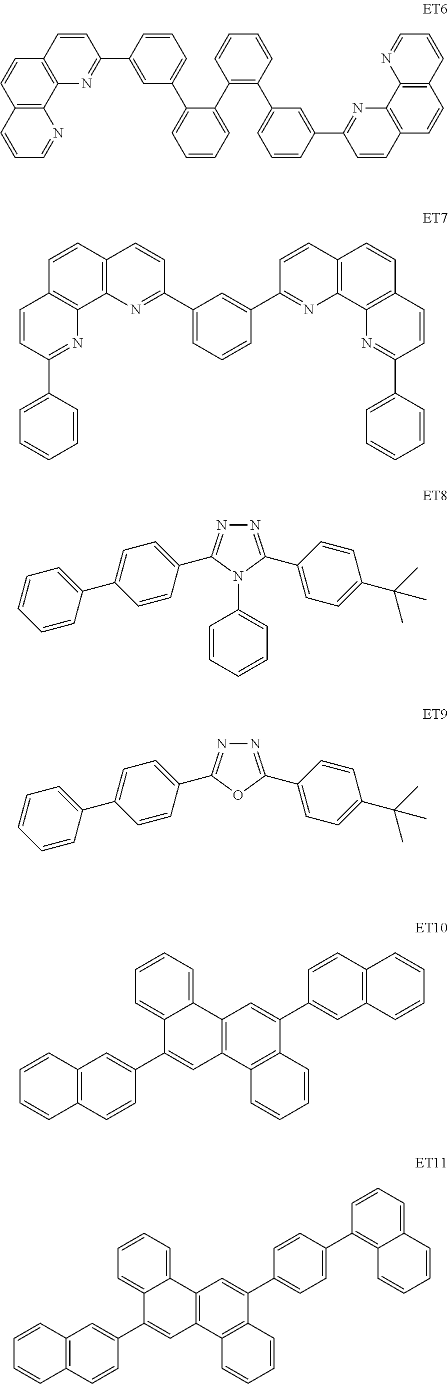

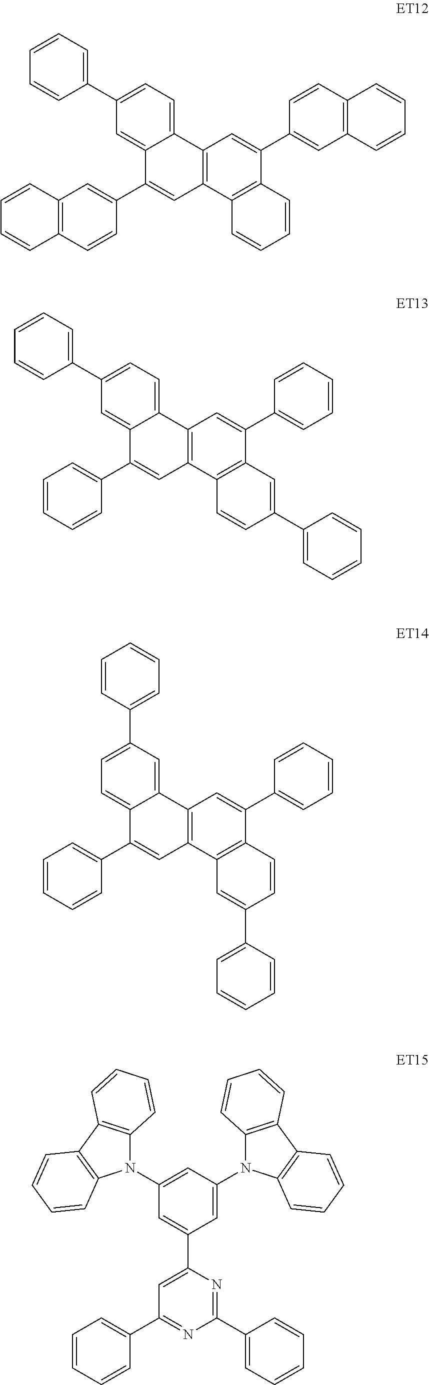

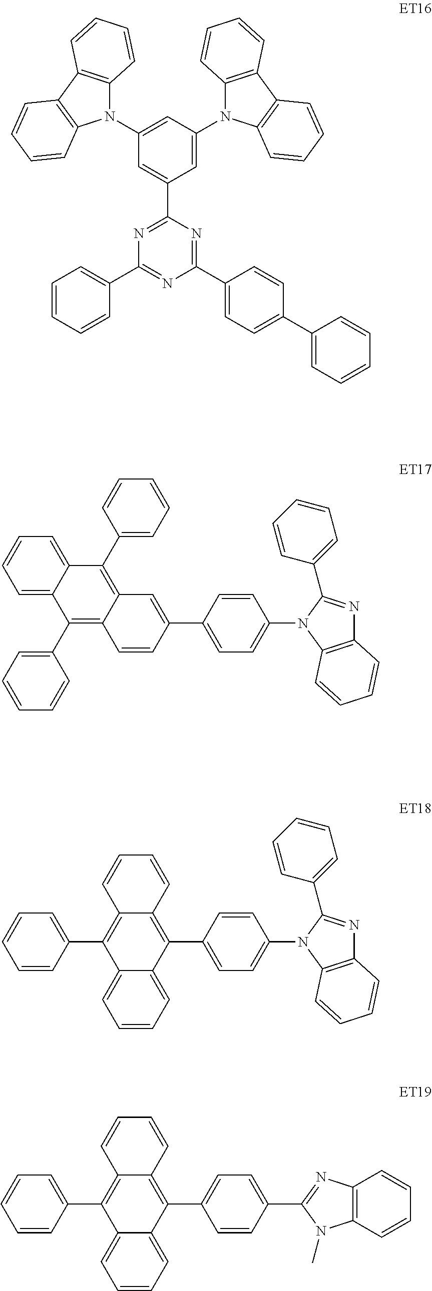 [SMILES: c1ccc(-c2ccc(-c3nc(-c4ccccc4)nc(-c4cc(-n5c6ccccc6c6ccccc65)cc(-n5c6ccccc6c6ccccc65)c4)n3)cc2)cc1 ; c1ccc(-c2c3ccccc3c(-c3ccccc3)c3cc(-c4ccc(-n5c(-c6ccccc6)nc6ccccc65)cc4)ccc23)cc1 ; c1ccc(-c2c3ccccc3c(-c3ccc(-n4c(-c5ccccc5)nc5ccccc54)cc3)c3ccccc23)cc1 ; Cn1c(-c2ccc(-c3c4ccccc4c(-c4ccccc4)c4ccccc34)cc2)nc2ccccc21]

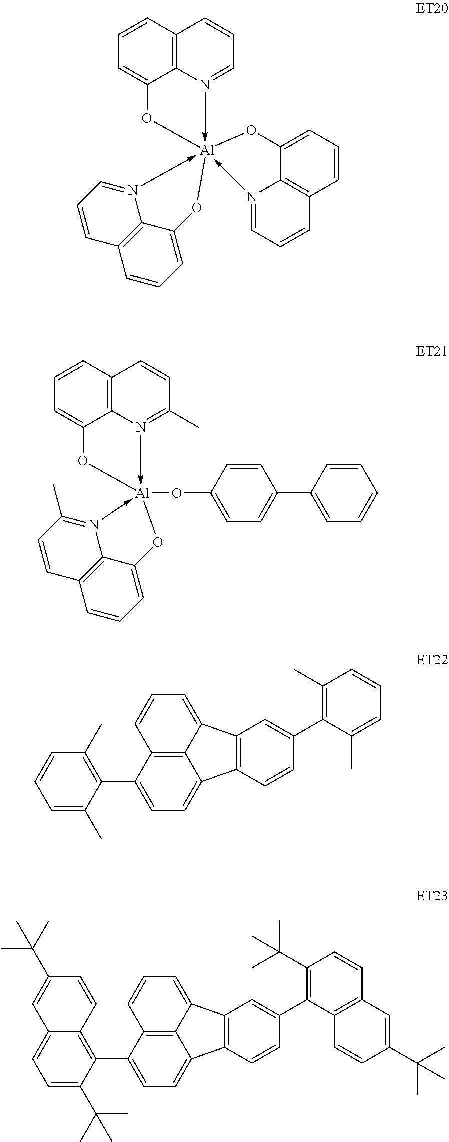

The electron injection material can be appropriately selected from materials that easily inject electrons from the cathode and is selected in consideration of, for example, the balance with the hole injection performance. Examples include organic compounds such as n-type dopants and reducing dopants. Examples include compounds containing alkali metals such as lithium fluoride, lithium complexes such as lithium quinolinolate, benzoimidazolidene derivatives, imidazolidene derivatives, fulvalene derivatives, and acridine derivatives.

The electron injection material can also be used in combination with the above-described electron transport material.

### (3) Configuration of Organic Light Emitting Element

Hereinafter, constituent members constituting the organic light emitting element according to the present embodiment will be described.

The organic light emitting element is provided by forming, on a substrate, an insulating layer, a first electrode, an organic compound layer, and a second electrode. On the second electrode, a protective layer, a color filter, a microlens, and the like may be disposed. When the color filter is disposed, a planarization layer may be disposed between the protective layer and the color filter. The planarization layer can be formed of an acrylic resin or the like. The same applies to the case where a planarization layer is disposed between the color filter and the microlens.

### Substrate

The substrate may be formed of quartz, glass, a silicon wafer, resin, or metal. On the substrate, a switching element such as a transistor and wiring may be disposed, and an insulating layer may be disposed thereon. The insulating layer may be formed of any material as long as it allows formation of a contact hole for wiring connection with the first electrode and ensures insulation from unconnected wiring. For example, a resin such as polyimide, silicon oxide, or silicon nitride can be used.

### Electrodes

As the electrodes, a pair of electrodes can be used. The pair of electrodes refers to a first electrode and a second electrode. Specifically, the pair of electrodes may be an anode and a cathode. When an electric field is applied in a direction in which the organic light emitting element emits light, the electrode having a higher potential is the anode and the other is the cathode. Stated another way, the electrode that supplies holes to the light emitting layer is the anode, and the electrode that supplies electrons to the light emitting layer is the cathode.

The anode is preferably formed of a material having a work function as large as possible. Examples include elemental metals such as gold, platinum, silver, copper, nickel, palladium, cobalt, selenium, vanadium, and tungsten; mixtures containing the foregoing; alloys that are combinations of the foregoing; and metal oxides such as tin oxide, zinc oxide, indium oxide, indium tin oxide (ITO), and indium zinc oxide. Conductive polymers such as polyaniline, polypyrrole, and polythiophene can also be used.

Such electrode substances may be used alone or in combination of two or more thereof. The anode may be formed as a single layer or as a plurality of layers.

A reflective electrode can be formed of, for example, chromium, aluminum, silver, titanium, tungsten, molybdenum, an alloy of the foregoing, or a laminated structure of the foregoing. Such materials can also function as reflective films that do not serve as electrodes. Alternatively, a transparent electrode can be formed as an oxide transparent conductive layer formed of indium tin oxide (ITO) or indium zinc oxide, but the transparent electrode is not limited thereto.

The electrode can be formed using photolithography techniques.

The cathode is preferably formed of a material having a small work function. Examples include alkali metals such as lithium, alkaline-earth metals such as calcium, elemental metals such as aluminum, titanium, manganese, silver, lead, and chromium, and mixtures containing the foregoing. Alloys that are combinations of these elemental metals can also be used. Examples include magnesium-silver, aluminum-lithium, aluminum-magnesium, silver-copper, and zinc-silver. A metal oxide such as indium tin oxide (ITO) can also be used. Such electrode substances may be used alone or in combination of two or more thereof. The cathode may be formed as a single layer or as a multilayer. In particular, silver is preferably used; more preferably, a silver alloy is used to reduce aggregation of silver. As long as aggregation of silver is reduced, the ratio of the alloy is not limited. For example, silver: other metal may be 1:1 or 3:1.

The cathode is not particularly limited and may be formed as an oxide conductive layer formed of ITO or the like to provide a top-emission element, or may be formed as a reflective electrode formed of aluminum (Al) or the like to provide a bottom-emission element. The method for forming the cathode is not particularly limited; however, for example, DC or AC sputtering is preferably used because such methods provide good film coverage and tend to provide lower resistance.

### Organic Compound Layer

The organic compound layer may be formed as a single layer or as a plurality of layers. When a plurality of layers are disposed, they may be referred to according to their functions as a hole injection layer, a hole transport layer, an electron blocking layer, a light emitting layer, a hole blocking layer, an electron transport layer, or an electron injection layer. The organic compound layer is mainly formed of an organic compound, but may contain inorganic atoms or an inorganic compound, such as copper, lithium, magnesium, aluminum, iridium, platinum, molybdenum, or zinc. The organic compound layer may be disposed between the first electrode and the second electrode and may be disposed in contact with the first electrode and the second electrode.

The organic compound layers (a hole injection layer, a hole transport layer, an electron blocking layer, a light emitting layer, a hole blocking layer, an electron transport layer, an electron injection layer, and the like) constituting the organic light emitting element according to the present embodiment are formed by the following methods.

The organic compound layers constituting the organic light emitting element according to the present embodiment can be formed using a dry process such as vacuum evaporation, ionized evaporation, sputtering, or plasma processing. Alternatively, instead of the dry process, a wet process may be used, wherein the materials are dissolved in appropriate solvents and a publicly known coating method (for example, spin coating, dipping, casting, LB method, or inkjet method) is performed to form the layers.

The layers are thus formed by vacuum evaporation, solution coating, or the like, so that crystallization and the like are less likely to occur, resulting in excellent temporal stability. When a coating method is employed for film formation, an appropriate binder resin may be additionally used to form the film.

Examples of the binder resin include polyvinylcarbazole resins, polycarbonate resins, polyester resins, ABS resins, acrylic resins, polyimide resins, phenol resins, epoxy resins, silicone resins, and urea resins, but are not limited thereto.

These binder resins may be used alone as a homopolymer or a copolymer, or as a mixture of two or more thereof. As necessary, publicly known additives such as plasticizers, antioxidants, and ultraviolet absorbers may be additionally used.

### Protective Layer

A protective layer may be disposed on the cathode. For example, a glass provided with a desiccant is bonded onto the cathode, to thereby reduce penetration of water or the like into the organic compound layer, resulting in reduction of the occurrence of display defects. In another embodiment, a passivation film formed of silicon nitride or the like may be disposed on the cathode to reduce penetration of water or the like into the organic compound layer. For example, after forming the cathode, the substrate may be transferred to another chamber without breaking the vacuum, and a silicon nitride film having a thickness of 2 μm may be formed by a CVD method to serve as the protective layer. After the film formation by the CVD method, a protective layer may also be formed by atomic layer deposition (ALD method). The material of the film formed by the ALD method is not limited, but may be silicon nitride, silicon oxide, or aluminum oxide. A silicon nitride film may be further formed by a CVD method on the film formed by the ALD method. The ALD film may have a smaller film thickness than the CVD film. Specifically, the film thickness of the ALD film may be 50% or less, or 10% or less of that of the CVD film.

### Color Filter

A color filter may be disposed on the protective layer. For example, a color filter corresponding to the size of the organic light emitting element may be formed on another substrate, which is then bonded to the substrate on which the organic light emitting element is formed; alternatively, the color filter may be formed by patterning on the above-described protective layer by photolithography techniques. The color filter may be formed of a polymer.

### Planarization Layer

A planarization layer may be disposed between the color filter and the protective layer. The planarization layer is disposed for the purpose of reducing irregularities of the underlying layer. The planarization layer may be referred to as a material resin layer without limitation on its purpose. The planarization layer may be formed of an organic compound, which may be either a low molecular compound or a polymer, and is preferably a polymer.

Such planarization layers may be disposed over and under the color filter and may be formed of the same material or different materials. Specific examples include polyvinylcarbazole resins, polycarbonate resins, polyester resins, ABS resins, acrylic resins, polyimide resins, phenol resins, epoxy resins, silicone resins, and urea resins.

### Microlens

The organic light emitting element according to the present embodiment may include an optical component such as a microlens on the light emission side. The microlens may be formed of an acrylic resin, an epoxy resin, or the like. The microlens may be disposed in order to increase the amount of light extracted from the organic light emitting element or to control the direction of the extracted light. The microlens may have a hemispherical shape. When the microlens has a hemispherical shape, among tangents contacting the hemisphere, a tangent is parallel to the insulating layer, and the point of contact of the tangent with the hemisphere is the vertex of the microlens. The vertex of the microlens can be similarly defined in any sectional view. Specifically, in a sectional view, among tangents contacting the semicircle of the microlens, a tangent is parallel to the insulating layer, and the point of contact of the tangent with the semicircle is the vertex of the microlens.

The midpoint of the microlens can also be defined. In a section of the microlens, a line segment is assumed between the point where one arc shape starts and the point where another arc shape starts, and the midpoint of this line segment can be referred to as the midpoint of the microlens. The section used to determine the vertex and the midpoint may be a section perpendicular to the insulating layer.

### Counter Substrate

A counter substrate may be disposed over the planarization layer. The counter substrate is disposed in a position corresponding to the above-described substrate and is therefore referred to as the counter substrate. The counter substrate may be formed of the same material as the above-described substrate. When the above-described substrate is referred to as the first substrate, the counter substrate may be referred to as the second substrate.

### Pixel Circuit

The light emitting device may include a pixel circuit connected to the light emitting element. The pixel circuit may be of an active matrix type that controls light emission of a first light emitting element and a second light emitting element independently. The active matrix circuit may be voltage-programmed or current-programmed. The driving circuit has a pixel circuit for each pixel. The pixel circuit may include a light emitting element, a transistor for controlling the light emission luminance of the light emitting element, a transistor for controlling the light emission timing, a capacitor for holding a gate voltage of the transistor controlling the light emission luminance, and a transistor for connecting to GND without passing through the light emitting element.

The light emitting device includes a display region and a peripheral region disposed around the display region. The display region has a pixel circuit, and the peripheral region has a display control circuit. The mobility of the transistors constituting the pixel circuit may be smaller than the mobility of the transistors constituting the display control circuit.

The slope of the current-voltage characteristic of the transistors constituting the pixel circuit may be smaller than the slope of the current-voltage characteristic of the transistors constituting the display control circuit. The slope of the current-voltage characteristic can be measured from, what is called, the Vg-Ig characteristic.

The transistors constituting the pixel circuit are transistors connected to the light emitting elements such as the first light emitting element.

### Pixels

The organic light emitting device includes a plurality of pixels. Each pixel includes subpixels that emit light of different colors from one another. The subpixels may each have an emission color of R, G, or B, for example.

The pixel has a region also called a pixel aperture where light emission occurs. This region is the same as the first region.

The pixel aperture may have a size of 15 μm or less or may have a size of 5 μm or more. More specifically, the size may be 11 μm, 9.5 μm, 7.4 μm, or 6.4 μm, for example.

The distance between subpixels may be 10 μm or less, and specifically may be 8 μm, 7.4 μm, or 6.4 μm.

The pixels may be arranged in a publicly known form in a plan view. For example, the pixels may be arranged in a stripe pattern, a delta pattern, a PenTile pattern, or a Bayer pattern. The subpixels may have any publicly known shape in a plan view. For example, the shape may be a quadrilateral such as a rectangle or a rhombus, a hexagon, or the like. The term “rectangle” obviously encompasses shapes that are not exact rectangles but are similar to rectangles. Such a shape of subpixels and such an arrangement of pixels may be used in combination.

### (4) Applications of Organic Light Emitting Element According to Present Embodiment

The organic light emitting element according to the present embodiment can be used as a component of an image display apparatus, a display apparatus, a lighting apparatus, or the like. Other applications include a display unit of an image display apparatus including the display unit and a housing in which the display unit is disposed, an exposure light source of an electrophotographic image forming apparatus, a backlight of a liquid crystal display apparatus, and a light emitting device including a color filter for a white light source.

The display apparatus may be an image information processing apparatus that includes an image input unit for inputting image information from an area CCD, a linear CCD, a memory card, or the like, includes an information processing unit for processing the input information, and displays an input image on a display unit.

A display unit of an image pickup apparatus or an inkjet printer may have a touch panel function. The drive method of the touch panel function is not particularly limited and may be an infrared method, a capacitive method, a resistive film method, or an electromagnetic induction method. The display apparatus may be used for the display unit of a multifunction printer.

Hereinafter, a display apparatus according to the present embodiment will be described with reference to drawings.

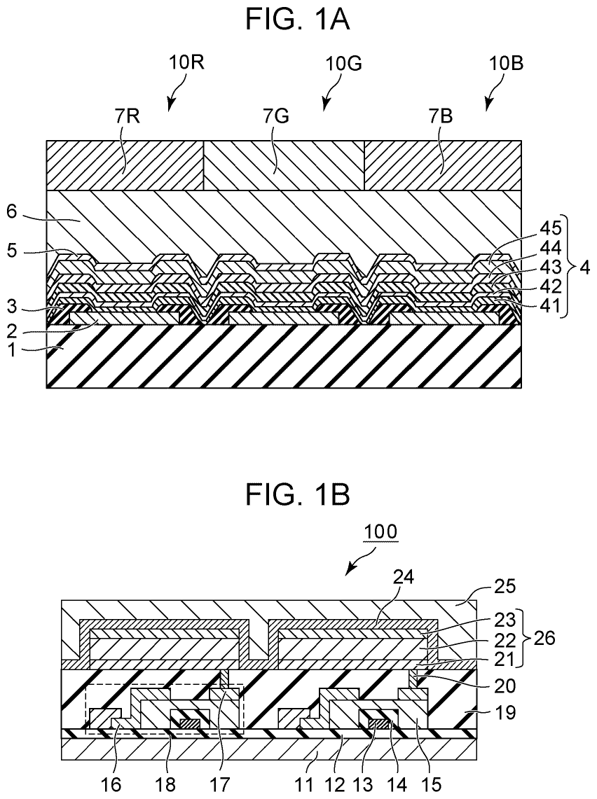

FIGS. 1A and 1B are schematic sectional views illustrating examples of a display apparatus including an organic light emitting element and a transistor connected to the organic light emitting element. The transistor is an example of an active element. The transistor may be a thin film transistor (TFT).

FIG. 1A illustrates an example of a pixel, which is a constituent element of the display apparatus according to the present embodiment. The pixel includes a subpixel 10. The subpixel is divided into 10R, 10G, and 10B on the basis of light emission. The emission colors may be distinguished on the basis of wavelengths of light emitted from the light emitting layer; alternatively, light emitted from such a subpixel may be subjected to selective transmission or color conversion using a color filter or the like. Each subpixel includes a reflective electrode 2 serving as a first electrode on an interlayer insulating layer 1, an insulating layer 3 covering the periphery of the reflective electrode 2, an organic compound layer 4 covering the first electrode and the insulating layer, a transparent electrode 5, a protective layer 6, and a color filter 7.

The interlayer insulating layer 1 may be provided with a transistor and a capacitor element disposed in an underlying layer thereof or inside thereof.

The transistor and the first electrode may be electrically connected via a contact hole or the like (not shown).

The insulating layer 3 is also called a bank or a pixel isolation film. The insulating layer 3 covers the periphery of the first electrode and is disposed so as to surround the first electrode. A portion where the insulating layer is not disposed is in contact with the organic compound layer 4 and serves as a light emission region.

The organic compound layer 4 has a hole injection layer 41, a hole transport layer 42, a first light emitting layer 43, a second light emitting layer 44, and an electron transport layer 45.

The second electrode 5 may be a transparent electrode, a reflective electrode, or a semi-transmissive electrode.

The protective layer 6 reduces permeation of moisture into the organic compound layer. The protective layer is illustrated as a single layer; however, the protective layer may include a plurality of layers. Each layer may include an inorganic compound layer and an organic compound layer.

The color filter 7 is divided into 7R, 7G, and 7B on the basis of color. The color filter may be formed on a planarization film (not shown). A resin protective layer (not shown) may be disposed on the color filter. The color filter may be formed on the protective layer 6. Alternatively, the color filter may be disposed on a counter substrate such as a glass substrate, and then bonded to the other substrate.

FIG. 1B illustrates a display apparatus 100 including an organic light emitting element 26 and a TFT 18 serving as an example of a transistor. A substrate 11 is formed of glass, silicon, or the like and an insulating layer 12 is disposed thereon. On the insulating layer, an active element 18 such as the TFT is disposed and a gate electrode 13, a gate insulating film 14, and a semiconductor layer 15 of the active element are disposed. The active element 18 further includes the semiconductor layer 15, a drain electrode 16, and a source electrode 17. On the active element 18, an insulating film 19 is disposed. An anode 21 that constitutes the organic light emitting element 26 is connected to the source electrode 17 via a contact hole 20 formed in the insulating film.

Note that the electrical connection scheme of electrodes (the anode and the cathode) included in the organic light emitting element 26 and electrodes (the source electrode and the drain electrode) included in the TFT is not limited to the example illustrated in FIG. 1B. In other words, it is sufficient that either one of the anode and the cathode is electrically connected to either one of the TFT source electrode and the TFT drain electrode. The TFT refers to a thin film transistor.

FIG. 1B illustrates the display apparatus 100 in which the organic compound layer is a single layer; however, an organic compound layer 22 may include a plurality of layers. On a cathode 23, a first protective layer 24 and a second protective layer 25 for reducing deterioration of the organic light emitting element are disposed.

FIG. 1B illustrates the display apparatus 100 using a transistor as a switching element; instead of this, another switching element may be used.

The transistor used in the display apparatus 100 of FIG. 1B is not limited to a transistor using a single-crystal silicon wafer, and may be a thin film transistor having an active layer on an insulating surface of a substrate. The active layer may be formed of single-crystal silicon, non-single-crystal silicon such as amorphous silicon or microcrystalline silicon, or a non-single-crystal oxide semiconductor such as indium zinc oxide or indium gallium zinc oxide. The thin film transistor is also called a TFT element.

A transistor included in the display apparatus 100 of FIG. 1B may be formed in a substrate such as a Si substrate. This phrase “formed in a substrate” means that the transistor is manufactured by processing the substrate itself, such as the Si substrate. Such a structure in which the transistor is disposed in the substrate can also be regarded as a structure in which the substrate and the transistor are formed as a single unit.

In the organic light emitting element according to the present embodiment, light emission luminance is controlled by a TFT serving as an example of a switching element; and a plurality of such organic light emitting elements are disposed in a surface and their light emission luminances are used to display an image. Note that the switching element according to the present embodiment is not limited to the TFT, and may be a transistor formed of low-temperature polysilicon or an active matrix driver formed on a substrate such as a Si substrate. The phrase “on a substrate” encompasses “in the substrate”. Whether a transistor is disposed in a substrate or a TFT is used is selected according to the size of a display unit; and for example, when the size is about 0.5 inch, the organic light emitting element is preferably disposed on a Si substrate.

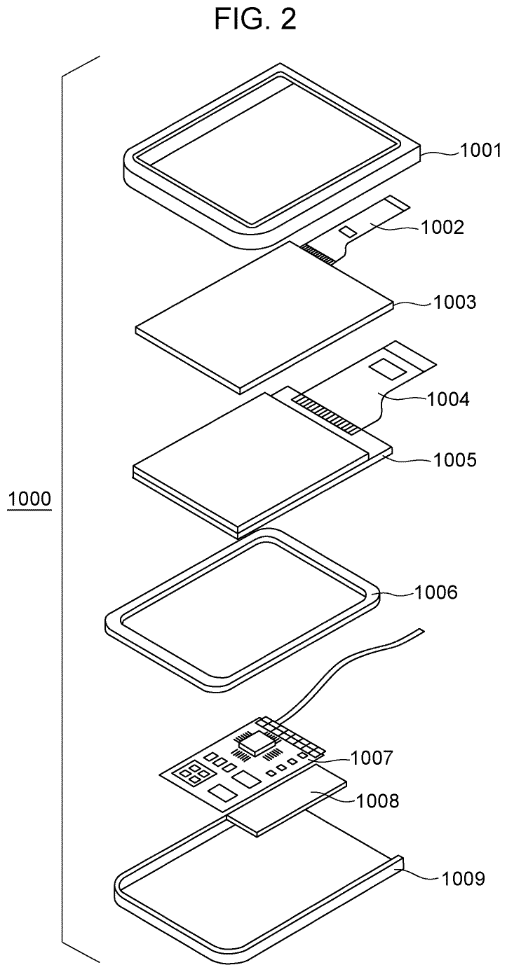

FIG. 2 is a schematic view illustrating an example of a display apparatus according to the present embodiment. A display apparatus 1000 may include a touch panel 1003, a display panel 1005, a frame 1006, a circuit substrate 1007, and a battery 1008 that are disposed between an upper cover 1001 and a lower cover 1009. The display panel 1005 may include the organic light emitting element according to the present embodiment. The touch panel 1003 and the display panel 1005 respectively have flexible printed circuits FPCs 1002 and 1004 connected thereto. A transistor is printed on the circuit substrate 1007. When the display apparatus is not a portable device, the battery 1008 is not necessarily disposed; and even when the display apparatus is a portable device, the battery 1008 may be disposed at another position.

The display apparatus according to the present embodiment may include color filters having red, green, and blue. The color filters having red, green, and blue may be arranged in a delta array.

The display apparatus according to the present embodiment may be used for a display unit of a portable terminal. In this case, the display apparatus may have both a display function and an operation function. Examples of the portable terminal include cellular phones such as smartphones, tablets, and head-mounted displays.

The display apparatus according to the present embodiment may be used for a display unit of an image pickup apparatus including an image pickup element that receives light. The image pickup apparatus may include a display unit that displays information acquired by the image pickup element. The display unit may be a display unit exposed to the outside of the image pickup apparatus or may be a display unit disposed in a finder. The image pickup apparatus may be a digital camera or a digital video camera.

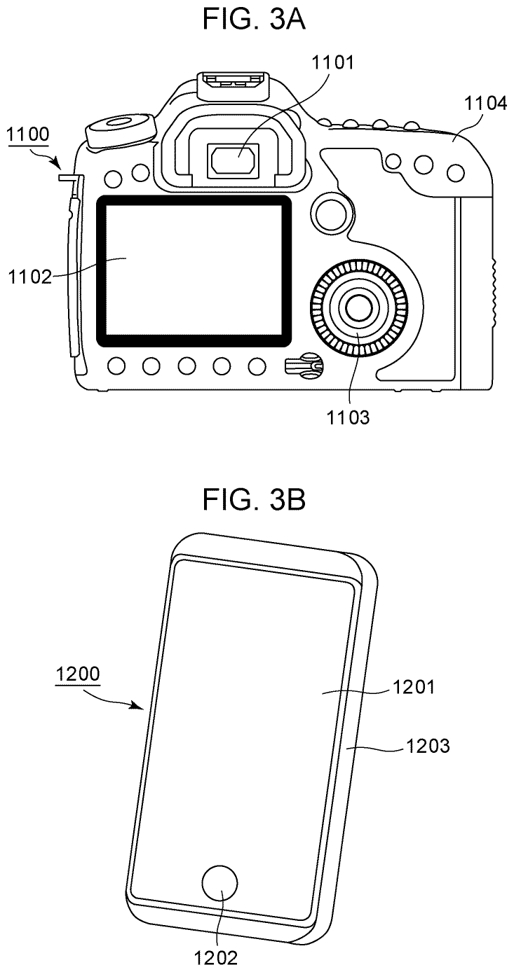

FIG. 3A is a schematic view illustrating an example of an image pickup apparatus according to the present embodiment. An image pickup apparatus 1100 may include a viewfinder 1101, a rear display 1102, an operation unit 1103, and a housing 1104. The viewfinder 1101 and the rear display 1102 may include the organic light emitting element according to the present embodiment. In this case, the viewfinder 1101 and the rear display 1102 may display not only an image to be captured but also environmental information, an image pickup instruction, and the like.

The environmental information may be the intensity of external light, the direction of external light, the moving speed of the subject, a possibility that the subject is shielded by a shielding object, and the like.

The timing suitable for image pickup is a short time, and hence information is preferably displayed as early as possible. Therefore, the display apparatus using the organic light emitting element according to the present embodiment is preferably used.

This is because the organic light emitting element has a fast response speed.

The image pickup apparatus 1100 may further include an optical unit (not shown). The optical unit may include a single lens or a plurality of lenses; such a lens forms an image on an image pickup element housed in the housing 1104. The relative positions of the plurality of lenses can be adjusted to thereby adjust the focus. This operation can be performed automatically. The image pickup apparatus may also be called a photoelectric conversion apparatus. The photoelectric conversion apparatus can include, as image pickup methods that do not sequentially capture images, a method of detecting a difference from a previous image, a method of cutting out from an image that is always recorded, and the like.

FIG. 3B is a schematic view illustrating an example of an electronic apparatus according to the present embodiment. An electronic apparatus 1200 includes a display unit 1201, an operation unit 1202, and a housing 1203. The housing 1203 may include a circuit, a printed substrate including the circuit, a battery, and a communication unit. The operation unit 1202 may include a button or may include a touch-panel-based input unit. The operation unit may include a biometric recognition unit that recognizes a fingerprint and performs unlocking and the like. An electronic apparatus including a communication unit can also be called a communication apparatus. The electronic apparatus may include a lens and an image pickup element to thereby further have a camera function. An image captured by the camera function is displayed on the display unit. Examples of the electronic apparatus include smartphones and notebook computers.

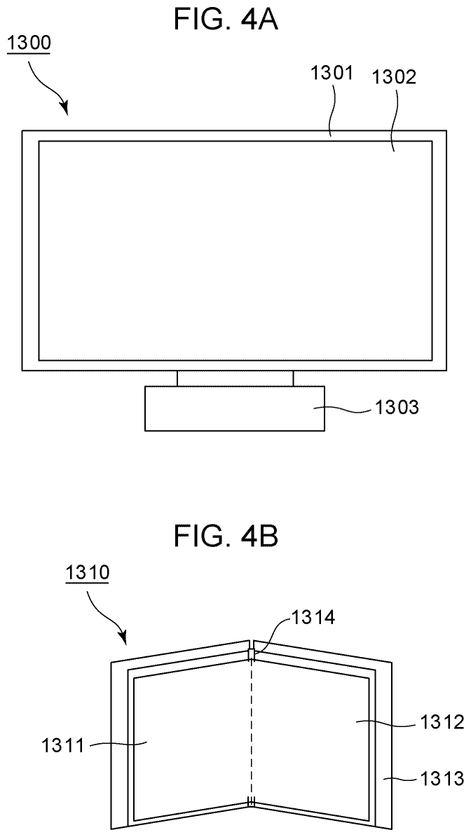

FIGS. 4A and 4B are schematic views illustrating examples of a display apparatus according to the present embodiment. FIG. 4A illustrates a display apparatus such as a television monitor or a PC monitor. A display apparatus 1300 includes a housing 1301 and a display unit 1302. The display unit 1302 may use the organic light emitting element according to the present embodiment.

The display apparatus 1300 may include the housing 1301 and a base 1303 that supports the display unit 1302. The base 1303 is not limited to the form in FIG. 4A. The lower side of the housing 1301 may also serve as the base.

The housing 1301 and the display unit 1302 may be curved and may have a curvature radius of 5000 mm or more and 6000 mm or less.

FIG. 4B is a schematic view illustrating another example of the display apparatus according to the present embodiment. In FIG. 4B, a display apparatus 1310 can be folded and is, what is called, a foldable display apparatus. The display apparatus 1310 includes a first display unit 1311, a second display unit 1312, a housing 1313, and a flexure point 1314. The first display unit 1311 and the second display unit 1312 may include the organic light emitting element according to the present embodiment. The first display unit 1311 and the second display unit 1312 may constitute a single seamless display apparatus. The first display unit 1311 and the second display unit 1312 can be divided at the flexure point. The first display unit 1311 and the second display unit 1312 may individually display different images, or the first and second display units may together display a single image.

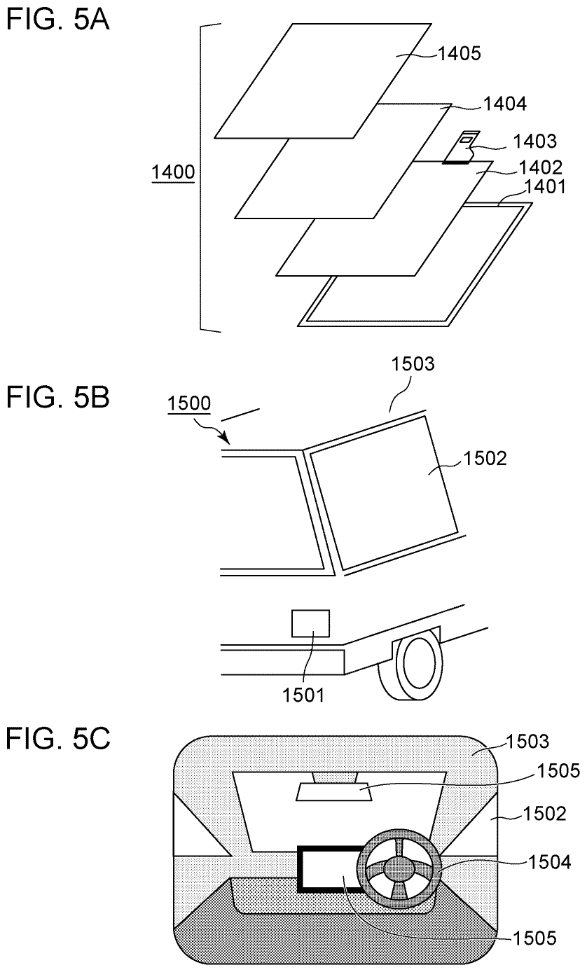

FIG. 5A is a schematic view illustrating an example of a lighting apparatus according to the present embodiment. A lighting apparatus 1400 may include a housing 1401, a light source 1402, and a circuit substrate 1403. The light source 1402 may include the organic light emitting element according to the present embodiment. The lighting apparatus 1400 may include an optical film 1404 to improve color rendering of the light source. The lighting apparatus 1400 may also include a light diffusion unit 1405 to effectively diffuse light of the light source. The lighting apparatus 1400 including the light diffusion unit 1405 can deliver light to a wide range. The optical film 1404 and the light diffusion unit 1405 may be disposed on the light emission side of the lighting apparatus. A cover may be disposed on the outermost side as necessary.

The lighting apparatus is an apparatus that illuminates a room, for example. The lighting apparatus may emit light having any one of white, neutral white, and other colors from blue to red. The lighting apparatus according to the present embodiment may include a dimming circuit that adjusts the emission. The lighting apparatus according to the present embodiment may include a power supply circuit connected to the organic light emitting element according to the present embodiment. The power supply circuit may be a circuit that converts an AC voltage into a DC voltage. The term “white” corresponds to a color temperature of 4200 K, and the term “neutral white” corresponds to a color temperature of 5000 K. The lighting apparatus according to the present embodiment may further include a color filter.

The lighting apparatus according to the present embodiment may include a heat dissipation unit. The heat dissipation unit discharges heat in the apparatus to outside the apparatus, and may be formed of, for example, a metal or ceramic having a large thermal conductivity.

FIG. 5B is a schematic view of an automobile serving as an example of a mobile object according to the present embodiment. The automobile includes a tail lamp serving as an example of a lighting device. An automobile 1500 includes a tail lamp 1501 and a vehicle body 1503, and may be configured such that the tail lamp lights when a brake operation or the like is performed. The vehicle body 1503 can also be referred to as a body. The automobile 1500 may include a window 1502 attached to the vehicle body 1503.

The tail lamp 1501 may include the organic light emitting element according to the present embodiment. The tail lamp may include a protective member that protects the light source. The protective member may be formed of any material as long as it has a certain high strength and is transparent, but is preferably formed of polycarbonate or the like. The polycarbonate may be mixed with a furandicarboxylic acid derivative, an acrylonitrile derivative, or the like.

When the window 1502 is not a window for checking the front and rear of the automobile, it may be a transparent display. The transparent display may include the organic light emitting element according to the present embodiment.

In this case, constituent materials such as electrodes included in the organic light emitting element according to the present disclosure are composed of transparent members.

As illustrated in FIG. 5C, the automobile 1500 includes a handle 1504 for controlling the traveling direction of the mobile object, and a display unit 1505 that displays, for example, a map, the position of the mobile object, and a turning direction, and is mounted on the vehicle body 1503. The display unit 1505 may include the organic light emitting element according to the present embodiment.

The mobile object according to the present embodiment includes one or both of a driving force generation unit that mainly generates a driving force used for movement of the mobile object, and a rotating body mainly used for the movement of the mobile object. The driving force generation unit may be an engine or a motor, for example. The rotating body may be a tire, a wheel, or a ship screw, for example. The mobile object may specifically be a bicycle, an automobile, a train, a ship, an aircraft, or a drone, for example. The mobile object may include a body and a lighting device disposed in the body or a display unit disposed in the body. The lighting device may emit light to make the position of the body recognizable.

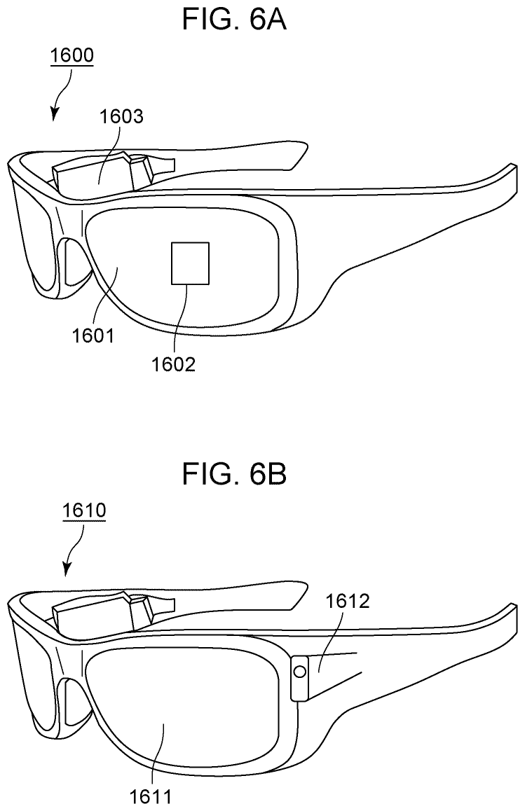

Referring to FIGS. 6A and 6B, examples of applications of the above-described display apparatuses of the embodiments will be described. The display apparatuses can be applied to systems wearable as wearable devices, such as smart glasses, head-mounted displays, and smart contact lenses. The display apparatuses usable for wearable devices may include an image pickup device that performs photoelectric conversion of visible light and a display apparatus that emits visible light.

FIGS. 6A and 6B are schematic views illustrating examples of eyeglasses (smart glasses) according to the present embodiment. Eyeglasses 1600 (smart glasses) will be described with reference to FIG. 6A. The eyeglasses 1600 include a display unit on the rear surface side of a lens 1601. The display unit may include the organic light emitting element according to the present disclosure. Furthermore, an image pickup device 1602 such as a CMOS sensor or a SPAD may be disposed on the front surface side of the lens 1601.

The eyeglasses 1600 further include a controller 1603. The controller 1603 functions as a power source for supplying power to the image pickup device 1602 and the display unit. The controller 1603 also controls the operations of the image pickup device 1602 and the display unit. An optical system for collecting light from the image pickup device 1602 and the display unit is formed in the lens 1601.

Referring to FIG. 6B, eyeglasses 1610 (smart glasses) will be described. The eyeglasses 1610 include a controller 1612, and the controller 1612 includes a display apparatus including the organic light emitting element according to the present disclosure. The controller 1612 may further include an image pickup device corresponding to the image pickup device 1602. An optical system for projecting light emitted from the controller 1612 is formed in a lens 1611, and an image is projected onto the lens 1611. The controller 1612 functions as a power source for supplying power to the image pickup device and the display apparatus, and also controls operations of the image pickup device and the display apparatus. The controller may include a gaze detection unit for detecting gaze of the wearer. The gaze detection may be performed using infrared light. The infrared light emitting unit emits infrared light toward the eyeball of a user who is gazing at a displayed image. Among the emitted infrared light, the image pickup unit including a light receiving element detects reflected light from the eyeball to obtain an image of the eyeball. A reduction unit that reduces light from the infrared light emitting unit to the display unit in plan view reduces degradation of image quality.

The controller 1612 detects the user's gaze toward the displayed image from the captured image of the eyeball obtained by infrared image pickup. For the gaze detection using the captured image of the eyeball, any publicly known method can be applied. An example can be a gaze detection method based on a Purkinje image generated by reflection of irradiation light on the cornea.

More specifically, gaze detection processing based on a pupil-corneal reflection method is performed. The pupil-corneal reflection method is used to generate a gaze vector representing the orientation (rotation angle) of the eyeball based on an image of the pupil and a Purkinje image included in the captured image of the eyeball, to thereby detect the user's gaze.

The display apparatus according to the present embodiment may include an image pickup device including a light receiving element and may control a displayed image of the display apparatus based on the user's gaze information from the image pickup device.

Specifically, the display apparatus determines, based on gaze information, a first field-of-view region gazed at by the user and a second field-of-view region other than the first field-of-view region. The first field-of-view region and the second field-of-view region may be determined by the controller of the display apparatus, or the display apparatus may receive the regions determined by an external controller. In a display region of the display apparatus, the display resolution of the first field-of-view region may be controlled to be higher than that of the second field-of-view region. In other words, the resolution of the second field-of-view region may be made lower than that of the first field-of-view region.

The display region includes a first field-of-view region and a second field-of-view region different from the first field-of-view region, and a region having a higher priority is determined, based on the gaze information, from among the first field-of-view region and the second field-of-view region. The first field-of-view region and the second field-of-view region may be determined by the controller of the display apparatus, or the display apparatus may receive the regions determined by an external controller. The resolution of the higher-priority region may be controlled to be higher than that of the non-higher-priority region. In other words, the resolution of the region having a relatively lower priority may be reduced.

Note that AI may be used for determining the first field-of-view region or the high-priority field-of-view region. The AI may be a model configured to estimate a gaze angle and the distance to the gaze target from an image of the eyeball, using, as training data, the image of the eyeball and the actual gaze direction of the eyeball in the image. The AI may be included in the display apparatus, the image pickup device, or an external device. When the external device includes the AI, the display apparatus can be preferably applied to smart glasses further including an image pickup device for image pickup of the outside. The smart glasses can display captured outside information in real time.

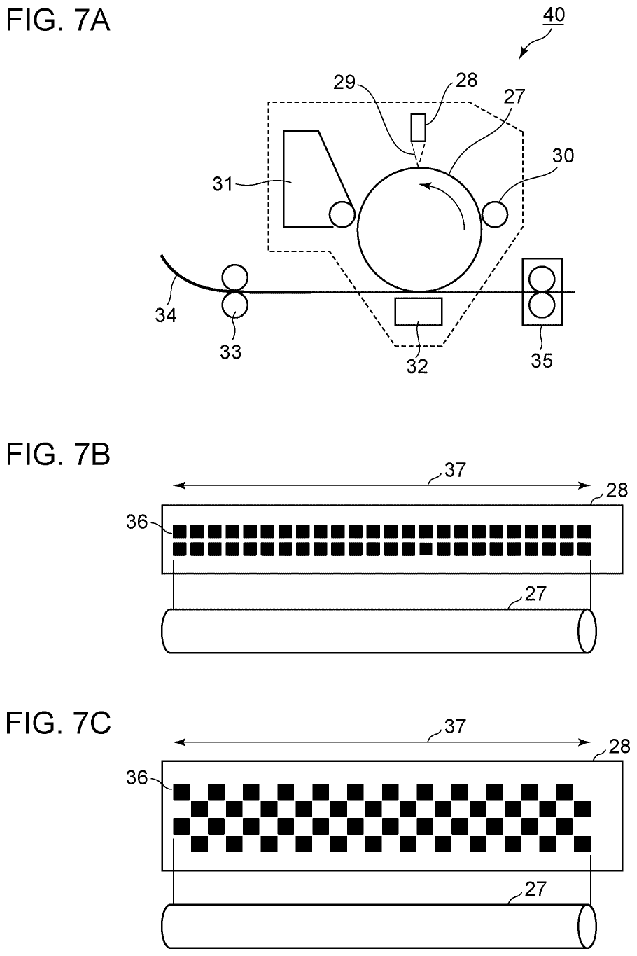

FIG. 7A is a schematic view illustrating an example of an image forming apparatus according to the present embodiment. An image forming apparatus 40 is an electrophotographic image forming apparatus including a photoconductor 27, an exposure light source 28, a charging unit 30, a developing unit 31, a transfer unit 32, a conveying roller 33, and a fixing unit 35. The exposure light source 28 emits light 29 to form an electrostatic latent image on the surface of the photoconductor 27. The exposure light source 28 may include the organic light emitting element according to the present embodiment. The developing unit 31 includes toner or the like. The charging unit 30 charges the photoconductor 27. The transfer unit 32 transfers the developed image onto a recording medium 34. The conveying roller 33 conveys the recording medium 34. The recording medium 34 may be paper, for example. The fixing unit 35 fixes the image formed on the recording medium 34.

FIG. 7B and FIG. 7C are schematic views illustrating the exposure light source 28, and illustrating configurations in which a plurality of light emitting portions 36 are arranged on an elongated substrate. Arrows 37 indicate a row direction in which the organic light emitting elements are arranged. This row direction is the same as the direction of the axis of rotation of the photoconductor 27. This direction can also be referred to as the longitudinal direction of the photoconductor 27. FIG. 7B illustrates a configuration in which the light emitting portions 36 are arranged in the longitudinal direction of the photoconductor 27. FIG. 7C illustrates a configuration different from that of FIG. 7B, in which the light emitting portions 36 are alternately arranged in the row direction in each of a first row and a second row. The first row and the second row are disposed at different positions in the column direction. In the first row, a plurality of light emitting portions 36 are arranged at intervals. The second row includes light emitting portions 36 at positions corresponding to the intervals between the light emitting portions 36 in the first row. Thus, a plurality of light emitting portions 36 are arranged at intervals also in the column direction. The arrangement in FIG. 7C can also be referred to as a grid arrangement, a staggered arrangement, or a checkerboard pattern.

As has been described so far, use of apparatuses including the organic light emitting element according to the present embodiment can provide stable displaying with excellent image quality even during long-time displaying.

### EXAMPLES

Hereinafter, the present disclosure will be described with reference to Examples; however, the present disclosure is not limited thereto.

### Examples 1 to 3 and Comparative Examples 1 to 2

In EXAMPLES, blue bottom-emission-type organic light emitting elements were produced, in which an anode, a hole injection layer, a hole transport layer, an electron blocking layer, a light emitting layer, a hole blocking layer, an electron transport layer, an electron injection layer, and a cathode were sequentially formed on a substrate.

On a glass substrate, a 40-nm-thick Ti film was deposited by sputtering, and patterned by photolithographic techniques to form an anode. The anode was formed so as to have an electrode area of 3 mm². The anode was subsequently washed.

Subsequently, the electrode-formed substrate prepared above was mounted in a vacuum deposition apparatus (manufactured by ULVAC, Inc.). The evaporation materials were prepared for deposition and then evacuation was performed to 1.33×10⁻⁴ Pa (1×10⁻⁶ Torr). Subsequently, the inside of the chamber was subjected to UV/ozone cleaning. Then, layers were formed so as to provide the layer configuration described in Table 3 below. Subsequently, the substrate was transferred into a glove box and sealed, in a nitrogen atmosphere, with a glass cap containing a desiccant to obtain an organic light emitting element. In the Table, “%” represents “mass %”.

In Examples 2 to 3 and Comparative Examples 1 to 2, organic light emitting elements were produced as in Example 1 except that the organic compound and the light emitting material were changed to the materials described in Table 4.

TABLE 3

| | | | Film |
|---|---|---|---|
| | | | thickness |
| | Material | | (nm) |
| Cathode | Al | | 100 |
| Electron injection layer (EIL) | LiF | | 1 |
| Electron transport layer (ETL) | ET2 | | 15 |
| Hole blocking layer (HBL) | ET12 | | 15 |
| Light emitting layer (EML) | Light emitting | Organic | 30 |
| | material | compound | |
| | 1-a | A9 | |
| | 1% | 99% | |

| | | |
|---|---|---|
| Electron blocking layer (EBL) | HT12 | 15 |
| Hole transport layer (HTL) | HT3 | 30 |
| Hole injection layer (HIL) | HT16 | 5 |

The obtained elements were measured and evaluated for their characteristics. For each light emitting element, external quantum efficiency (E.Q.E.) at a current density of 100 mA/cm² was measured; and a continuous driving test at a current density of 100 mA/cm² was performed and the time to a 5% decrease in luminance was measured. The results will be described in Table 4. Element efficiency is expressed as a relative value, with the E.Q.E. of Comparative Example 1 taken as 1.0, and element durability is expressed as a ratio, with the time to a 5% decrease in luminance in Comparative Example 1 taken as 1.0.

In EXAMPLES, the measurement instruments employed were specifically as follows: the current-voltage characteristics were measured using a micro-ammeter 4140B manufactured by Hewlett-Packard Company, and the light emission luminance was measured using BM7 manufactured by TOPCON CORPORATION.

TABLE 4

| | Organic compound | Light emitting | | | |
|---|---|---|---|---|---|
| | (permanent dipole | material (permanent | | Element | Element |
| | moment μₕ) | dipole moment μ_{d}) | μₕ/μ_{d} | efficiency | durability |
| Example 1 | 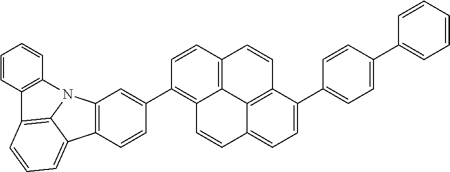 [SMILES: c1ccc(-c2ccc(-c3ccc4ccc5c(-c6ccc7c8cccc9c%10ccccc%10n(c7c6)c98)ccc6ccc3c4c65)cc2)cc1] | 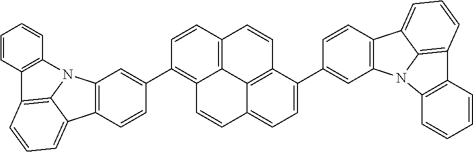 [SMILES: c1ccc2c(c1)c1cccc3c4ccc(-c5ccc6ccc7c(-c8ccc9c%10cccc%11c%12ccccc%12n(c9c8)c%11%10)ccc8ccc5c6c87)cc4n2c13] | 1.8 | 1.2 | 1.2 |
| | A9(0.53) | 1-a(0.30) | | | |
| Example 2 | 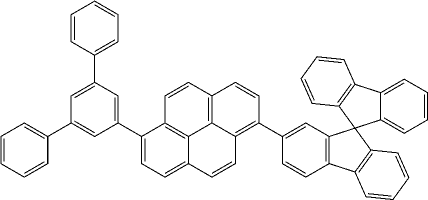 [SMILES: c1ccc(-c2cc(-c3ccccc3)cc(-c3ccc4ccc5c(-c6ccc7c(c6)C6(c8ccccc8-c8ccccc86)c6ccccc6-7)ccc6ccc3c4c65)c2)cc1] | 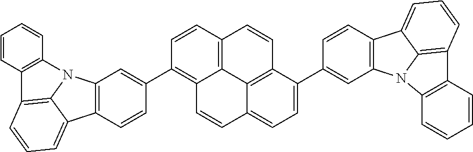 [SMILES: c1ccc2c(c1)c1cccc3c4ccc(-c5ccc6ccc7c(-c8ccc9c%10cccc%11c%12ccccc%12n(c9c8)c%11%10)ccc8ccc5c6c87)cc4n2c13] | 0.8 | 1.1 | 1.2 |
| | EM41(0.24) | 1-a(0.30) | | | |
| Example 3 | 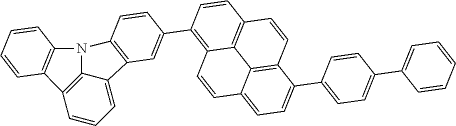 [SMILES: c1ccc(-c2ccc(-c3ccc4ccc5c(-c6ccc7c(c6)c6cccc8c9ccccc9n7c86)ccc6ccc3c4c65)cc2)cc1] | 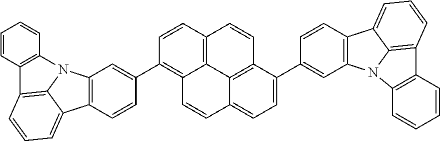 [SMILES: c1ccc2c(c1)c1cccc3c4ccc(-c5ccc6ccc7c(-c8ccc9c%10cccc%11c%12ccccc%12n(c9c8)c%11%10)ccc8ccc5c6c87)cc4n2c13] | 1.5 | 1.1 | 1.1 |
| | 2-a(0.44) | 1-a(0.30) | | | |
| Comparative Example 1 | 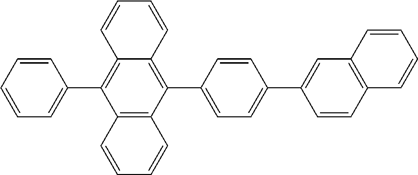 [SMILES: c1ccc(-c2c3ccccc3c(-c3ccc(-c4ccc5ccccc5c4)cc3)c3ccccc23)cc1] | 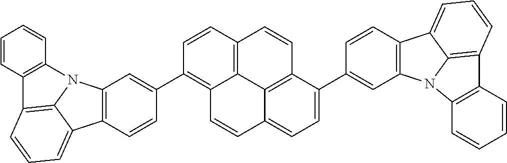 [SMILES: c1ccc2c(c1)c1cccc3c4ccc(-c5ccc6ccc7c(-c8ccc9c%10cccc%11c%12ccccc%12n(c9c8)c%11%10)ccc8ccc5c6c87)cc4n2c13] | 0.1 | 1.0 | 1.0 |
| | 1-b(0.03) | 1-a(0.30) | | | |
| Comparative Example 2 | 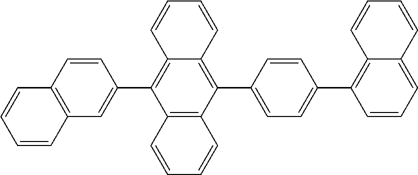 [SMILES: c1ccc2cc(-c3c4ccccc4c(-c4ccc(-c5cccc6ccccc56)cc4)c4ccccc34)ccc2c1] | 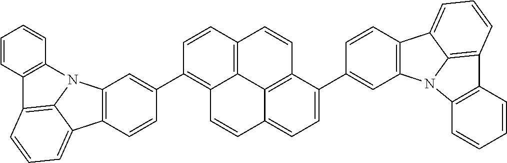 [SMILES: c1ccc2c(c1)c1cccc3c4ccc(-c5ccc6ccc7c(-c8ccc9c%10cccc%11c%12ccccc%12n(c9c8)c%11%10)ccc8ccc5c6c87)cc4n2c13] | 0.5 | 1.0 | 1.0 |
| | EM42(0.15) | 1-a(0.30) | | | |

### Examples 4 to 6 and Comparative Example 3

Organic light emitting elements were produced as in Example 1 except that the organic compound and the light emitting material were changed to the materials described in Table 5. The results will be described in Table 5. Element efficiency is expressed as a relative value, with the E.Q.E. of Comparative Example 3 taken as 1.0, and element durability is expressed as a ratio, with the time to a 5% decrease in luminance in Comparative Example 3 taken as 1.0.

TABLE 5

| | Organic compound | Light emitting | | | |
|---|---|---|---|---|---|
| | (permanent dipole | material (permanent | | Element | Element |
| | moment μₕ) | dipole moment μ_{d}) | μₕ/μ_{d} | efficiency | durability |
| Example 4 | 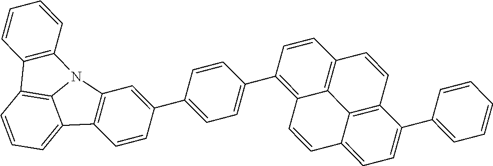 [SMILES: c1ccc(-c2ccc3ccc4c(-c5ccc(-c6ccc7c8cccc9c%10ccccc%10n(c7c6)c98)cc5)ccc5ccc2c3c54)cc1] | 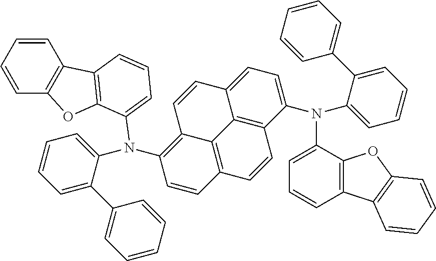 [SMILES: c1ccc(-c2ccccc2N(c2ccc3ccc4c(N(c5ccccc5-c5ccccc5)c5cccc6c5oc5ccccc56)ccc5ccc2c3c54)c2cccc3c2oc2ccccc23)cc1] | 1.1 | 1.2 | 1.2 |
| | A2(0.57) | BD6(0.53) | | | |
| Example 5 | 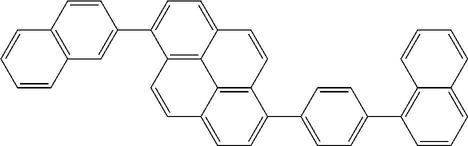 [SMILES: c1ccc2cc(-c3ccc4ccc5c(-c6ccc(-c7cccc8ccccc78)cc6)ccc6ccc3c4c65)ccc2c1] | 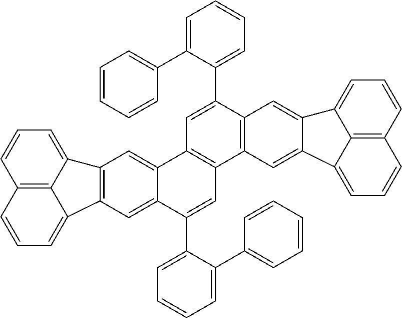 [SMILES: c1ccc(-c2ccccc2-c2cc3c4cc5c(cc4c(-c4ccccc4-c4ccccc4)cc3c3cc4c(cc23)-c2cccc3cccc-4c23)-c2cccc3cccc-5c23)cc1] | 1.3 | 1.1 | 1.2 |
| | EM43(0.12) | BD11(0.09) | | | |
| Example 6 | 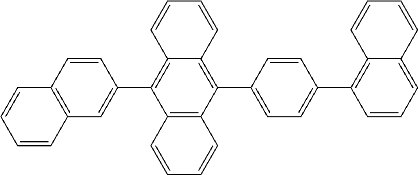 [SMILES: c1ccc2cc(-c3c4ccccc4c(-c4ccc(-c5cccc6ccccc56)cc4)c4ccccc34)ccc2c1] | 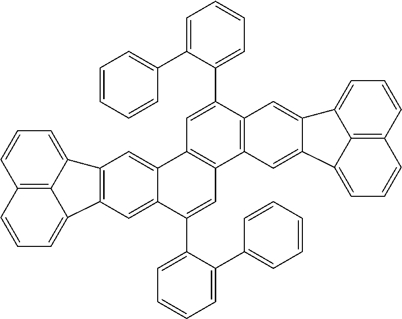 [SMILES: c1ccc(-c2ccccc2-c2cc3c4cc5c(cc4c(-c4ccccc4-c4ccccc4)cc3c3cc4c(cc23)-c2cccc3cccc-4c23)-c2cccc3cccc-5c23)cc1] | 1.7 | 1.1 | 1.1 |
| | EM42(0.15) | BD11(0.09) | | | |
| Comparative Example 3 | 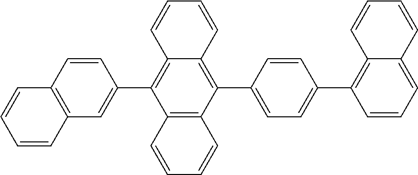 [SMILES: c1ccc2cc(-c3c4ccccc4c(-c4ccc(-c5cccc6ccccc56)cc4)c4ccccc34)ccc2c1] | 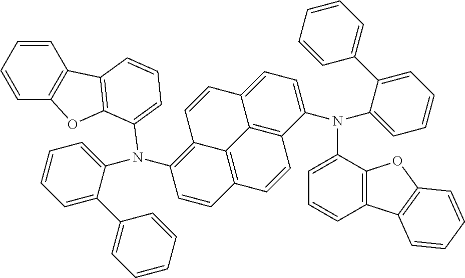 [SMILES: c1ccc(-c2ccccc2N(c2ccc3ccc4c(N(c5ccccc5-c5ccccc5)c5cccc6c5oc5ccccc56)ccc5ccc2c3c54)c2cccc3c2oc2ccccc23)cc1] | 0.3 | 1.0 | 1.0 |
| | EM42(0.15) | BD6(0.53) | | | |

### Examples 7 to 10 and Comparative Example 4

Organic light emitting elements were produced as in Example 1 except that the organic compound and the light emitting material were changed to the materials described in Table 6. The results will be described in Table 6. Element efficiency is expressed as a relative value, with the E.Q.E. of Comparative Example 4 taken as 1.0, and element durability is expressed as a ratio, with the time to a 5% decrease in luminance in Comparative Example 4 taken as 1.0.

TABLE 6

| | Organic compound | Light emitting | | | |
|---|---|---|---|---|---|
| | (permanent dipole | material (permanent | | Element | Element |
| | moment μₕ) | dipole moment μ_{d}) | μₕ/μ_{d} | efficiency | durability |
| Example 7 | 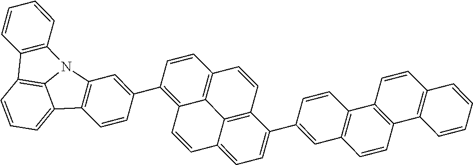 [SMILES: c1ccc2c(c1)ccc1c3ccc(-c4ccc5ccc6c(-c7ccc8c9cccc%10c%11ccccc%11n(c8c7)c%109)ccc7ccc4c5c76)cc3ccc21] | 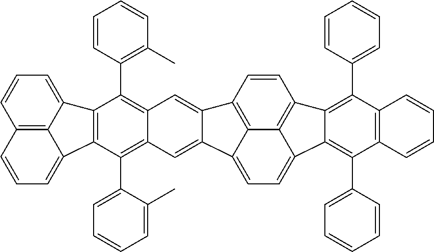 [SMILES: Cc1ccccc1-c1c2cc3c(cc2c(-c2ccccc2C)c2c4cccc5cccc(c12)c54)c1ccc2c4c(ccc3c41)-c1c-2c(-c2ccccc2)c2ccccc2c1-c1ccccc1] | 1.2 | 1.2 | 1.3 |
| | A18(0.51) | GD21(0.43) | | | |
| Example 8 | 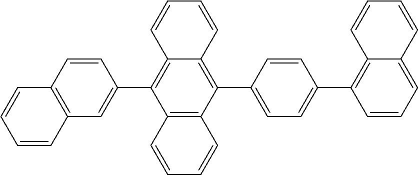 [SMILES: c1ccc2cc(-c3c4ccccc4c(-c4ccc(-c5cccc6ccccc56)cc4)c4ccccc34)ccc2c1] | 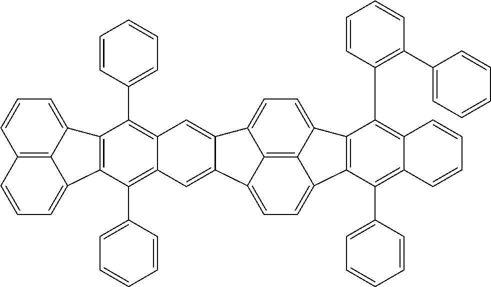 [SMILES: c1ccc(-c2ccccc2-c2c3c(c(-c4ccccc4)c4ccccc24)-c2ccc4c5cc6c(-c7ccccc7)c7c8cccc9cccc(c7c(-c7ccccc7)c6cc5c5ccc-3c2c45)c98)cc1] | 0.6 | 1.1 | 1.2 |
| | EM42(0.15) | GD22(0.25) | | | |
| Example 9 | 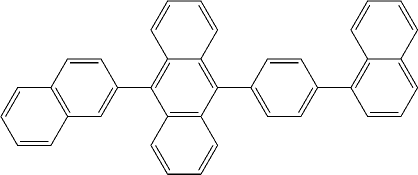 [SMILES: c1ccc2cc(-c3c4ccccc4c(-c4ccc(-c5cccc6ccccc56)cc4)c4ccccc34)ccc2c1] | 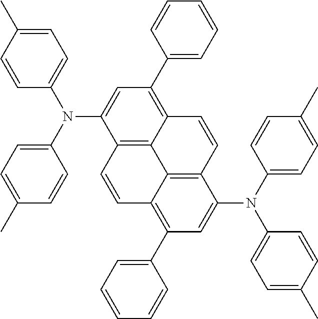 [SMILES: Cc1ccc(N(c2ccc(C)cc2)c2cc(-c3ccccc3)c3ccc4c(N(c5ccc(C)cc5)c5ccc(C)cc5)cc(-c5ccccc5)c5ccc2c3c54)cc1] | 1.7 | 1.1 | 1.1 |
| | EM42(0.15) | GD16(0.09) | | | |
| Example 10 | 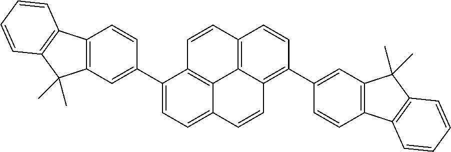 [SMILES: CC1(C)c2ccccc2-c2ccc(-c3ccc4ccc5c(-c6ccc7c(c6)C(C)(C)c6ccccc6-7)ccc6ccc3c4c65)cc21] | 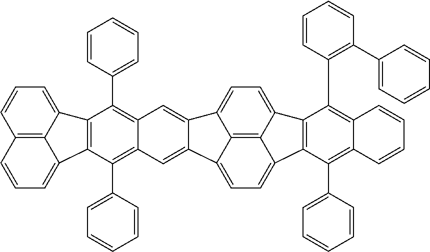 [SMILES: c1ccc(-c2ccccc2-c2c3c(c(-c4ccccc4)c4ccccc24)-c2ccc4c5cc6c(-c7ccccc7)c7c8cccc9cccc(c7c(-c7ccccc7)c6cc5c5ccc-3c2c45)c98)cc1] | 1.9 | 1.1 | 1.3 |
| | EM33(0.48) | GD22(0.25) | | | |
| Comparative Example 4 | 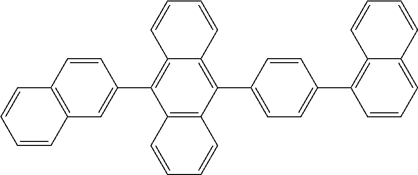 [SMILES: c1ccc2cc(-c3c4ccccc4c(-c4ccc(-c5cccc6ccccc56)cc4)c4ccccc34)ccc2c1] | 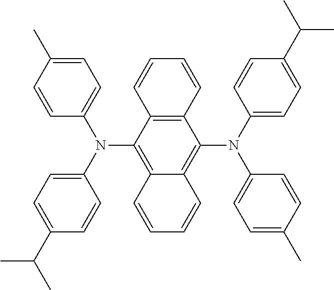 [SMILES: Cc1ccc(N(c2ccc(C(C)C)cc2)c2c3ccccc3c(N(c3ccc(C)cc3)c3ccc(C(C)C)cc3)c3ccccc23)cc1] | 3.8 | 1.0 | 1.0 |
| | EM42(0.15) | GD17(0.04) | | | |

### Examples 11 to 14 and Comparative Examples 5 to 7

Organic light emitting elements were produced as in Example 1 except that the organic compound and the light emitting material were changed to the materials described in Table 7. The results will be described in Table 7. Element efficiency is expressed as a relative value, with the E.Q.E. of Comparative Example 6 taken as 1.0, and element durability is expressed as a ratio, with the time to a 5% decrease in luminance in Comparative Example 6 taken as 1.0.

TABLE 7

| | Organic compound | Light emitting | | | |
|---|---|---|---|---|---|
| | (permanent dipole | material (permanent | | Element | Element |
| | moment μₕ) | dipole moment μ_{d}) | μₕ/μ_{d} | efficiency | durability |
| Example 11 | 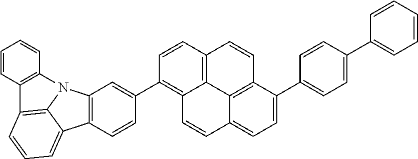 [SMILES: c1ccc(-c2ccc(-c3ccc4ccc5c(-c6ccc7c8cccc9c%10ccccc%10n(c7c6)c98)ccc6ccc3c4c65)cc2)cc1] | 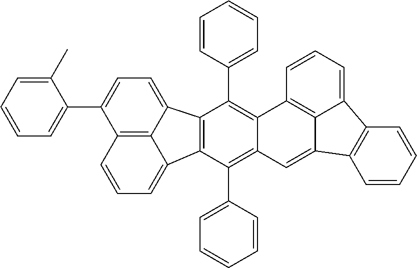 [SMILES: Cc1ccccc1-c1ccc2c3c(-c4ccccc4)c4c(cc5c6ccccc6c6cccc4c65)c(-c4ccccc4)c3c3cccc1c32] | 0.6 | 1.2 | 1.3 |
| | A9(0.53) | BD12(0.87) | | | |
| Comparative Example 5 | 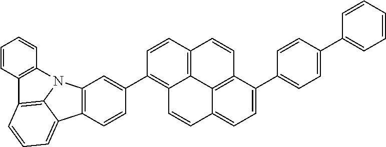 [SMILES: c1ccc(-c2ccc(-c3ccc4ccc5c(-c6ccc7c8cccc9c%10ccccc%10n(c7c6)c98)ccc6ccc3c4c65)cc2)cc1] | 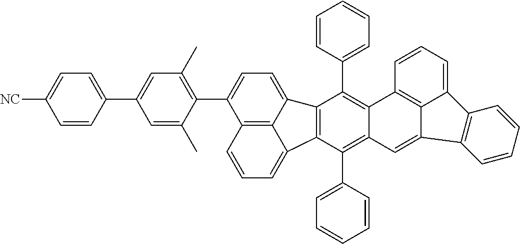 [SMILES: Cc1cc(-c2ccc(C#N)cc2)cc(C)c1-c1ccc2c3c(-c4ccccc4)c4c(cc5c6ccccc6c6cccc4c65)c(-c4ccccc4)c3c3cccc1c32] | 0.1 | 1.1 | 1.1 |
| | A9(0.53) | BD13(5.38) | | | |
| Example 12 | 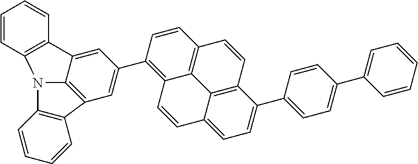 [SMILES: c1ccc(-c2ccc(-c3ccc4ccc5c(-c6cc7c8ccccc8n8c9ccccc9c(c6)c78)ccc6ccc3c4c65)cc2)cc1] | 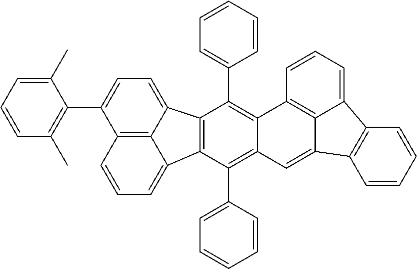 [SMILES: Cc1cccc(C)c1-c1ccc2c3c(-c4ccccc4)c4c(cc5c6ccccc6c6cccc4c65)c(-c4ccccc4)c3c3cccc1c32] | 1.0 | 1.2 | 1.2 |
| | 2-b(0.89) | BD12(0.87) | | | |
| Example 13 | 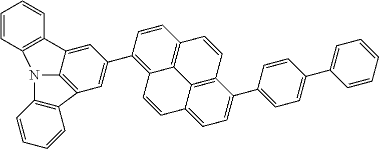 [SMILES: c1ccc(-c2ccc(-c3ccc4ccc5c(-c6cc7c8ccccc8n8c9ccccc9c(c6)c78)ccc6ccc3c4c65)cc2)cc1] | 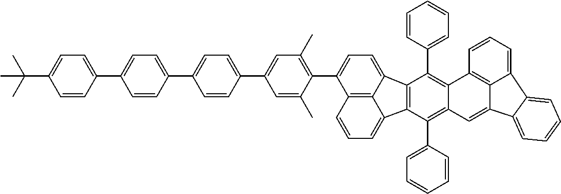 [SMILES: Cc1cc(-c2ccc(-c3ccc(-c4ccc(C(C)(C)C)cc4)cc3)cc2)cc(C)c1-c1ccc2c3c(-c4ccccc4)c4c(cc5c6ccccc6c6cccc4c65)c(-c4ccccc4)c3c3cccc1c32] | 0.8 | 1.3 | 1.2 |
| | 2-b(0.89) | BD14(1.14) | | | |
| Comparative Example 6 | 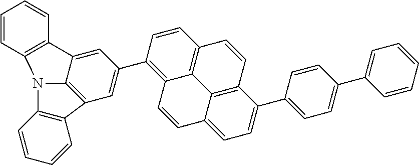 [SMILES: c1ccc(-c2ccc(-c3ccc4ccc5c(-c6cc7c8ccccc8n8c9ccccc9c(c6)c78)ccc6ccc3c4c65)cc2)cc1] | 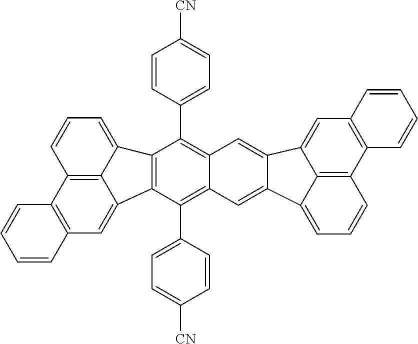 [SMILES: N#Cc1ccc(-c2c3cc4c(cc3c(-c3ccc(C#N)cc3)c3c5cc6ccccc6c6cccc(c23)c65)c2cccc3c5ccccc5cc4c32)cc1] | 2.0 | 1.0 | 1.0 |
| | 2-b(0.89) | BD 15(0.45) | | | |
| Example 14 | 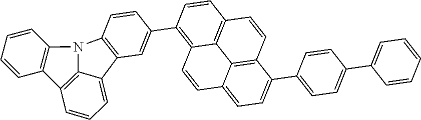 [SMILES: c1ccc(-c2ccc(-c3ccc4ccc5c(-c6ccc7c(c6)c6cccc8c9ccccc9n7c86)ccc6ccc3c4c65)cc2)cc1] | 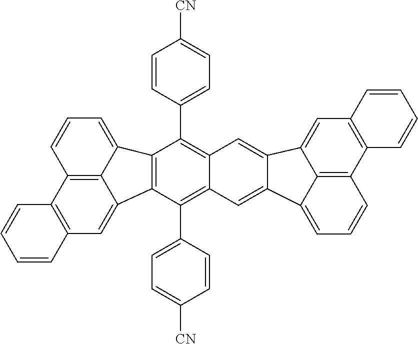 [SMILES: N#Cc1ccc(-c2c3cc4c(cc3c(-c3ccc(C#N)cc3)c3c5cc6ccccc6c6cccc(c23)c65)c2cccc3c5ccccc5cc4c32)cc1] | 1.0 | 1.2 | 1.1 |
| | 2-a(0.44) | BD15(0.45) | | | |
| Comparative Example 7 | 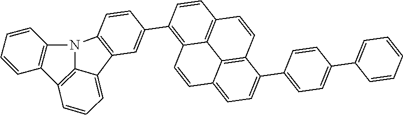 [SMILES: c1ccc(-c2ccc(-c3ccc4ccc5c(-c6ccc7c(c6)c6cccc8c9ccccc9n7c86)ccc6ccc3c4c65)cc2)cc1] | 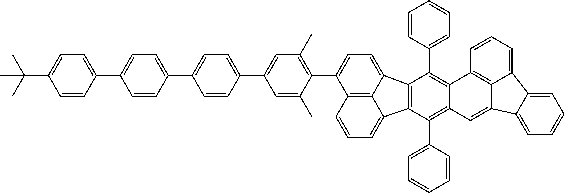 [SMILES: Cc1cc(-c2ccc(-c3ccc(-c4ccc(C(C)(C)C)cc4)cc3)cc2)cc(C)c1-c1ccc2c3c(-c4ccccc4)c4c(cc5c6ccccc6c6cccc4c65)c(-c4ccccc4)c3c3cccc1c32] | 0.4 | 1.1 | 1.1 |
| | 2-a(0.44) | BD14(1.14) | | | |

### Examples 15 to 17 and Comparative Examples 8 to 9

Organic light emitting elements were produced as in Example 1 except that the organic compound and the light emitting material were changed to the materials described in Table 8. The results will be described in Table 8. Element efficiency is expressed as a relative value, with the E.Q.E. of Comparative Example 8 taken as 1.0, and element durability is expressed as a ratio, with the time to a 5% decrease in luminance in Comparative Example 8 taken as 1.0.

TABLE 8

| | Organic compound | Light emitting | | | |
|---|---|---|---|---|---|
| | (permanent dipole | material (permanent | | Element | Element |
| | moment μₕ) | dipole moment μ_{d}) | μₕ/μ_{d} | efficiency | durability |
| Example 15 | 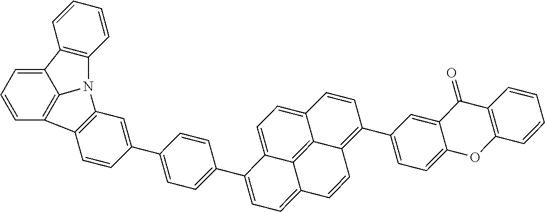 [SMILES: O=c1c2ccccc2oc2ccc(-c3ccc4ccc5c(-c6ccc(-c7ccc8c9cccc%10c%11ccccc%11n(c8c7)c%109)cc6)ccc6ccc3c4c65)cc12] | 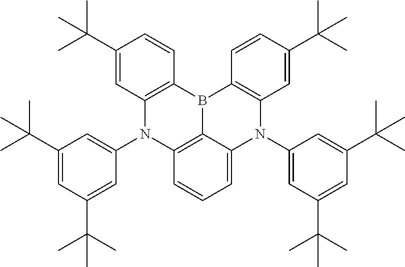 [SMILES: CC(C)(C)c1cc(N2c3cc(C(C)(C)C)ccc3B3c4ccc(C(C)(C)C)cc4N(c4cc(C(C)(C)C)cc(C(C)(C)C)c4)c4cccc2c43)cc(C(C)(C)C)c1] | 1.0 | 1.1 | 1.2 |
| | EM34(2.67) | BD10(2.70) | | | |
| Example 16 | 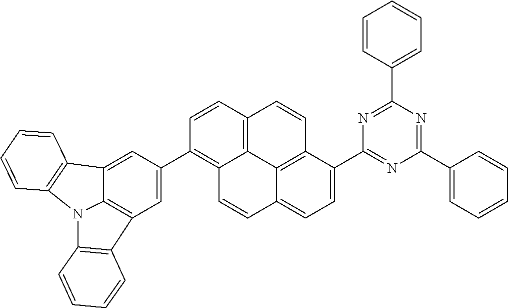 [SMILES: c1ccc(-c2nc(-c3ccccc3)nc(-c3ccc4ccc5c(-c6cc7c8ccccc8n8c9ccccc9c(c6)c78)ccc6ccc3c4c65)n2)cc1] | 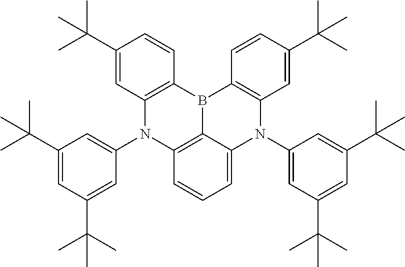 [SMILES: CC(C)(C)c1cc(N2c3cc(C(C)(C)C)ccc3B3c4ccc(C(C)(C)C)cc4N(c4cc(C(C)(C)C)cc(C(C)(C)C)c4)c4cccc2c43)cc(C(C)(C)C)c1] | 0.6 | 1.1 | 1.1 |
| | A2(1.67) | BD10(2.70) | | | |
| Comparative Example 8 | 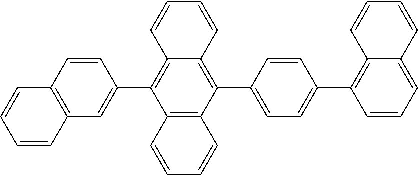 [SMILES: c1ccc2cc(-c3c4ccccc4c(-c4ccc(-c5cccc6ccccc56)cc4)c4ccccc34)ccc2c1] | 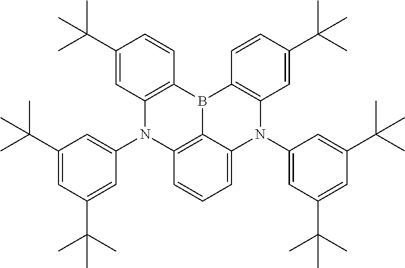 [SMILES: CC(C)(C)c1cc(N2c3cc(C(C)(C)C)ccc3B3c4ccc(C(C)(C)C)cc4N(c4cc(C(C)(C)C)cc(C(C)(C)C)c4)c4cccc2c43)cc(C(C)(C)C)c1] | <0.1 | 1.0 | 1.0 |
| | EM42(0.15) | BD10(2.70) | | | |
| Example 17 | 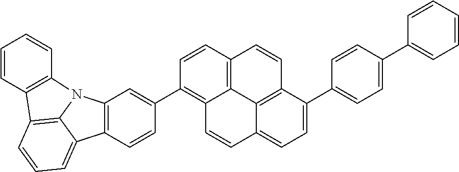 [SMILES: c1ccc(-c2ccc(-c3ccc4ccc5c(-c6ccc7c8cccc9c%10ccccc%10n(c7c6)c98)ccc6ccc3c4c65)cc2)cc1] | 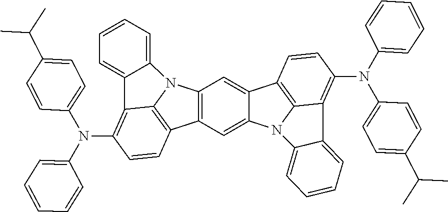 [SMILES: CC(C)c1ccc(N(c2ccccc2)c2ccc3c4cc5c(cc4n4c6ccccc6c2c34)c2ccc(N(c3ccccc3)c3ccc(C(C)C)cc3)c3c4ccccc4n5c23)cc1] | 0.7 | 1.1 | 1.3 |
| | A9(0.53) | BD16(0.72) | | | |
| Comparative Example 9 | 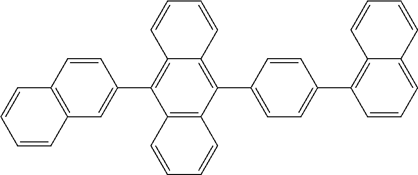 [SMILES: c1ccc2cc(-c3c4ccccc4c(-c4ccc(-c5cccc6ccccc56)cc4)c4ccccc34)ccc2c1] | 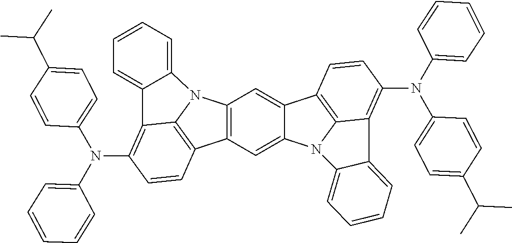 [SMILES: CC(C)c1ccc(N(c2ccccc2)c2ccc3c4cc5c(cc4n4c6ccccc6c2c34)c2ccc(N(c3ccccc3)c3ccc(C(C)C)cc3)c3c4ccccc4n5c23)cc1] | 0.3 | 1.0 | 1.0 |
| | EM42(0.15) | BD16(0.72) | | | |

Tables 5 to 8 have demonstrated that the organic light emitting elements according to the Examples exhibit higher luminous efficiency than the organic light emitting elements according to the Comparative Examples. This is inferentially because such an organic compound and such a light emitting material have similar permanent dipole moments, to thereby provide improved compatibility between the organic compound and the light emitting material, resulting in more efficient energy transfer.

In Table 5, Example 4 and Example 5 are compared: the organic compound in Example 4 has a larger permanent dipole moment than the organic compound in Example 5, and therefore, the organic light emitting element in Example 4 exhibited higher luminous efficiency. Furthermore, Example 5 and Example 6 are compared: the organic compound in Example 5 is a compound including a pyrene skeleton more excellent in oxidation stability, and therefore, Example 5 exhibited better element durability.

In Table 6, Example 7 and Example 8 are compared: the organic compound in Example 7 has a larger permanent dipole moment than the organic compound in Example 8, and therefore, the organic light emitting element in Example 7 exhibited higher luminous efficiency. Furthermore, Example 8 and Example 9 are compared: the light emitting material in Example 8 is a compound composed only of hydrocarbon and excellent in stability, and therefore, the organic compound in Example 8 provided better element durability.

As has been described so far, the organic light emitting element according to the present disclosure is excellent in luminous efficiency. The organic light emitting element according to the present embodiment is also excellent in durability.

The present disclosure can provide an organic light emitting element excellent in luminous efficiency.

While the present disclosure has been described with reference to embodiments, it is to be understood that the present disclosure is not limited to the disclosed embodiments. The scope of the following claims is to be accorded the broadest interpretation so as to encompass all such modifications and equivalent structures and functions.

This application claims the benefit of Japanese Patent Applications No. 2025-024000, filed Feb. 18, 2025, and No. 2026-010607, filed Jan. 26, 2026, which are hereby incorporated by reference herein in their entirety.

What is claimed is:

1. An organic light emitting element comprising:
a first electrode;
a second electrode; and
an organic compound layer disposed between the first electrode and the second electrode,
wherein the organic compound layer includes a light emitting layer containing an organic compound and a light emitting material; in a case that a permanent dipole moment of the organic compound is defined as μₕ and a permanent dipole moment of the light emitting material is defined as μ_{d},
μₕ/μ_{d} is 0.6 or more and 1.9 or less; and
the light emitting material is any one of formulas (4) to (9): 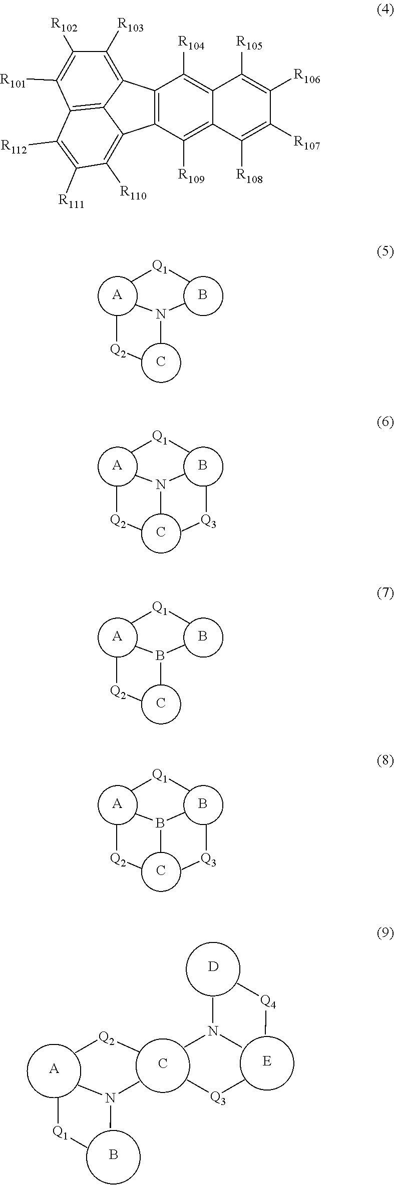
in formula (4), R₁₀₁ to R₁₁₂ are each independently selected from the group consisting of a hydrogen atom, a deuterium atom, substituted or unsubstituted alkyl groups, substituted or unsubstituted alkoxy groups, substituted or unsubstituted aryl groups, substituted or unsubstituted aryloxy groups, substituted or unsubstituted heteroaryl groups, substituted or unsubstituted heteroaryloxy groups, substituted or unsubstituted amino groups, and a cyano group; R₁₀₁ to R₁₁₂ are optionally bonded together to form a ring,
in formulas (5) to (8), cyclic units A to C are each independently selected from substituted or unsubstituted aryl groups or substituted or unsubstituted heteroaryl groups; Q₁ to Q₃ are each independently selected from a direct bond, a boron atom, C(R_{A})(R_{B}), N(R_{C}), an oxygen atom, a sulfur atom, a selenium atom, or a tellurium atom; R_{A} to R_{C} are each independently selected from a hydrogen atom, a deuterium atom, halogen atoms, substituted or unsubstituted alkyl groups, substituted or unsubstituted alkoxy groups, substituted or unsubstituted aryl groups, or substituted or unsubstituted heteroaryl groups; R_{C} and adjacent cyclic units A to C optionally form rings,
in formula (9), cyclic units A to E are each independently selected from substituted or unsubstituted aryl groups or substituted or unsubstituted heteroaryl groups; the cyclic units A to E are optionally substituted or unsubstituted benzene skeletons; the cyclic units A, B, D, and E are optionally substituted or unsubstituted benzene skeletons and the cyclic unit C is optionally a substituted or unsubstituted benzene skeleton or naphthalene skeleton; Q₁ to Q₃ are each independently selected from a direct bond, C(R_{A})(R_{B}), N(R_{C}), B(R_{D}), an oxygen atom, a sulfur atom, a selenium atom, or a tellurium atom; Q₁ to Q₄ are optionally direct bonds; and R_{A} to R_{D} are each independently selected from a hydrogen atom, a deuterium atom, halogen atoms, substituted or unsubstituted alkyl groups, substituted or unsubstituted alkoxy groups, substituted or unsubstituted aryl groups, or substituted or unsubstituted heteroaryl groups.

2. The organic light emitting element according to claim 1, wherein μₕ/μ_{d} is 0.6 or more and 1.8 or less.

3. The organic light emitting element according to claim 1, wherein μₕ/μ_{d} is 0.6 or more and 1.2 or less.

4. The organic light emitting element according to claim 1, wherein the organic compound includes a fused polycyclic hydrocarbon ring having 10 or more and 30 or less carbon atoms.

5. The organic light emitting element according to claim 1, wherein the organic compound includes a fused polycyclic hydrocarbon ring having 3 or more and 6 or less rings.

6. The organic light emitting element according to claim 1, wherein the organic compound includes an anthracene skeleton, a phenanthrene skeleton, a fluorene skeleton, a pyrene skeleton, a triphenylene skeleton, a fluoranthene skeleton, a tetracene skeleton, a chrysene skeleton, a perylene skeleton, or a spirofluorene skeleton.

7. The organic light emitting element according to claim 1, wherein the organic compound includes a pyrene skeleton.

8. The organic light emitting element according to claim 1, wherein the organic compound is any one of formulas (1) to (3): 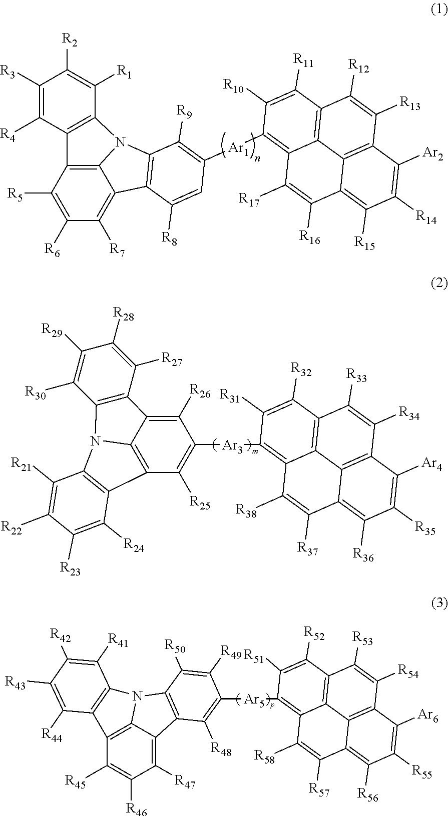
in formulas (1) to (3), R₁ to R₁₇, R₂₁ to R₃₈, and R₄₁ to R₅₈ are each independently selected from the group consisting of a hydrogen atom, a deuterium atom, substituted or unsubstituted alkyl groups, substituted or unsubstituted alkoxy groups, substituted or unsubstituted silyl groups, substituted or unsubstituted amino groups, and a cyano group,
Ar₁, Ar₃, and Ar₅ are each independently selected from the group consisting of aromatic hydrocarbon rings, heteroaromatic rings, and combinations thereof; the aromatic hydrocarbon rings optionally having a substituent,
Ar₂, Ar₄, and Ar₆ are each independently selected from the group consisting of a hydrogen atom, a deuterium atom, aromatic hydrocarbon rings, and combinations of aromatic hydrocarbon rings; the aromatic hydrocarbon rings optionally having a substituent, and
n, m, and p are 0 or 1.

9. The organic light emitting element according to claim 8, wherein the organic compound is an organic compound represented by formula (1).

10. The organic light emitting element according to claim 8, wherein in formulas (1) to (3), n, m, and p are 0.

11. The organic light emitting element according to claim 1, wherein the organic compound includes a freely rotatable single bond that is a carbon-carbon bond.

12. The organic light emitting element according to claim 1, wherein the light emitting material is a compound that emits fluorescence.

13. A display apparatus comprising a plurality of pixels, wherein at least one of the plurality of pixels includes the organic light emitting element according to claim 1 and a transistor connected to the organic light emitting element.

14. A photoelectric conversion apparatus comprising:
an image pickup element configured to receive light; and
a display unit configured to display an image captured by the image pickup element,
wherein the display unit includes the organic light emitting element according to claim 1.

15. An image display apparatus comprising:
a display unit including the organic light emitting element according to claim 1; and
a housing in which the display unit is disposed.

16. An electronic apparatus comprising:
a display unit including the organic light emitting element according to claim 1;
a housing in which the display unit is disposed; and
a communication unit disposed in the housing and configured to communicate with an external unit.

17. A wearable device comprising:
a display unit including the organic light emitting element according to claim 1;
an optical system configured to collect light from the display unit; and
a controller configured to control displaying of the display unit.

18. A lighting apparatus comprising:
a light source including the organic light emitting element according to claim 1; and
a housing in which the light source is disposed.

19. A mobile object comprising:
a lighting device including the organic light emitting element according to claim 1; and
a body in which the lighting device is disposed.

20. An organic light emitting element comprising:
a first electrode;
a second electrode; and
an organic compound layer disposed between the first electrode and the second electrode,
wherein the organic compound layer includes a light emitting layer containing an organic compound and a light emitting material; in a case that a permanent dipole moment of the organic compound is defined as μₕ and a permanent dipole moment of the light emitting material is defined as μ_{d},
μₕ/μ_{d} is 0.6 or more and 1.9 or less, and the organic compound includes a pyrene skeleton.
